(19) United States
(12) Patent Application Publication
(10) Pub. No.: US 2024/0138179 A1
(43) Pub. Date: Apr. 25, 2024

(54) OLED efficency and lifetime with doped electron blocking layer

(71) Applicant: ARIZONA BOARD OF REGENTS ON BEHALF OF ARIZONA STATE UNIVERSITY, Scottsdale, AZ (US)

(72) Inventors: Jian Li, Tempe, AZ (US); Lin Song Li, Fayetteville, AR (US)

(21) Appl. No.: 18/481,044

(22) Filed: Oct. 4, 2023

Related U.S. Application Data
(60) Provisional application No. 63/378,327, filed on Oct. 4, 2022.

(51) Int. Cl. H10K 50/17; C09K 11/06; H10K 50/165; H10K 50/18

(52) U.S. Cl. CPC H10K 50/171; C09K 11/06; H10K 50/165; H10K 50/18; H10K 85/341

(57) ABSTRACT

Disclosed herein is a hybrid inorganic-organic light emitting device that can include a cathode; an anode; at least one organic layer disposed between the cathode and the anode, wherein the at least one organic layer comprises an emissive material; at least one additional layer selected from the group consisting of an electron injection layer, an electron transport layer, and a hole blocking layer; wherein the at least one additional layer is disposed between the cathode and the at least one organic layer; and wherein the at least one additional layer comprises at least one metal oxide. Also disclosed are consumer products comprising this hybrid inorganic-organic light emitting device.

### CROSS-REFERENCE TO RELATED APPLICATIONS

The present application claims priority to U.S. Provisional Application No. 63/378,327, filed Oct. 4, 2022, which is incorporated by reference herein in its entirety.

### FIELD

The present invention relates to devices and techniques for fabricating organic emissive devices, such as organic light emitting diodes, and devices and techniques including the same.

### BACKGROUND

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

One application for phosphorescent emissive molecules is a full color display. Industry standards for such a display call for pixels adapted to emit particular colors, referred to as “saturated” colors. In particular, these standards call for saturated red, green, and blue pixels. Alternatively the OLED can be designed to emit white light. In conventional liquid crystal displays emission from a white backlight is filtered using absorption filters to produce red, green and blue emission. The same technique can also be used with OLEDs. The white OLED can be either a single EML device or a stack structure. Color may be measured using CIE coordinates, which are well known to the art.

There remains a need in the art for efficient and stable organic light-emitting diodes. This invention addresses this unmet need.

### SUMMARY

According to an embodiment, hybrid inorganic-organic light emitting device is provided. The device can include a cathode; an anode; at least one organic layer disposed between the cathode and the anode, wherein the at least one organic layer comprises an emissive material; at least one additional layer selected from the group consisting of an electron injection layer, an electron transport layer, and a hole blocking layer; wherein the at least one additional layer is disposed between the cathode and the at least one organic layer; and wherein the at least one additional layer comprises at least one metal oxide.

In one embodiment, the at least one additional layer comprises metal oxide nanoparticles. In one embodiment, the metal oxide nanoparticles have an average diameter between 1 nm and 10 nm. In one embodiment, the at least one metal oxide comprises a compound selected from the group consisting of zinc oxide (ZnO), tin oxide (SnOx), and titanium oxide (TiOx). In one embodiment, the at least one metal oxide comprises zinc oxide (ZnO). In one embodiment, the at least one additional layer comprises at least one metal oxide selected from the group consisting of zinc oxide (ZnO), tin oxide (SnOx), and titanium oxide (TiOx); and at least one additional salt having the formula MXₙ or MYₘ; wherein M is selected from the group consisting of Cs⁺, Li⁺, Na⁺, and Al³⁺; X is selected from the group consisting of Br, Cl, and F; Y is selected from the group consisting of CO₃²⁻, and SO₄²⁻; n is an integer equal to the charge on the metal M; and m is equal to the charge on the metal M, divided by 2. In one embodiment, the at least one metal oxide comprises an aluminum, gallium, magnesium, or lithium dopant.

In one embodiment, the device further comprises an interlayer thin film, disposed between the at least one additional layer and the at least one organic layer, wherein the interlayer thin film has a thickness between 1 and 5 nm. In one embodiment, the interlayer thin film comprises a metal selected from the group consisting of aluminum, lithium, magnesium, and gallium. In one embodiment, the interlayer thin film comprises a metal salt selected form the group consisting of cesium bromide, cesium chloride, cesium carbonate, lithium chloride, lithium bromide, lithium carbonate, lead chloride, lead bromide, and lead carbonate. In one embodiment, the interlayer thin film comprises aluminum metal. In one embodiment, the interlayer thin film has a thickness between 1 and 3 nm. In one embodiment, the interlayer thin film has a thickness of about 1 nm. In one embodiment, the interlayer thin film has a thickness of about 2 nm. In one embodiment, the interlayer thin film has a thickness of about 3 nm.

In one embodiment, the emissive material comprises a tetracoordinate metal complex selected from the group consisting of Au(I), Ir(I), Rh(I), Pt(II), and Pd(II). In one embodiment, the emissive material is neutral. In one embodiment, the emissive material comprises a tetradentate ligand. In one embodiment, the emissive material has a structure represented by General Formula I or General Formula II:

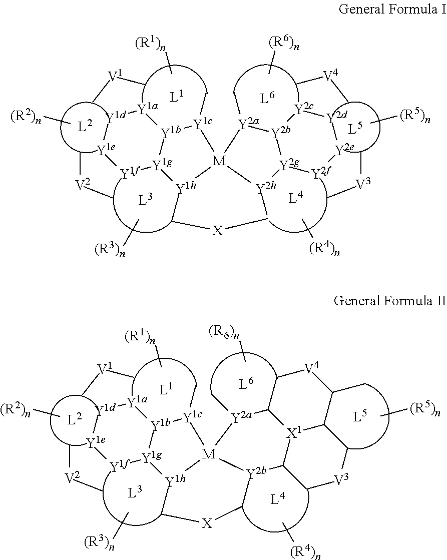

wherein, in General Formula I and General Formula II:
M represents Pt(II), Pd(II), Ir(I), Rh(I), Au(III);
Y^{1a}, Y^{1b}, Y^{1c}, Y^{1f}, Y^{1g}, Y^{1h}, Y^{2a}, Y^{2b}, Y^{2c}, Y^{2f}, Y^{2g}, Y^{2h} each independently represents C or N;
Y^{1d}, Y^{1e}, Y^{2d}, Y^{2e} each is independently absent or present, and if present, Y^{1d}, Y^{1e}, Y^{2d}, Y^{2e} each independently represents C or N;
X and X¹ each is independently present or absent, and, if present, each of X and X¹ independently represents C, N, Si, O, S, Ge, P, As, Se, B, Al, or Bi, or if valency permits, each independently represents CR⁷, SiR⁷, GeR⁷, NR⁷, P═O, As═O, B, BR⁷, AlR⁷, Bi═O, CR⁷R⁸, C═O, SiR⁷R⁸, GeR⁷R ⁸, PR⁷, PR⁷R⁸, R⁷P═O, AsR⁷, R⁷As═O, S═O, SO₂, Se═O, SeO₂, BR⁷R⁸, AlR⁷R⁸, R⁷Bi═O, or BiR⁷;
R¹, R², R³, R⁴, R⁵, R⁶, R⁷, and R⁸ each is independently absent or present as a single substituent or multiple substituents, valency permitting, and, if present, each of R¹, R², R³, R⁴, R⁵, R⁶, R⁷, and R⁸ independently represents hydrogen, deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof; wherein any two adjacent groups R¹, R², R³, R⁴, R⁵, R⁶, R⁷, or R⁸ may together join to form a ring
L¹, L³, L⁴, and L⁶ each independently represents a 5- to 10-membered aryl, heteroaryl, fused aryl, or fused heteroaryl;
L² and L⁵ each is independently present or absent, and, if present, L² and L⁵ each independently represents a 5- to 10-membered aryl, heteroaryl, fused aryl, or fused heteroaryl;
V¹, V², V³, V⁴ each is independently present, absent, or a covalent bond, and if present, each of V¹, V², V³, V⁴ independently represents C, N, Si, O, S, Ge, P, As, Se, B, Al, or Bi, or if valency permits, each independently represents CR⁷, SiR⁷, GeR⁷, NR⁷, P═O, As═O, B, BR⁷, AlR⁷, Bi═O, CR⁷R⁸, C═O, SiR⁷R⁸, GeR⁷R ⁸, PR⁷, PR⁷R⁸, R⁷P═O, AsR⁷, R⁷As═O, S═O, SO₂, Se═O, SeO₂, BR⁷R⁸, AlR⁷R⁸, R⁷Bi═O, or BiR⁷and
each n is independently an integer, valency permitting.

According to an embodiment, the organic light emitting device is incorporated into one or more device selected from a consumer product, an electronic component module, and/or a lighting panel.

### BRIEF DESCRIPTION OF THE DRAWINGS

FIG. 1 shows an organic light emitting device.

FIG. 2 shows an inverted organic light emitting device that does not have a separate electron transport layer.

FIG. 3 depicts a diagram of energy levels and chemical structure of the organic materials used in an exemplary device.

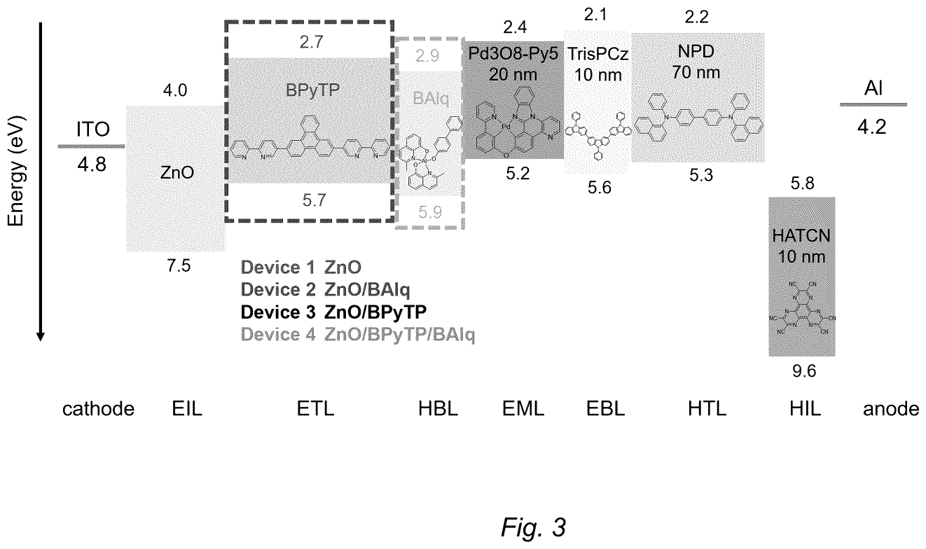

FIG. 4 is a schematic presentation of exemplary devices 1, 2, 3, and 4.

FIG. 5 is a plot of current density versus voltage for exemplary devices 1, 2, 3, and 4. with a general structure of ITO/ZnO (30 nm)/ETL/Pd3O8-Py5 (20 nm)/TrisPCz (10 nm)/NPD (70 nm)/HATCN (10 nm)/Al, where ETL is none for device 1 (open down triangles), BAlq (10 nm) for device 2 (open diamond), BPyTP (10 nm) for device 3 (open hexagon), and BPyTP (10 nm)/BAlq (10 nm) for device 4 (open star). The electroluminescent spectra of Device 4 at 1 mA/cm² is presented in the inset.

FIG. 6 is a plot of EQE versus luminance for exemplary devices 1, 2, 3, and 4.

FIG. 7 is a plot of relative luminance versus operational time at a constant current density of 20 mAcm⁻² for exemplary devices 1, 2, 3, and 4.

FIG. 8 is a plot of EQE versus luminance for devices fabricated by ZnO 20 mg/mL in structure Device 4 having the structure: ITO/ZnO (30 nm)/BPyTP (10 nm)/BAlq (10 nm)/ Pd3O8-Py5 (20 nm)/TrisPCz (10 nm)/NPD (70 nm)/HATCN (10 nm)/Al

FIG. 9 depicts a diagram of energy levels and chemical structure of the organic materials used in an exemplary device comprising an interlayer between the cathode and the at least one organic layer.

FIG. 10 is a plot of current density versus voltage for exemplary devices 4, 5, 6, and 7 having the structures of ITO/ZnO (30 nm)/Al (x nm)/BPyTP (10 nm)/BAlq (10 nm)/Pd3O8-Py5 (20 nm)/TrisPCz (10 nm)/NPD (70 nm)/HATCN (10 nm)/Al, where x is 0 nm for device 4, 1 nm for device 5 (open squares), 2 nm for device 6 (open triangles), and 3 nm for device 7 (open circles).

FIG. 11 is a plot of electroluminescent spectra for exemplary devices 4, 5, 6, and 7.

FIG. 12 is a plot of EQE versus luminance for exemplary devices 4, 5, 6, and 7.

FIG. 13 is a plot of relative luminance versus operational time at a constant current density of 20 mAcm⁻² for exemplary devices 4, 5, 6, and 7.

FIG. 14 is a plot of current density-voltage characteristics for exemplary SiTrzCz₂(n) based OLEDs. The ZnO mixed layers are as follows: Cs₂CO₃:ZnO (dot line) and CsBr:ZnO (solid line).

FIG. 15 is a plot of EQE versus luminance for exemplary SiTrzCz₂(n) based OLEDs. The ZnO mixed layers are as follows: Cs₂CO₃:ZnO (dot line) and CsBr:ZnO (solid line). The ZnO mixed layers are as follows: Cs₂CO₃:ZnO (dot line) and CsBr:ZnO (solid line).

### DETAILED DESCRIPTION

It is to be understood that the figures and descriptions in the present disclosure have been simplified to illustrate elements that are relevant for a clear understanding of the present invention, while eliminating, for the purpose of clarity, many other elements found in the art related to phosphorescent organic light emitting devices and the like. Those of ordinary skill in the art may recognize that other elements and/or steps are desirable and/or required in implementing the disclosed embodiments. However, because such elements and steps are well known in the art, and because they do not facilitate a better understanding of the present disclosure, a discussion of such elements and steps is not provided herein. The disclosure herein is directed to all such variations and modifications to such elements and methods known to those skilled in the art.

Unless defined otherwise, all technical and scientific terms used herein have the same meaning as commonly understood by one of ordinary skill in the art to which this disclosure belongs. Although any methods, materials and components similar or equivalent to those described herein can be used in the practice or testing of the disclosed embodiments, the preferred methods, and materials are described.

As used herein, each of the following terms has the meaning associated with it in this section.

The articles “a” and “an” are used herein to refer to one or to more than one (i.e., to at least one) of the grammatical object of the article. By way of example, “an element” means one element or more than one element.

“About” as used herein when referring to a measurable value such as an amount, a temporal duration, and the like, is meant to encompass variations of ±20%, ±10%, ±5%, ±1%, or ±0.1% from the specified value, as such variations are appropriate.

Throughout this disclosure, various aspects of the invention can be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 2.7, 3, 4, 5, 5.3, 6 and any whole and partial increments therebetween. This applies regardless of the breadth of the range.

Disclosed are the components to be used to prepare the compositions of the disclosure as well as the compositions themselves to be used within the methods disclosed herein. These and other materials are disclosed herein, and it is understood that when combinations, subsets, interactions, groups, etc. of these materials are disclosed that while specific reference of each various individual and collective combinations and permutation of these compounds cannot be explicitly disclosed, each is specifically contemplated and described herein. For example, if a particular compound is disclosed and discussed and a number of modifications that can be made to a number of molecules including the compounds are discussed, specifically contemplated is each and every combination and permutation of the compound and the modifications that are possible unless specifically indicated to the contrary. Thus, if a class of molecules A, B, and C are disclosed as well as a class of molecules D, E, and F and an example of a combination molecule, A-D is disclosed, then even if each is not individually recited each is individually and collectively contemplated meaning combinations, A-E, A-F, B-D, B-E, B-F, C-D, C-E, and C-F are considered disclosed. Likewise, any subset or combination of these is also disclosed. Thus, for example, the sub-group of A-E, B-F, and C-E would be considered disclosed. This concept applies to all aspects of this application including, but not limited to, steps in methods of making and using the compositions of the invention. Thus, if them are a variety of additional steps that can be performed it is understood that each of these additional steps can be performed with any specific embodiment or combination of embodiments of the methods of the invention.

As referred to herein, a linking atom or a linking group can connect two groups such as, for example, an N and C group. The linking atom can optionally, if valency permits, have other chemical moieties attached. For example, in one aspect, an oxygen would not have any other chemical groups attached as the valency is satisfied once it is bonded to two groups (e.g., N and/or C groups). In another aspect, when carbon is the linking atom, two additional chemical moieties can be attached to the carbon. Suitable chemical moieties include, but are not limited to, hydrogen, hydroxyl, alkyl, alkoxy, ═O, halogen, nitro, amine, amide, thiol, aryl, heteroalyl, cycloalkyl, and heterocyclyl.

The term “cyclic structure” or the like terms used herein refer to any cyclic chemical structure which includes, but is not limited to, aryl, heteroaryl, cycloalkyl, cycloalkenyl, and heterocyclyl.

As used herein, the term “substituted” is contemplated to include all permissible substituents of organic compounds. In a broad aspect, the permissible substituents include acyclic and cyclic, branched and unbranched, carbocyclic and heterocyclic, and aromatic and nonaromatic substituents of organic compounds. Illustrative substituents include, for example, those described below. The permissible substituents can be one or more and the same or different for appropriate organic compounds. For purposes of this disclosure, the heteroatoms, such as nitrogen, can have hydrogen substituents and/or any permissible substituents of organic compounds described herein which satisfy the valences of the heteroatoms. This disclosure is not intended to be limited in any manner by the permissible substituents of organic compounds. Also, the terms “substitution” or “substituted with” include the implicit proviso that such substitution is in accordance with permitted valence of the substituted atom and the substituent, and that the substitution results in a stable compound, e.g., a compound that does not spontaneously undergo transformation such as by rearrangement, cyclization, elimination, etc. It is also contemplated that, in certain aspects, unless expressly indicated to the contrary, individual substituents can be further optionally substituted (i.e., further substituted or unsubstituted).

The term “alkyl” as used herein is a branched or unbranched saturated hydrocarbon group of 1 to 24 carbon atoms, such as methyl, ethyl, n-propyl, isopropyl, n-butyl, isobutyl, s-butyl, t-butyl, n-pentyl, isopentyl, s-pentyl, neopentyl, hexyl, heptyl, octyl, nonyl, decyl, dodecyl, tetradecyl, hexadecyl, eicosyl, tetracosyl, and the like. The alkyl group can be cyclic or acyclic. The alkyl group can be branched or unbranched. The alkyl group can also be substituted or unsubstituted. For example, the alkyl group can be substituted with one or more groups including, but not limited to, alkyl, cycloalkyl, alkoxy, amino, ether, halide, hydroxy, nitro, silyl, sulfo-oxo, or thiol, as described herein. A “lower alkyl” group is an alkyl group containing from one to six (e.g., from one to four) carbon atoms.

Throughout the specification “alkyl” is generally used to refer to both unsubstituted alkyl groups and substituted alkyl groups; however, substituted alkyl groups are also specifically referred to herein by identifying the specific substituent(s) on the alkyl group. For example, the term “halogenated alkyl” or “haloalkyl” specifically refers to an alkyl group that is substituted with one or more halide, e.g., fluorine, chlorine, bromine, or iodine. The term “alkoxyalkyl” specifically refers to an alkyl group that is substituted with one or more alkoxy groups, as described below. The term “alkylamino” specifically refers to an alkyl group that is substituted with one or more amino groups, as described below, and the like. When “alkyl” is used in one instance and a specific term such as “alkylalcohol” is used in another, it is not meant to imply that the term “alkyl” does not also refer to specific terms such as “alkylalcohol” and the like.

This practice is also used for other groups described herein. That is, while a term such as “cycloalkyl” refers to both unsubstituted and substituted cycloalkyl moieties, the substituted moieties can, in addition, be specifically identified herein; for example, a particular substituted cycloalkyl can be referred to as, e.g., an “alkylcycloalkyl.” Similarly, a substituted alkoxy can be specifically referred to as, e.g., a “halogenated alkoxy,” a particular substituted alkenyl can be, e.g., an “alkenylalcohol,” and the like. Again, the practice of using a general term, such as “cycloalkyl,” and a specific term, such as “alkylcycloalkyl,” is not meant to imply that the general term does not also include the specific term.

The term “cycloalkyl” as used herein is a non-aromatic carbon-based ring composed of at least three carbon atoms. Examples of cycloalkyl groups include, but are not limited to, cyclopropyl, cyclobutyl, cyclopentyl, cyclohexyl, norbornyl, and the like. The term “heterocycloalkyl” is a type of cycloalkyl group as defined above, and is included within the meaning of the term “cycloalkyl,” where at least one of the carbon atoms of the ring is replaced with a heteroatom such as, but not limited to, nitrogen, oxygen, sulfur, or phosphorus. The cycloalkyl group and heterocycloalkyl group can be substituted or unsubstituted. The cycloalkyl group and heterocycloalkyl group can be substituted with one or more groups including, but not limited to, alkyl, cycloalkyl, alkoxy, amino, ether, halide, hydroxy, nitro, silyl, sulfo-oxo, or thiol as described herein.

The term “polyalkylene group” as used herein is a group having two or more CH₂ groups linked to one another. The polyalkylene group can be represented by the formula —(CH₂)ₐ—, where “a” is an integer of from 2 to 500.

The terms “alkoxy” and “alkoxyl” as used herein to refer to an alkyl or cycloalkyl group bonded through an ether linkage; that is, an “alkoxy” group can be defined as —OA¹ where A¹ is alkyl or cycloalkyl as defined above. “Alkoxy” also includes polymers of alkoxy groups as just described; that is, an alkoxy can be a polyether such as —OA¹-OA₂ or —OA¹-(OA²)ₐ-OA³, where “a” is an integer of from 1 to 200 and A¹, A², and A³ are alkyl and/or cycloalkyl groups.

The term “alkenyl” as used herein is a hydrocarbon group of from 2 to 24 carbon atoms with a structural formula containing at least one carbon-carbon double bond. Asymmetric structures such as (A¹A²)C═C(A³A⁴) are intended to include both the E and Z isomers. This can be presumed in structural formulae herein wherein an asymmetric alkene is present, or it can be explicitly indicated by the bond symbol C═C. The alkenyl group can be substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol, as described herein.

The term “cycloalkenyl” as used herein is a non-aromatic carbon-based ring composed of at least three carbon atoms and containing at least one carbon-carbon double bond, i.e., C═C. Examples of cycloalkenyl groups include, but are not limited to, cyclopropenyl, cyclobutenyl, cyclopentenyl, cyclopentadienyl, cyclohexenyl, cyclohexadienyl, norbornenyl, and the like. The term “heterocycloalkenyl” is a type of cycloalkenyl group as defined above, and is included within the meaning of the term “cycloalkenyl,” where at least one of the carbon atoms of the ring is replaced with a heteroatom such as, but not limited to, nitrogen, oxygen, sulfur, or phosphorus. The cycloalkenyl group and heterocycloalkenyl group can be substituted or unsubstituted. The cycloalkenyl group and heterocycloalkenyl group can be substituted with one or more groups including, but not limited to, alkyl, cycloalkyl, alkoxy, alkenyl, cycloalkenyl, alkynyl, cycloalkynyl, heteroaryl, aldehyde, amino, carboxylic acid, ester, ether, halide, hydroxy, ketone, azide, nitro, silyl, sulfo-oxo, or thiol as described herein.

The term “alkynyl” as used herein is a hydrocarbon group of 2 to 24 carbon atoms with a structural formula containing at least one carbon-carbon triple bond. The alkynyl group can be unsubstituted or substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol, as described herein.

The term “cycloalkynyl” as used herein is a non-aromatic carbon-based ring composed of at least seven carbon atoms and containing at least one carbon-carbon triple bound. Examples of cycloalkynyl groups include, but are not limited to, cycloheptynyl, cyclooctynyl, cyclononynyl, and the like. The term “heterocycloalkynyl” is a type of cycloalkenyl group as defined above, and is included within the meaning of the term “cycloalkynyl,” where at least one of the carbon atoms of the ring is replaced with a heteroatom such as, but not limited to, nitrogen, oxygen, sulfur, or phosphorus. The cycloalkynyl group and heterocycloalkynyl group can be substituted or unsubstituted. The cycloalkynyl group and heterocycloalkynyl group can be substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol as described herein.

The term “aryl” as used herein is a group that contains any carbon-based aromatic group including, but not limited to, benzene, naphthalene, phenyl, biphenyl, phenoxybenzene, and the like. The term “aryl” refers to and includes both single-ring aromatic hydrocarbyl groups and polycyclic aromatic ring systems. The polycyclic rings may have two or more rings in which two carbons are common to two adjoining rings (the rings are “fused”) wherein at least one of the rings is an aromatic hydrocarbyl group, e.g., the other rings can be cycloalkyls, cycloalkenyls, aryl, heterocycles, and/or heteroaryls. Preferred aryl groups are those containing six to thirty carbon atoms, preferably six to twenty carbon atoms, more preferably six to twelve carbon atoms. Especially preferred is an aryl group having six carbons, ten carbons or twelve carbons. Suitable aryl groups include phenyl, biphenyl, triphenyl, triphenylene, tetraphenylene, naphthalene, anthracene, phenalene, phenanthrene, fluorene, pyrene, cluysene, petylene, and azulene, preferably phenyl, biphenyl, triphenyl, triphenylene, fluorene, and naphthalene. Additionally, the aryl group is optionally substituted.

The term “aryl” also includes “heteroatyl,” which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term “non-heteroaryl,” which is also included in the term “aryl,” defines a group that contains an aromatic group that does not contain a heteroatom. The aryl group can be substituted or unsubstituted. The aryl group can be substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol as described herein. The term “biaryl” is a specific type of aryl group and is included in the definition of “aryl.” Biaryl refers to two aryl groups that are bound together via a fused ring structure, as in naphthalene, or are attached via one or more carbon-carbon bonds, as in biphenyl.

The term “heteroatyl” refers to and includes both single-ring aromatic groups and polycyclic aromatic ring systems that include at least one heteroatom. The heteroatoms include, but are not limited to O, S, N, P, B, Si, and Se. In many instances, O, S, or N are the preferred heteroatoms. Hetero-single ring aromatic systems are preferably single rings with 5 or 6 ring atoms, and the ring can have from one to six heteroatoms. The hetero-polycyclic ring systems can have two or more rings in which two atoms are common to two adjoining rings (the rings are “fused”) wherein at least one of the rings is a heteroaryl, e.g., the other rings can be cycloalkyls, cycloalkenyls, aryl, heterocycles, and/or heteroaryls. The hetero-polycyclic aromatic ring systems can have from one to six heteroatoms per ring of the polycyclic aromatic ring system. Preferred heteroaryl groups are those containing three to thirty carbon atoms, preferably three to twenty carbon atoms, more preferably three to twelve carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group is optionally substituted.

Of the aryl and heteroaryl groups listed above, the groups of triphenylene, naphthalene, anthracene, dibenzothiophene, dibenzofuran, dibenzoselenophene, carbazole, indolocarbazole, imidazole, pyridine, pyrazine, pyrimidine, triazine, and benzimidazole, and the respective aza-analogs of each thereof are of particular interest.

The “aza” designation in the fragments described herein, i.e. aza-dibenzofuran, aza-dibenzothiophene, etc. means that one or more of the C—H groups in the respective aromatic ring can be replaced by a nitrogen atom, for example, and without any limitation, azatriphenylene encompasses both dibenzo[f,h]quinoxaline and dibenzo[f,h]quinoline. One of ordinary skill in the art can readily envision other nitrogen analogs of the aza-derivatives described above, and all such analogs are intended to be encompassed by the terms as set forth herein.

The term “aldehyde” as used herein is represented by the formula —C(O)H. Throughout this specification “C(O)” is a short hand notation for a carbonyl group, i.e.,

The terms “amine” or “amino” as used herein are represented by the formula —NA¹A², where A¹ and A² can be, independently, hydrogen or alkyl, cycloalkyl, alkenyl, cycloalkenyl, alkynyl, cycloalkynyl, aryl, or heteroaryl group as described herein.

The term “alkylamino” as used herein is represented by the formula —NH(-alkyl) where alkyl is a described herein. Representative examples include, but are not limited to, methylamino group, ethylamino group, propylamino group, isopropylamino group, butylamino group, isobutylamino group, (sec-butyl)amino group, (tert-butyflamino group, pentylamino group, isopentylamino group, (tert-pentyflamino group, hexylamino group, and the like.

The term “dialkylamino” as used herein is represented by the formula —N(-alkyl)₂ where alkyl is a described herein. Representative examples include, but are not limited to, dimethylamino group, diethylamino group, dipropylamino group, diisopropylamino group, dibutylamino group, diisobutylamino group, di(sec-butyl)amino group, di(tert-butyflamino group, dipentylamino group, diisopentylamino group, di(tert-pentyflamino group, dihexylamino group, N-ethyl-N-methylamino group, N-methyl-N-propylamino group, N-ethyl-N-propylamino group and the like.

The term “carboxylic acid” as used herein is represented by the formula —C(O)OH.

The term “ester” as used herein is represented by the formula —OC(O)A¹ or —C(O)OA¹, where A¹ can be alkyl, cycloalkyl, alkenyl, cycloalkenyl, alkynyl, cycloalkynyl, aryl, or heteroaryl group as described herein. The term “polyester” as used herein is represented by the formula -(A¹O(O)C-A²-C(O)O), or -(A¹O(O)C-A²-OC(O))ₐ—, where A¹ and A² can be, independently, an alkyl, cycloalkyl, alkenyl, cycloalkenyl, cycloalkynyl, aryl, or heteroaryl group described herein and “a” is an integer from 1 to 500. “Polyester” is as the term used to describe a group that is produced by the reaction between a compound having at least two carboxylic acid groups with a compound having at least two hydroxyl groups.

The term “ether” as used herein is represented by the formula A¹OA², where A¹ and A² can be, independently, an alkyl, cycloalkyl, alkenyl, cycloalkenyl, alkynyl, cycloalkynyl, aryl, or heteroaryl group described herein. The term “polyether” as used herein is represented by the formula -(A¹O-A²O)ₐ—, where A¹ and A² can be, independently, an alkyl, cycloalkyl, alkenyl, cycloalkenyl, alkynyl, cycloalkynyl, aryl, or heteroaryl group described herein and “a” is an integer of from 1 to 500. Examples of polyether groups include polyethylene oxide, polypropylene oxide, and polybutylene oxide.

The term “halide” as used herein refers to the halogens fluorine, chlorine, bromine, and iodine.

The term “heterocyclyl,” as used herein refers to single and multi-cyclic non-aromatic ring systems and “heteroaryl” as used herein refers to single and multi-cyclic aromatic ring systems: in which at least one of the ring members is other than carbon. The term “heterocyclyl” includes azetidine, dioxane, furan, imidazole, isothiazole, isoxazole, morpholine, oxazole, oxazole, including, 1,2,3-oxadiazole, 1,2,5-oxadiazole and 1,3,4-oxadiazole, piperazine, piperidine, pyrazine, pyrazole, pyridazine, pyridine, pyrimidine, pyrrole, pyrrolidine, tetrahydrofuran, tetrahydropyran, tetrazine, including 1,2,4,5-tetrazine, tetrazole, including 1,2,3,4-tetrazole and 1,2,4,5-tetrazole, thiadiazole, including, 1,2,3-thiadiazole, 1,2,5-thiadiazole, and 1,3,4-thiadiazole, thiazole, thiophene, triazine, including 1,3,5-triazine and 1,2,4-triazine, triazole, including, 1,2,3-triazole, 1,3,4-triazole, and the like.

The term “hydroxyl” as used herein is represented by the formula —OH.

The term “ketone” as used herein is represented by the formula A¹C(O)A², where A¹ and A² can be, independently, an alkyl, cycloalkyl, alkenyl, cycloalkenyl, alkynyl, cycloalkynyl, aryl, or heteroaryl group as described herein.

The term “azide” as used herein is represented by the formula —N3.

The term “nitro” as used herein is represented by the formula —NO₂.

The term “nitrile” as used herein is represented by the formula —CN.

The term “ureido” as used herein refers to a urea group of the formula —NHC(O)NH₂ or —NHC(O)NH—.

The term “phosphoramide” as used herein refers to a group of the formula —P(O)(NA¹A²)₂, where A¹ and A² can be, independently, hydrogen or an alkyl, cycloalkyl, alkoxy, alkenyl, cycloalkenyl, alkynyl, cycloalkynyl, aryl, or heteroaryl group as described herein.

The term “carbamoyl” as used herein refers to an amide group of the formula —CONA¹A², where A¹ and A² can be, independently, hydrogen or an alkyl, cycloalkyl, alkoxy, alkenyl, cycloalkenyl, alkynyl, cycloalkynyl, aryl, or heteroaryl group as described herein.

The term “sulfamoyl” as used herein refers to a group of the formula —S(O)₂NA¹A², where A¹ and A² can be, independently, hydrogen or an alkyl, cycloalkyl, alkoxy, alkenyl, cycloalkenyl, alkynyl, cycloalkynyl, aryl, or heteroaryl group as described herein.

The term “silyl” as used herein is represented by the formula —SiA lA²A³, where A¹, A², and A³ can be, independently, hydrogen or an alkyl, cycloalkyl, alkoxy, alkenyl, cycloalkenyl, alkynyl, cycloalkynyl, or heteroaryl group as described herein.

The term “sulfo-oxo” as used herein is represented by the formulas —S(O)A¹, —S(O)₂A¹, —OS(O)₂A¹, or —OS(O)₂OA¹, where A¹ is hydrogen or an alkyl, cycloalkyl, alkenyl, cycloalkenyl, alkynyl, cycloalkynyl, aryl, or heteroaryl group as described herein. Throughout this specification “S(O)” is a short hand notation for S═O. The term “sulfonyl” is used herein to refer to the sulfo-oxo group represented by the formula —S(O)₂A¹, where A¹ is hydrogen or an alkyl, cycloalkyl, alkenyl, cycloalkenyl, alkynyl, cycloalkynyl, aryl, or heteroaryl group as described herein. The term “sulfone” as used herein is represented by the formula A¹S(O)₂A², where A¹ and A² can be, independently, an alkyl, cycloalkyl, alkenyl, cycloalkenyl, alkynyl, cycloalkynyl, aryl, or heteroaryl group as described herein. The term “sulfoxide” as used herein is represented by the formula A¹S(O)A², where A¹ and A² can be, independently, an alkyl, cycloalkyl, alkenyl, cycloalkenyl, alkynyl, cycloalkynyl, aryl, or heteroaryl group as described herein.

The term “thiol” as used herein is represented by the formula —SH.

The term “polymeric” includes polyalkylene, polyether, polyester, and other groups with repeating units, such as, but not limited to —(CH₂O)ₙ—CH₃, —(CH₂CH₂O)ₙ—CH₃, —[CH₂CH(CH₃)]ₙ—CH₃, —[CH₂CH(COOCH₃)]ₙ—CH₃, —[CH₂CH(COOCH₂CH₃)]ₙ—CH₃, and —[CH₂CH(COO^{2t}B u)]ₙ—CH₃, where n is an integer (e.g., n>1 or n>2).

“R,” “R¹,” “R², ” “R³, ” “Rⁿ,” where n is an integer, as used herein can, independently, include hydrogen or one or more of the groups listed above. For example, if R′ is a straight chain alkyl group, one of the hydrogen atoms of the alkyl group can optionally be substituted with a hydroxyl group, an alkoxy group, an alkyl group, a halide, and the like. Depending upon the groups that are selected, a first group can be incorporated within a second group or, alternatively, the first group can be pendant (i.e., attached) to the second group. For example, with the phrase “an alkyl group comprising an amino group,” the amino group can be incorporated within the backbone of the alkyl group. Alternatively, the amino group can be attached to the backbone of the alkyl group. The nature of the group(s) that is (are) selected will determine if the first group is embedded or attached to the second group.

As described herein, compounds of the disclosure may contain “optionally substituted” moieties. In general, the term “substituted,” whether preceded by the term “optionally” or not, means that one or more hydrogens of the designated moiety are replaced with a suitable substituent. Unless otherwise indicated, an “optionally substituted” group may have a suitable substituent at each substitutable position of the group, and when more than one position in any given structure may be substituted with more than one substituent selected from a specified group, the substituent may be either the same or different at every position. Combinations of substituents envisioned by this disclosure are preferably those that result in the formation of stable or chemically feasible compounds. It is also contemplated that, in certain aspects, unless expressly indicated to the contrary, individual substituents can be further optionally substituted (i.e., further substituted or unsubstituted).

In some instance, a pair of adjacent substituents can be optionally joined or fused into a ring. The preferred ring is a five, six, or seven-membered carbocyclic or heterocyclic ring, includes both instances where the portion of the ring formed by the pair of substituents is saturated and where the portion of the ring formed by the pair of substituents is unsaturated. As used herein, “adjacent” means that the two substituents involved can be on the same ring next to each other, or on two neighboring rings having the two closest available substitutable positions, such as 2, 2′ positions in a biphenyl, or 1, 8 position in a naphthalene, as long as they can form a stable fused ring system.

In some aspects, a structure of a compound can be represented by a formula:

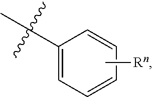

which is understood to be equivalent to a formula:

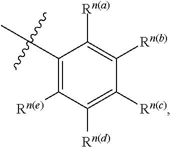

wherein n is typically an integer. That is, Rⁿ is understood to represent five independent substituents, R^{n(a)}, R^{n(b)}, R^{n(c)}, R^{n(d)}, R^{n(e)}. By “independent substituents,” it is meant that each R substituent can be independently defined. For example, if in one instance R^{n(a)} is halogen, then R^{n(b)} is not necessarily halogen in that instance.

Several references to R, R¹, R², R³, R⁴, R⁵, R⁶, etc. are made in chemical structures and moieties disclosed and described herein. Any description of R, R¹, R², R³, R⁴, R⁵, R⁶, etc. in the specification is applicable to any structure or moiety reciting R, R¹, R², R³, R⁴, R⁵, R⁶, etc. respectively.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative) Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

Layers, materials, regions, and devices may be described herein in reference to the color of light they emit. In general, as used herein, an emissive region that is described as producing a specific color of light may include one or more emissive layers disposed over each other in a stack.

As used herein, a “red” layer, material, region, or device refers to one that emits light in the range of about 580-700 nm or having a highest peak in its emission spectrum in that region. Similarly, a “green” layer, material, region, or device refers to one that emits or has an emission spectrum with a peak wavelength in the range of about 500-600 nm; a “blue” layer, material, or device refers to one that emits or has an emission spectrum with a peak wavelength in the range of about 400-500 nm; and a “yellow” layer, material, region, or device refers to one that has an emission spectrum with a peak wavelength in the range of about 540-600 nm. In some arrangements, separate regions, layers, materials, regions, or devices may provide separate “deep blue” and a “light blue” light. As used herein, in arrangements that provide separate “light blue” and “deep blue”, the “deep blue” component refers to one having a peak emission wavelength that is at least about 4 nm less than the peak emission wavelength of the “light blue” component. Typically, a “light blue” component has a peak emission wavelength in the range of about 465-S00 nm, and a “deep blue” component has a peak emission wavelength in the range of about 400-470 nm, though these ranges may vary for some configurations. Similarly, a color altering layer refers to a layer that converts or modifies another color of light to light having a wavelength as specified for that color. For example, a “red” color filter refers to a filter that results in light having a wavelength in the range of about 580-700 nm. In general, there are two classes of color altering layers: color filters that modify a spectrum by removing unwanted wavelengths of light, and color changing layers that convert photons of higher energy to lower energy. A component “of a color” refers to a component that, when activated or used, produces or otherwise emits light having a particular color as previously described. For example, a “first emissive region of a first color” and a “second emissive region of a second color different than the first color” describes two emissive regions that, when activated within a device, emit two different colors as previously described.

As used herein, emissive materials, layers, and regions may be distinguished from one another and from other structures based upon light initially generated by the material, layer or region, as opposed to light eventually emitted by the same or a different structure. The initial light generation typically is the result of an energy level change resulting in emission of a photon. For example, an organic emissive material may initially generate blue light, which may be converted by a color filter, quantum dot or other structure to red or green light, such that a complete emissive stack or sub-pixel emits the red or green light. In this case the initial emissive material or layer may be referred to as a “blue” component, even though the sub-pixel is a “red” or “green” component.

In some cases, it may be preferable to describe the color of a component such as an emissive region, sub-pixel, color altering layer, or the like, in terms of 1931 CIE coordinates. For example, a yellow emissive material may have multiple peak emission wavelengths, one in or near an edge of the “green” region, and one within or near an edge of the “red” region as previously described. Accordingly, as used herein, each color term also corresponds to a shape in the 1931 CIE coordinate color space. The shape in 1931 CIE color space is constructed by following the locus between two color points and any additional interior points. For example, interior shape parameters for red, green, blue, and yellow may be defined as shown below:

| Color | CIE Shape Parameters |
|---|---|
| Central Red | Locus: [0.6270, 0.3725]; [0.7347, 0.2653]; |
| | Interior: [0.5086, 0.2657] |
| Central Green | Locus: [0.0326, 0.3530]; [0.3731, 0.6245]; |
| | Interior: [0.2268, 0.3321 |
| Central Blue | Locus: [0.1746, 0.0052]; [0.0326, 0.3530]; |
| | Interior: [0.2268, 0.3321] |
| Central Yellow | Locus: [0.373 1, 0.6245]; [0.6270, 0.3725]; |
| | Interior: [0.3 700, 0.4087]; [0.2886, 0.4572] |

More details on OLEDs, and the definitions described above, can be found in U.S. Pat. No. 7,279,704, which is incorporated herein by reference in its entirety.

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), are incorporated by reference in their entireties. Phosphorescence is described in more detail in U.S. Pat. No. 7,279,704 at cols. 5-6, which are incorporated by reference.

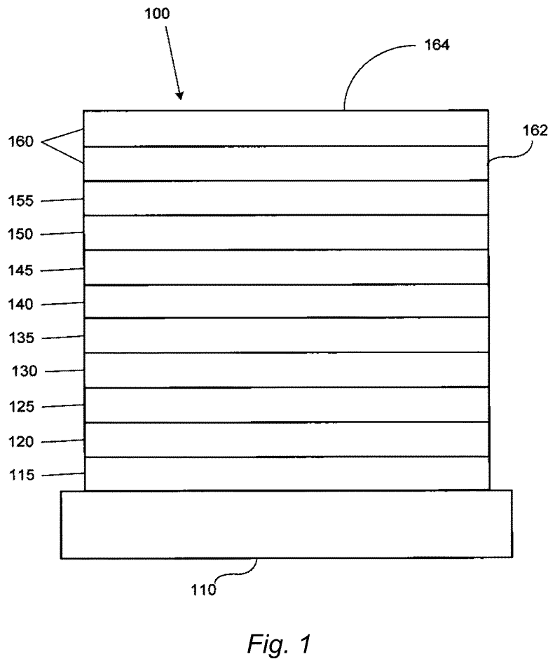

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F₄ -TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. Barrier layer 170 may be a single- or multi-layer barrier and may cover or surround the other layers of the device. The barrier layer 170 may also surround the substrate 110, and/or it may be arranged between the substrate and the other layers of the device. The barrier also may be referred to as an encapsulant, encapsulation layer, protective layer, or permeation barrier, and typically provides protection against permeation by moisture, ambient air, and other similar materials through to the other layers of the device. Examples of barrier layer materials and structures are provided in U.S. Pat. Nos. 6,537,688, 6,597,111, 6,664,137, 6,835,950, 6,888,305, 6,888,307, 6,897,474, 7,187,119, and 7,683,534, each of which is incorporated by reference in its entirety.

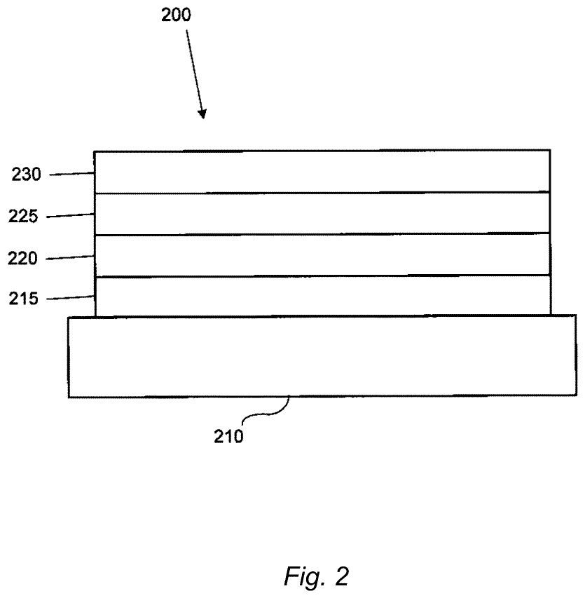

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the invention may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

In some embodiments disclosed herein, emissive layers or materials, such as emissive layer 135 and emissive layer 220 shown in FIGS. 1-2, respectively, may include quantum dots. An “emissive layer” or “emissive material” as disclosed herein may include an organic emissive material and/or an emissive material that contains quantum dots or equivalent structures, unless indicated to the contrary explicitly or by context according to the understanding of one of skill in the art. In general, an emissive layer includes emissive material within a host matrix. Such an emissive layer may include only a quantum dot material which converts light emitted by a separate emissive material or other emitter, or it may also include the separate emissive material or other emitter, or it may emit light itself directly from the application of an electric current. Similarly, a color altering layer, color filter, upconversion, or downconversion layer or structure may include a material containing quantum dots, though such layer may not be considered an “emissive layer” as disclosed herein. In general, an “emissive layer” or material is one that emits an initial light based on an injected electrical charge, where the initial light may be altered by another layer such as a color filter or other color altering layer that does not itself emit an initial light within the device, but may re-emit altered light of a different spectra content based upon absorption of the initial light emitted by the emissive layer and downconversion to a lower energy light emission. In some embodiments disclosed herein, the color altering layer, color filter, upconversion, and/or downconversion layer may be disposed outside of an OLED device, such as above or below an electrode of the OLED device.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

Devices fabricated in accordance with embodiments of the present invention may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

In some embodiments, at least one of the anode, the cathode, or a new layer disposed over the organic emissive layer functions as an enhancement layer. The enhancement layer comprises a plasmonic material exhibiting surface plasmon resonance that non-radiatively couples to the emitter material and transfers excited state energy from the emitter material to non-radiative mode of surface plasmon polariton. The enhancement layer is provided no more than a threshold distance away from the organic emissive layer, wherein the emitter material has a total non-radiative decay rate constant and a total radiative decay rate constant due to the presence of the enhancement layer and the threshold distance is where the total non-radiative decay rate constant is equal to the total radiative decay rate constant. In some embodiments, the OLED further comprises an outcoupling layer. In some embodiments, the outcoupling layer is disposed over the enhancement layer on the opposite side of the organic emissive layer. In some embodiments, the outcoupling layer is disposed on opposite side of the emissive layer from the enhancement layer but still outcouples energy from the surface plasmon mode of the enhancement layer. The outcoupling layer scatters the energy from the surface plasmon polaritons. In some embodiments this energy is scattered as photons to free space. In other embodiments, the energy is scattered from the surface plasmon mode into other modes of the device such as but not limited to the organic waveguide mode, the substrate mode, or another waveguiding mode. If energy is scattered to the non-free space mode of the OLED other outcoupling schemes could be incorporated to extract that energy to free space. In some embodiments, one or more intervening layer can be disposed between the enhancement layer and the outcoupling layer. The examples for interventing layer(s) can be dielectric materials, including organic, inorganic, perovskites, oxides, and may include stacks and/or mixtures of these materials.

The enhancement layer modifies the effective properties of the medium in which the emitter material resides resulting in any or all of the following: a decreased rate of emission, a modification of emission line-shape, a change in emission intensity with angle, a change in the stability of the emitter material, a change in the efficiency of the OLED, and reduced efficiency roll-off of the OLED device. Placement of the enhancement layer on the cathode side, anode side, or on both sides results in OLED devices which take advantage of any of the above-mentioned effects. In addition to the specific functional layers mentioned herein and illustrated in the various OLED examples shown in the figures, the OLEDs according to the present disclosure may include any of the other functional layers often found in OLEDs.

The enhancement layer can be comprised of plasmonic materials, optically active metamaterials, or hyperbolic metamaterials. As used herein, a plasmonic material is a material in which the real part of the dielectric constant crosses zero in the visible or ultraviolet region of the electromagnetic spectrum. In some embodiments, the plasmonic material includes at least one metal. In such embodiments the metal may include at least one of Ag, Al, Au, Ir, Pt, Ni, Cu, W, Ta, Fe, Cr, Mg, Ga, Rh, Ti, Ru, Pd, In, Bi, Ca alloys or mixtures of these materials, and stacks of these materials. In general, a metamaterial is a medium composed of different materials where the medium as a whole acts differently than the sum of its material parts. In particular, we define optically active metamaterials as materials which have both negative permittivity and negative permeability. Hyperbolic metamaterials, on the other hand, are anisotropic media in which the permittivity or permeability are of different sign for different spatial directions. Optically active metamaterials and hyperbolic metamaterials are strictly distinguished from many other photonic structures such as Distributed Bragg Reflectors (“DBRs”) in that the medium should appear uniform in the direction of propagation on the length scale of the wavelength of light. Using terminology that one skilled in the art can understand: the dielectric constant of the metamaterials in the direction of propagation can be described with the effective medium approximation. Plasmonic materials and metamaterials provide methods for controlling the propagation of light that can enhance OLED performance in a number of ways.

In some embodiments, the enhancement layer is provided as a planar layer. In other embodiments, the enhancement layer has wavelength-sized features that are arranged periodically, quasi-periodically, or randomly, or sub-wavelength-sized features that are arranged periodically, quasi-periodically, or randomly. In some embodiments, the wavelength-sized features and the sub-wavelength-sized features have sharp edges.

In some embodiments, the outcoupling layer has wavelength-sized features that are arranged periodically, quasi-periodically, or randomly, or sub-wavelength-sized features that are arranged periodically, quasi-periodically, or randomly. In some embodiments, the outcoupling layer may be composed of a plurality of nanoparticles and in other embodiments the outcoupling layer is composed of a pluraility of nanoparticles disposed over a material. In these embodiments the outcoupling may be tunable by at least one of varying a size of the plurality of nanoparticles, varying a shape of the plurality of nanoparticles, changing a material of the plurality of nanoparticles, adjusting a thickness of the material, changing the refractive index of the material or an additional layer disposed on the plurality of nanoparticles, varying a thickness of the enhancement layer, and/or varying the material of the enhancement layer. The plurality of nanoparticles of the device may be formed from at least one of metal, dielectric material, semiconductor materials, an alloy of metal, a mixture of dielectric materials, a stack or layering of one or more materials, and/or a core of one type of material and that is coated with a shell of a different type of material. In some embodiments, the outcoupling layer is composed of at least metal nanoparticles wherein the metal is selected from the group consisting of Ag, Al, Au, Ir, Pt, Ni, Cu, W, Ta, Fe, Cr, Mg, Ga, Rh, Ti, Ru, Pd, In, Bi, Ca, alloys or mixtures of these materials, and stacks of these materials. The plurality of nanoparticles may have additional layer disposed over them. In some embodiments, the polarization of the emission can be tuned using the outcoupling layer. Varying the dimensionality and periodicity of the outcoupling layer can select a type of polarization that is preferentially outcoupled to air. In some embodiments the outcoupling layer also acts as an electrode of the device.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the thermal population between the triplet states and the singlet excited states. Compounds that are capable of generating E-type delayed fluorescence are required to have very small singlet-triplet gaps. Thermal energy can activate the transition from the triplet state back to the singlet state. This type of delayed fluorescence is also known as thermally activated delayed fluorescence (TADF). A distinctive feature of TADF is that the delayed component increases as temperature rises due to the increased thermal energy. If the reverse intersystem crossing rate is fast enough to minimize the non-radiative decay from the triplet state, the fraction of back populated singlet excited states can potentially reach 75%. The total singlet fraction can be 100%, far exceeding the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (ΔFS-T). Organic, non-metal containing, donor-acceptor luminescent materials may be able to achieve this. The emission in these materials is often characterized as a donor-acceptor charge-transfer (CT) type emission. The spatial separation of the HOMO and LUMO in these donor-acceptor type compounds often results in small ΔFS-T. These states may involve CT states. Often, donor-acceptor luminescent materials are constructed by connecting an electron donor moiety such as amino- or carbazole-derivatives and an electron acceptor moiety such as N-containing six-membered aromatic ring.

Devices fabricated in accordance with embodiments of the invention can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the invention can be incorporated into a wide variety of consumer products that have one or more of the electronic component modules (or units) incorporated therein. A consumer product comprising an OLED that includes the compound of the present disclosure in the organic layer in the OLED is disclosed. Such consumer products would include any kind of products that include one or more light source(s) and/or one or more of some type of visual displays. Some examples of such consumer products include a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video walls comprising multiple displays tiled together, a theater or stadium screen, and a sign. Various control mechanisms may be used to control devices fabricated in accordance with the present invention, including passive matrix and active matrix. Many of the devices are intended for use in a temperature range comfortable to humans, such as 18 C to 30 C, and more preferably at room temperature (20-25 C), but could be used outside this temperature range, for example, from −40 C to 80 C.

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

In one aspect, the present disclosure relates to A hybrid inorganic-organic light emitting device, comprising: a cathode; an anode; at least one organic layer disposed between the cathode and the anode, wherein the at least one organic layer comprises an emissive material; at least one additional layer selected from the group consisting of an electron injection layer, an electron transport layer, and a hole blocking layer; wherein the at least one additional layer is disposed between the cathode and the at least one organic layer; and wherein the at least one additional layer comprises at least one metal oxide.

In one embodiment, the at least one additional layer comprises metal oxide nanoparticles. In one embodiment, the metal oxide nanoparticles have an average diameter between 1 nm and 10 nm. In one embodiment, the at least one metal oxide comprises a compound selected from the group consisting of zinc oxide (ZnO), tin oxide (SnOx), and titanium oxide (TiOx). In one embodiment, at least one metal oxide comprises zinc oxide (ZnO).

In one embodiment, the at least one additional layer comprises at least one metal oxide selected from the group consisting of zinc oxide (ZnO), tin oxide (SnOx), and titanium oxide (TiOx); and at least one additional salt having the formula MXₙ or MYₘ; wherein M is selected from the group consisting of Cs⁺, Li⁺, Na⁺, and Al³⁺; X is selected from the group consisting of Br, Cl, and F; Y is selected from the group consisting of CO₃²⁻, and SO₄²⁻; n is an integer equal to the charge on the metal M; and m is equal to the charge on the metal M, divided by 2. In one embodiment, the at least one metal oxide comprises an aluminum, gallium, magnesium, or lithium dopant.

In one embodiment, the device comprises an interlayer thin film, disposed between the at least one additional layer and the at least one organic layer, wherein the interlayer thin film has a thickness between 1 and 5 nm. In one embodiment, the interlayer thin film comprises a metal selected from the group consisting of aluminum, lithium, magnesium, and gallium. In one embodiment, the interlayer thin film comprises a metal salt selected form the group consisting of cesium bromide, cesium chloride, cesium carbonate, lithium chloride, lithium bromide, lithium carbonate, lead chloride, lead bromide, and lead carbonate. In one embodiment, the interlayer thin film comprises aluminum metal.

In one embodiment, the interlayer thin film has a thickness between 1 and 3 nm. In one embodiment, the interlayer thin film has a thickness of about 1 nm. In one embodiment, the interlayer thin film has a thickness of about 2 nm. In one embodiment, the interlayer thin film has a thickness of about 3 nm.

In one embodiment, the emissive material comprises a tetracoordinate metal complex selected from the group consisting of Au(I), Ir(I), Rh (I), Pt(II), and Pd(II). In one embodiment, the emissive material is neutral. In one embodiment, the emissive material comprises a tetradentate ligand

In one embodiment, the emissive material has a structure represented by General Formula I or General Formula II:

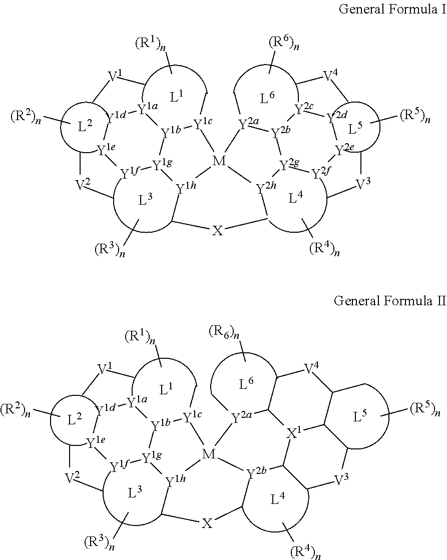

wherein, in General Formula I and General Formula II:
M represents Pt(II), Pd(II), Ir(I), Rh(I), Au(III);
Y^{1a}, Y^{1b}, Y^{1c}, Y^{1f}, Y^{1g}, Y^{1h}, Y^{2a}, Y^{2b}, Y^{2c}, Y^{2f}, Y^{2g}, Y^{2h} each independently represents C or N;
Y^{1d}, Y^{1e}, Y^{2d}, Y^{2e} each is independently absent or present, and if present, Y^{1d}, Y^{1e}, Y^{2d}, Y^{2e} each independently represents C or N;
X and X¹ each is independently present or absent, and, if present, each of X and X¹ independently represents C, N, Si, O, S, Ge, P, As, Se, B, Al, or Bi, or if valency permits, each independently represents CR⁷, SiR⁷, GeR⁷, NR⁷, P═O, As═O, B, BR⁷, AlR⁷, Bi═O, CR⁷R⁸, C═O, SiR⁷R⁸, GeR⁷R ⁸, PR⁷, PR⁷R⁸, R⁷P═O, AsR⁷, R⁷As═O, S═O, SO₂, Se═O, SeO₂, BR⁷R⁸, AlR⁷R⁸, R⁷Bi═O, or BiR⁷;
R¹, R², R³, R⁴, R⁵, R⁶, R⁷, and R⁸ each is independently absent or present as a single substituent or multiple substituents, valency permitting, and, if present, each of R¹, R², R³, R⁴, R⁵, R⁶, R⁷, and R⁸ independently represents hydrogen, deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof; wherein any two adjacent groups R¹, R², R³, R⁴, R⁵, R⁶, R⁷, or R⁸ may together join to form a ring
L¹, L³, L⁴, and L⁶ each independently represents a 5- to 10-membered aryl, heteroaryl, fused aryl, or fused heteroaryl;
L² and L⁵ each is independently present or absent, and, if present, L² and L⁵ each independently represents a 5- to 10-membered aryl, heteroaryl, fused aryl, or fused heteroaryl;
V¹, V², V³, V⁴ each is independently present, absent, or a covalent bond, and if present, each of V¹, V², V³, V⁴ independently represents C, N, Si, O, S, Ge, P, As, Se, B, Al, or Bi, or if valency permits, each independently represents CR⁷, SiR⁷, GeR⁷, NR⁷, P═O, As═O, B, BR⁷, AlR⁷, Bi═O, CR⁷R⁸, C═O, SiR⁷R⁸, GeR⁷R ⁸, PR⁷, PR⁷R⁸, R⁷P═O, AsR⁷, R⁷As═O, S═O, SO₂, Se═O, SeO₂, BR⁷R⁸, AlR⁷R⁸, R⁷Bi═O, or BiR⁷; and
each n is independently an integer, valency permitting.

In one embodiment, the emissive material has a structure represented by General Formula III, General Formula IV, General Formula V, or General Formula VI:

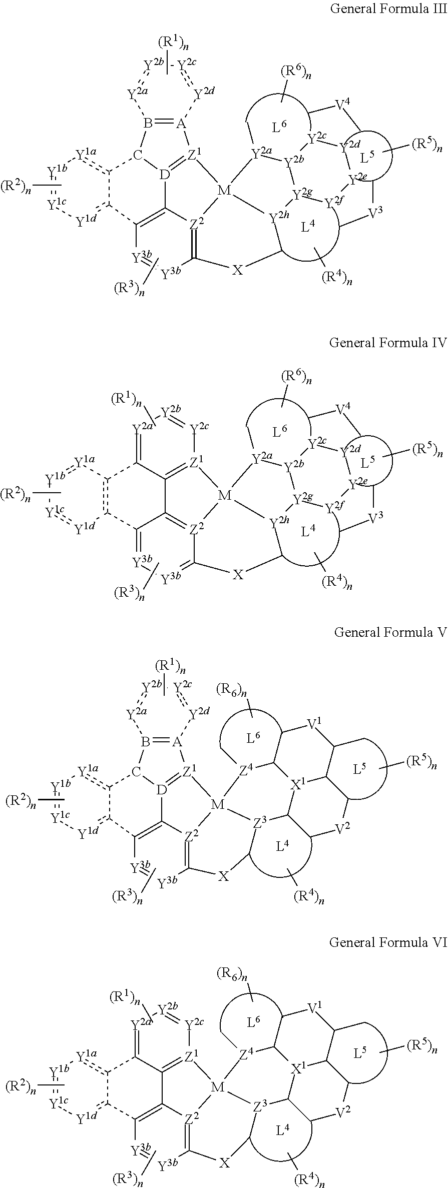

wherein, in General Formulas III-VI:
M represents Pt(II), Pd(II), Ir(I), Rh(I), or Au(III);
each Y^{1a}, Y^{1b}, Y^{1c}, Y^{1d}, Y^{2a}, Y^{2b}, Y^{2c}, Y^{2d}, Y^{2e}, Y^{2f}, Y^{3a}, Y^{3b}, Z¹, Z², Z³, and Z⁴ independently represents C or N;
X and X¹ each is independently present or absent, and, if present, each of X and X¹ independently represents C, N, Si, O, S, Ge, P, As, Se, B, Al, or Bi, or if valency permits, each independently represents CR⁷, SiR⁷, GeR⁷, NR⁷, P═O, As═O, B, BR⁷, AlR⁷, Bi═O, CR⁷R⁸, C═O, SiR⁷R⁸, GeR⁷R ⁸, PR⁷, PR⁷R⁸, R⁷P═O, AsR⁷, R⁷As═O, S═O, SO₂, Se═O, SeO₂, BR⁷R⁸, AlR⁷R⁸, R⁷Bi═O, or BiR⁷
A, B, C, and D each independently represents C, N, O, or S;
R¹, R², R³, R⁴, R⁵, R⁶, R⁷, and R⁸ each is independently absent or present as a single substituent or multiple substituents, valency permitting, and, if present, each of R¹, R², R³, R⁴, R⁵, R⁶, R⁷, and R⁸ independently represents hydrogen, deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof;
L⁴, L⁵, and L⁶ each independently represents a 5- to 10-membered aryl, heteroaryl, fused aryl, or fused heteroaryl;
V¹ and V² each is independently present, absent, or a covalent bond, and if present, each of V¹ and V² independently represents C, N, Si, O, S, Ge, P, As, Se, B, Al, or Bi, or if valency permits, each independently represents CR⁷, SiR⁷, GeR⁷, NR⁷, P═O, As═O, B, BR⁷, AlR⁷, Bi═O, CR⁷R⁸, C═O, SiR⁷R⁸, GeR⁷R ⁸, PR⁷, PR⁷R⁸, R⁷P═O, AsR⁷, R⁷As═O, S═O, SO₂, Se═O, SeO₂, BR⁷R⁸, AlR⁷R⁸, R⁷Bi═O, or BiR⁷; and
each n is independently an integer, valency permitting.

In one embodiment, the emissive material has a structure represented by one of the following compounds:

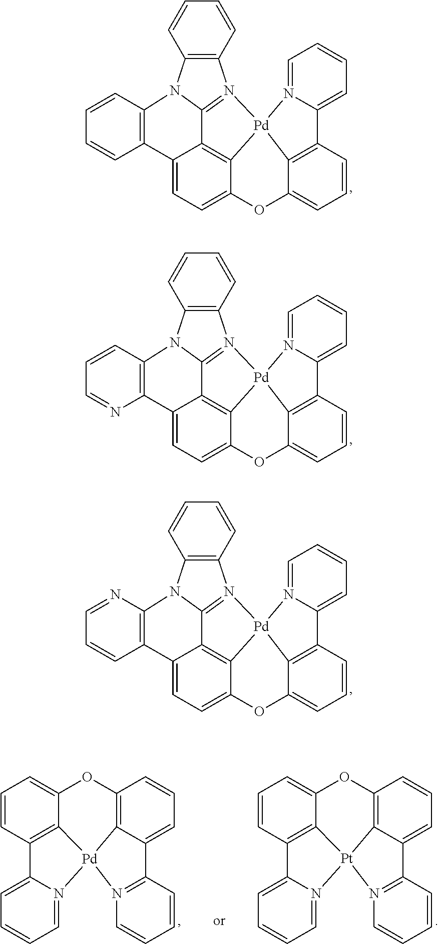

In one embodiment, the emissive material has a structure represented by General Formula A:

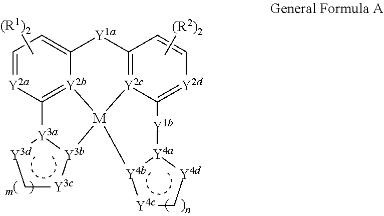

wherein:
M is Ir, Rh, Mn, Ni, Cu, or Ag;
each R¹ and R² is independently hydrogen, halogen, hydroxyl, nitro, thiol, or substituted or unsubstituted alkyl, alkenyl, alkynyl, aryl, heteroaryl, cycloalkane, cycloalkane, heterocyclyl, amino, alkoxy, haloalkyl, arylalkane, or arylalkene;
each of Y^{1a} and Y^{1b} is independently O, NR³, CR³R⁴, S, AsR³, BR³, PR³, P(O)R³, or SiR³R⁴, or a combination thereof, wherein each of R³ and R⁴ is independently hydrogen, halogen, hydroxyl, thiol, or substituted or unsubstituted alkyl, alkenyl, alkynyl, aryl, heteroaryl, cycloalkane, cycloalkane, heterocyclyl, amino, alkoxy, haloalkyl, arylalkane, mylalkene, or R³ and R⁴ together form C═O, wherein each of R³ and R⁴ is independently optionally linked to an adjacent ring structure, thereby forming a cyclic structure;
each of Y^{2a}, Y^{2b}, Y^{2c}, and Y^{2d} is independently N or CR⁵, wherein R⁵ is hydrogen, halogen, hydroxyl, thiol, or substituted or unsubstituted alkyl, alkenyl, alkynyl, aryl, heteroaryl, cycloalkane, cycloalkane, heterocyclyl, amino, alkoxy, haloalkyl, arylalkane, or arylalkene;
each of Y^{3a}, Y^{3b}, Y^{3c}, Y^{3d}, Y^{4a}, Y^{4b}, Y^{4c}, and Y^{4d} is independently N, O, S, NR⁶, or CR⁷, wherein each of R⁶ and R⁷ is independently hydrogen, halogen, hydroxyl, thiol, or substituted or unsubstituted alkyl, alkenyl, alkynyl, aryl, heteroaryl, cycloalkane, cycloalkane, heterocyclyl, amino, alkoxy, haloalkyl, arylalkane, or arylalkene; or Z(R⁸)₂, wherein Z is C or Si, and wherein each R⁸ is independently hydrogen, halogen, hydroxyl, thiol, or substituted or unsubstituted alkyl, alkenyl, alkynyl, aryl, heteroaryl, cycloalkane, cycloalkane, heterocyclyl, amino, alkoxy, haloalkyl, arylalkane, or arylalkene;
each of m and n is independently 1 or 2; and
each

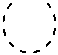

independently represents partial or full unsaturation of the ring with which it is associated.

In some cases, Y^{2b} is C; Y^{2c}, Y^{3b} and Y^{4b} are N, and M is Ir or Rh.

In some embodiments, the emissive material has a structure represented by General Formula B:

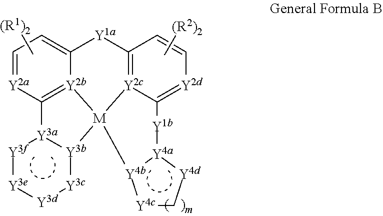

wherein:
M is Pt, Pd, or Au;
each of R¹ and R² is independently hydrogen, halogen, hydroxyl, nitro, thiol, or substituted or unsubstituted alkyl, alkenyl, alkynyl, aryl, heteroaryl, cycloalkane, cycloalkane, heterocyclyl, amino, alkoxy, haloalkyl, arylalkane, or arylalkene;
each of Y^{1a} and Y^{1b} is independently O, NR³, CR³R⁴, S, AsR³, BR³, PR³, P(O)R³, or SiR³R⁴, or a combination thereof, wherein each of R³ and R⁴ is independently hydrogen, halogen, hydroxyl, thiol, or substituted or unsubstituted alkyl, alkenyl, alkynyl, aryl, heteroaryl, cycloalkane, cycloalkane, heterocyclyl, amino, alkoxy, haloalkyl, arylalkane, arylalkene, or R³ and R⁴ together form C═O, wherein each of R³ and R⁴ is independently optionally linked to an adjacent ring structure, thereby forming a cyclic structure;
each of Y^{2a}, Y^{2b}, Y^{2c}, and Y^{2d}is independently N or CR₅, wherein R⁵ is hydrogen, halogen, hydroxyl, thiol, or substituted or unsubstituted alkyl, alkenyl, alkynyl, aryl, heteroaryl, cycloalkane, cycloalkane, heterocyclyl, amino, alkoxy, haloalkyl, arylalkane, or arylalkene;
each of Y^{3a}, Y^{3b}, Y^{3c}, Y^{3d}, Y^{3e}, Y^{3f}, Y^{4a}, Y^{4b}, Y^{4c}, and Y^{4d} is independently N, O, S, NR⁶, CR⁷, wherein each of R⁶ and R⁷ is independently hydrogen, halogen, hydroxyl, thiol, or substituted or unsubstituted alkyl, alkenyl, alkynyl, aryl, heteroaryl, cycloalkane, cycloalkane, heterocyclyl, amino, alkoxy, haloalkyl, arylalkane, or arylalkene; or Z(R⁸)₂, wherein Z is C or Si, and wherein each R⁸ is independently hydrogen, halogen, hydroxyl, thiol, or substituted or unsubstituted alkyl, alkenyl, alkynyl, aryl, heteroaryl, cycloalkane, cycloalkane, heterocyclyl, amino, alkoxy, haloalkyl, arylalkane, or arylalkene;
m is 1 or 2; and
each

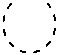

independently represents partial or full unsaturation of the ring with which it is associated.

In some cases, M is Pt or Pd, Y^{2b} and Y^{2c} are C, Y^{3b} and Y^{4b} are N, each of Y^{1a} and Y^{1b} is independently O, NR³, CR³R⁴, S, AsR³, BR³, PR³, P(O)R³, or SiR³R⁴, or a combination thereof, wherein each of R³ and R⁴ is independently hydrogen, halogen, hydroxyl, thiol, or substituted or unsubstituted alkyl, alkenyl, alkynyl, heteroaryl, cycloalkane, cycloalkane, heterocyclyl, amino, alkoxy, haloalkyl, arylalkane, arylalkene, or R³ and R⁴ together form C═O, wherein each of R³ and R⁴ is independently optionally linked to an adjacent ring structure, thereby forming a cyclic structure.

In some cases, M is Au, Y^{2b}, Y^{2c} and Y^{4b} are C , Y^{3b} is N, each of Y^{1a} and Y^{1b} is independently O, NR³, CR³R⁴, S, AsR³, BR³, PR³, P(O)R³, or SiR³R⁴, or a combination thereof, wherein each of R³ and R⁴ is independently hydrogen, halogen, hydroxyl, thiol, or substituted or unsubstituted alkyl, alkenyl, alkynyl, heteroaryl, cycloalkane, cycloalkane, heterocyclyl, amino, alkoxy, haloalkyl, arylalkane, arylalkene, or R³ and R⁴ together form C═O, wherein each of R³ and R⁴ is independently optionally linked to an adjacent ring structure, thereby forming a cyclic structure.

In some embodiments, the emissive material has a structure represented by General Formula C:

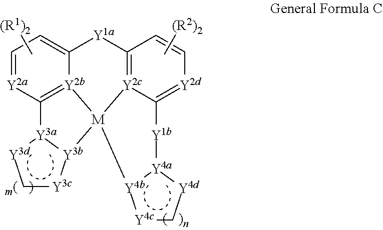

wherein:
M is Pt, Pd, Au, or Ag;
each of R¹ and R² is independently hydrogen, halogen, hydroxyl, nitro, thiol, or substituted or unsubstituted alkyl, alkenyl, alkynyl, aryl, heteroaryl, cycloalkane, cycloalkane, heterocyclyl, amino, alkoxy, haloalkyl, arylalkane, or arylalkene;
one of Y^{1a} and Y^{1b} is B(R³)₂ and the other of Y^{1a} and Y^{1b} is O, NR³, CR³R⁴, S, AsR³, BR³, PR³, P(O)R³, or SiR³R⁴, wherein each of R³ and R⁴ is independently hydrogen, halogen, hydroxyl, thiol, or substituted or unsubstituted alkyl, alkenyl, alkynyl, aryl, heteroaryl, cycloalkane, cycloalkane, heterocyclyl, amino, alkoxy, haloalkyl, arylalkane, arylalkene, or R³ and R⁴ together form C═O, wherein each of R³ and R⁴ is independently optionally linked to an adjacent ring structure, thereby forming a cyclic structure;
each of Y^{2a}, Y^{2b}, Y^{2c}, and Y^{2d} is independently N or CR⁵, wherein R⁵ is hydrogen, halogen, hydroxyl, thiol, or substituted or unsubstituted alkyl, alkenyl, alkynyl, aryl, heteroaryl, cycloalkane, cycloalkane, heterocyclyl, amino, alkoxy, haloalkyl, arylalkane, or arylalkene;
each of Y^{3a}, Y^{3b}, Y^{3c}, Y^{3d}, Y^{4a}, Y^{4b}, Y^{4c}, and Y^{4d} is independently N, O, S, NR⁶, CR⁷, wherein each of R⁶ and R⁷ independently hydrogen, halogen, hydroxyl, thiol, or substituted or unsubstituted alkyl, alkenyl, alkynyl, aryl, heteroaryl, cycloalkane, cycloalkane, heterocyclyl, amino, alkoxy, haloalkyl, arylalkane, or arylalkene; or Z(R⁸)₂, wherein Z is C or Si, and wherein each R⁸ is independently hydrogen, halogen, hydroxyl, thiol, or substituted or unsubstituted alkyl, alkenyl, alkynyl, aryl, heteroaryl, cycloalkane, cycloalkane, heterocyclyl, amino, alkoxy, haloalkyl, arylalkane, or arylalkene;
each of m and n is independently 1 or 2; and
each

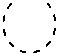

independently represents partial or full unsaturation of the ring with which it is associated.

In some embodiments, the emissive material has a structure represented by General Formula D:

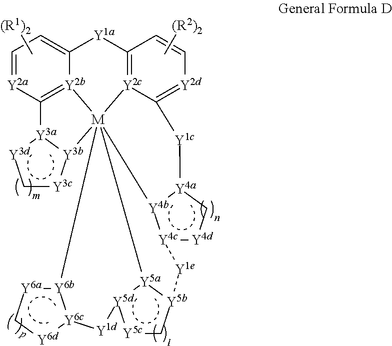

wherein:
M is Ir, Rh, Pt, Os, Zr, Co, or Ru;
each of R¹ and R² is independently hydrogen, halogen, hydroxyl, nitro, thiol, or substituted or unsubstituted alkyl, alkenyl, alkynyl, aryl, heteroaryl, cycloalkane, cycloalkane, heterocyclyl, amino, alkoxy, haloalkyl, arylalkane, or arylalkene;
each of Y^{1a}, Y^{1b}, Y^{1c} and Y^{1d} is independently O, NR³, CR³R⁴, S, AsR³, BR³, PR³, P(O)R³, or SiR³R⁴, wherein each of R³ and R⁴ is independently hydrogen, halogen, hydroxyl, thiol, or substituted or unsubstituted alkyl, alkenyl, alkynyl, aryl, heteroaryl, cycloalkane, cycloalkane, heterocyclyl, amino, alkoxy, haloalkyl, arylalkane, arylalkene, or R³ and R⁴ together form C═O, wherein each of R³ and R⁴ is independently optionally linked to an adjacent ring structure, thereby forming a cyclic structure;
Y^{1e}, if present, is O, NR³, CR³R⁴, S, AsR³, BR³, PR³, P(O)R³, or SiR³R⁴, wherein each of R³ and R⁴ is independently hydrogen, halogen, hydroxyl, thiol, or substituted or unsubstituted alkyl, alkenyl, alkynyl, heteroaryl, cycloalkane, cycloalkane, heterocyclyl, amino, alkoxy, haloalkyl, arylalkane, mylalkene, or R³ and R⁴ together form C═O, wherein each of R³ and R⁴ is independently optionally linked to an adjacent ring structure, thereby forming a cyclic structure;
each of Y^{2a}, Y^{2b}, Y^{2c} and Y^{2d} is independently N or CR⁵, wherein R⁵ is hydrogen, halogen, hydroxyl, thiol, or substituted or unsubstituted alkyl, alkenyl, alkynyl, aryl, heteroaryl, cycloalkane, cycloalkane, heterocyclyl, amino, alkoxy, haloalkyl, arylalkane, or arylalkene;
each of Y^{3a}, Y^{3b}, Y^{3c}, Y^{3d}, Y^{3e}, Y^{4a}, Y^{4b}, Y^{4c}, and Y^{4d} is independently N, O, S, NR⁶, or CR⁷, wherein each of R⁶ and R⁷ is independently hydrogen, halogen, hydroxyl, thiol, or substituted or unsubstituted alkyl, alkenyl, alkynyl, aryl, heteroaryl, cycloalkane, cycloalkane, heterocyclyl, amino, alkoxy, haloalkyl, arylalkane, or arylalkene; or Z(R⁸)₂, wherein Z is C or Si, and wherein each R⁸ is independently hydrogen, halogen, hydroxyl, thiol, or substituted or unsubstituted alkyl, alkenyl, alkynyl, aryl, heteroaryl, cycloalkane, cycloalkane, heterocyclyl, amino, alkoxy, haloalkyl, arylalkane, or arylalkene;
each of Y^{5a}, Y^{5b}, Y^{5c}, Y^{5d}, Y^{6a}, Y^{6b}, Y^{6c}, and Y^{6d} is independently N, O, S, NR⁵, or CR⁶;
each of m, n, l, and p is independently 1 or 2; and
each

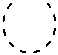

independently represents partial or full unsaturation of the ring with which it is associated.

In some embodiments, the emissive material has a structure represented by General Formula E:

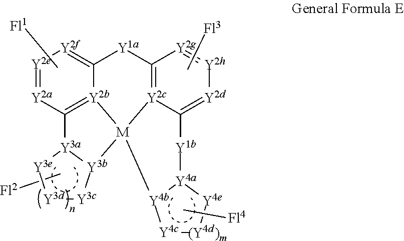

wherein:
M is Pt, Pd, Ir, Rh, Au, Co, Mn, Ni, Ag, or Cu;
each of Y^{1a} and Y^{1b} is independently O, NR³, CR³R⁴, S, AsR³, BR³, PR³, P(O)R³, or SiR³R⁴, wherein each of R³ and R⁴ is independently hydrogen, halogen, hydroxyl, thiol, or substituted or unsubstituted alkyl, alkenyl, alkynyl, aryl, heteroaryl, cycloalkane, cycloalkane, heterocyclyl, amino, alkoxy, haloalkyl, arylalkane, mylalkene, or R³ and R⁴ together form C═O, wherein each of R³ and R⁴ is independently optionally linked to an adjacent ring structure, thereby forming a cyclic structure;
each of Y^{2a}, Y^{2b}, Y^{2c}, Y^{2d}, Y^{2e}, Y^{2f}, Y^{2g}, and Y^{2h} is independently N or CR⁵, wherein R⁵ is hydrogen, halogen, hydroxyl, thiol, or substituted or unsubstituted alkyl, alkenyl, alkynyl, aryl, heteroaryl, cycloalkane, cycloalkane, heterocyclyl, amino, alkoxy, haloalkyl, arylalkane, or arylalkene;
each of Y^{3a}, Y^{3b}, Y^{3c}, Y^{3d}, Y^{3e}, Y^{4a}, Y^{4b}, Y^{4c}, Y^{4d} and Y^{4e} is independently N, O, S, NR⁶, or CR⁷, wherein each of R⁶ and R⁷ independently hydrogen, halogen, hydroxyl, thiol, or substituted or unsubstituted alkyl, alkenyl, alkynyl, aryl, heteroaryl, cycloalkane, cycloalkane, heterocyclyl, amino, alkoxy, haloalkyl, arylalkane, or arylalkene; or Z(R⁸)₂, wherein Z is C or Si, and wherein each R⁸ is independently hydrogen, halogen, hydroxyl, thiol, or substituted or unsubstituted alkyl, alkenyl, alkynyl, aryl, heteroaryl, cycloalkane, cycloalkane, heterocyclyl, aminoalkoxy, haloalkyl, arylalkane, or arylalkene;
m is 1 or 2;
n is 1 or 2;
each

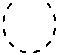

independently represents partial or full unsaturation of the ring with which it is associated; and
each of Fl¹, Fl², Fl³, and Fl⁴ is independently present or absent, with at least one of Fl¹, Fl², Fl³, and Fl⁴ present, and if present each of Fl¹, Fl², Fl³, and Fl⁴ is a fluorescent emitter covalently bonded to one of Y^{2a}, Y^{2d}, Y^{2e}, Y^{2f}, Y^{2g}, Y^{2h}, Y^{3c}, Y^{3d}, Y^{3e}, Y^{4c}, Y^{4d} and Y^{4e}.

In some cases, the energy of the singlet excited state(s) is slightly higher (0.2 eV or less) than the energy of the lowest triplet state, and metal-assisted delayed fluorescent emitter emits simultaneously from the lowest triplet state and the singlet excited state(s) at room temperature or elevated temperature. The metal-assisted delayed fluorescent emitter can harvest both electrogenerated singlet and triplet excitons.

In some embodiments, the at least one emissive layer comprises a fluorescent emitter having one of the following structures. In some embodiments, the emissive material has a substituent Fl¹, Fl², Fl³, and Fl⁴ having a structure selected from the following structures

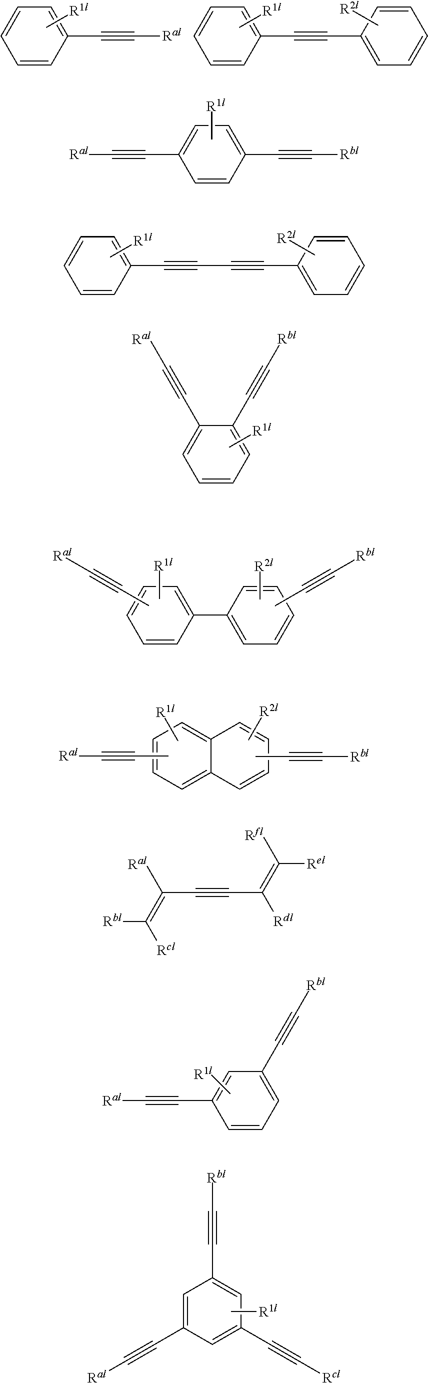

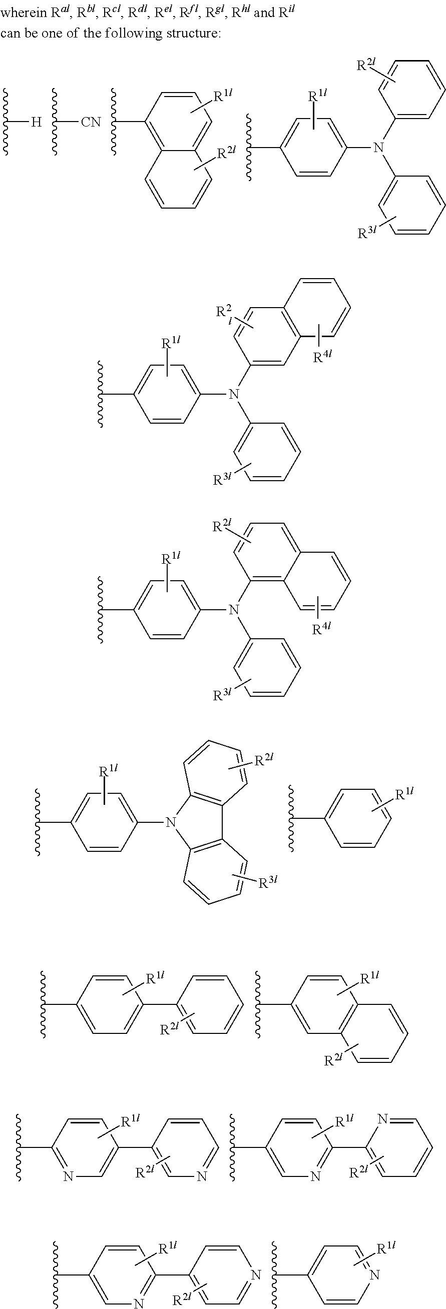

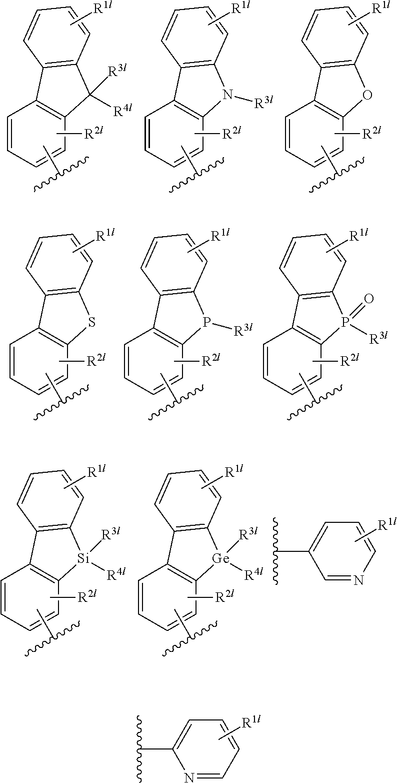

### 3. Heterocyclic Counnounds and Their Derivatives

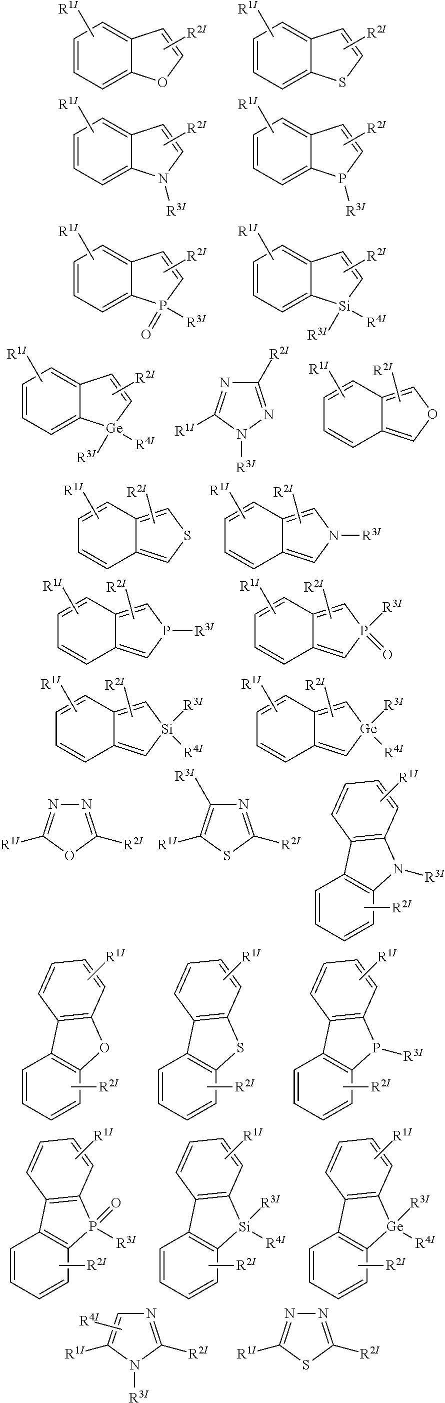

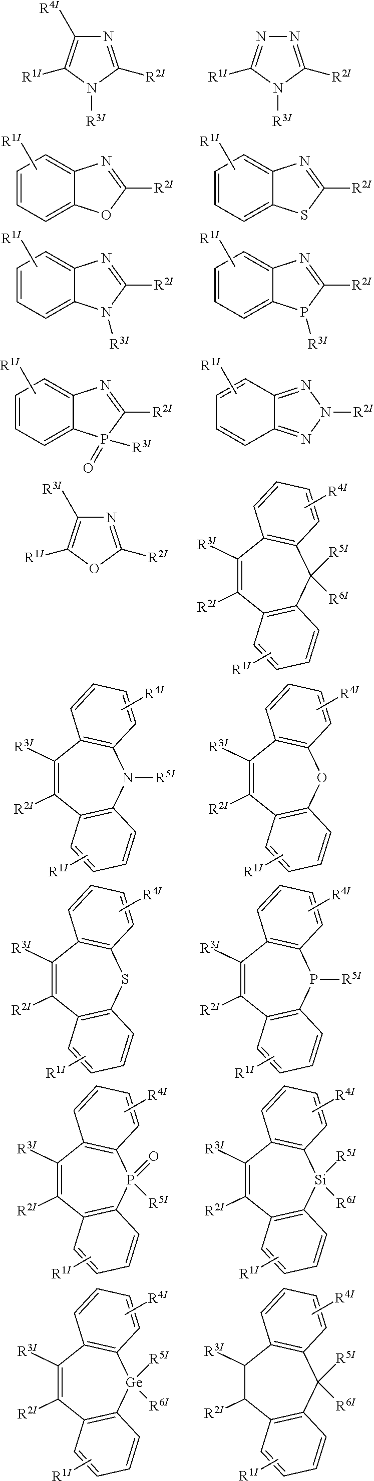

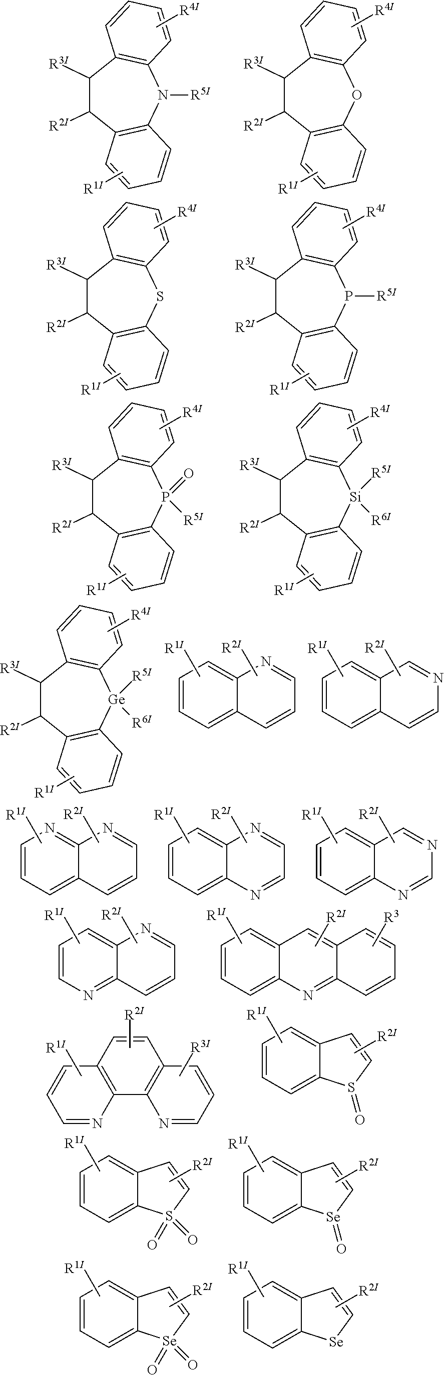

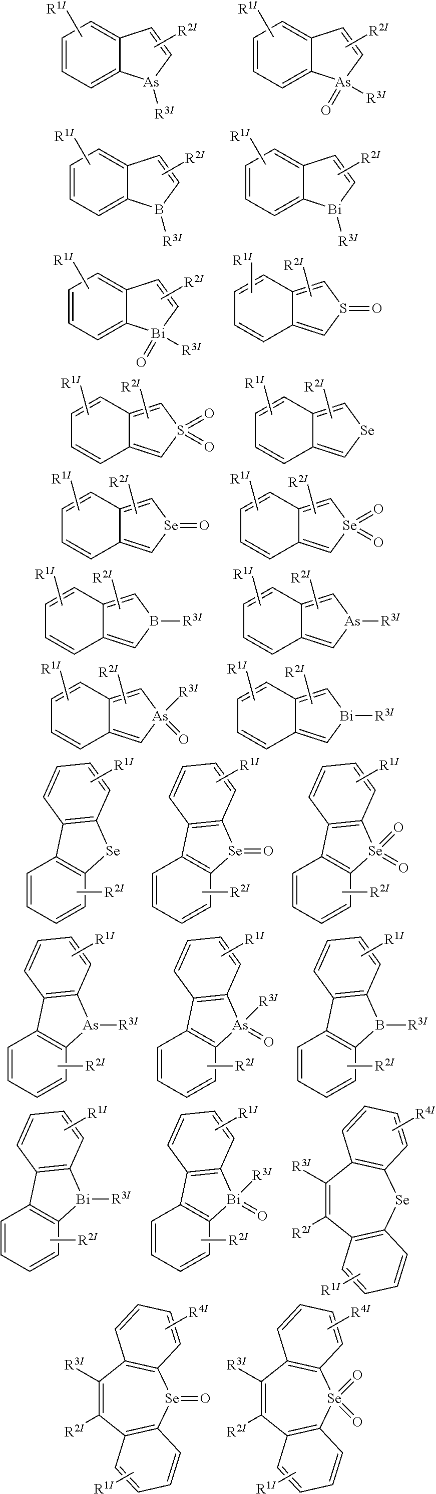

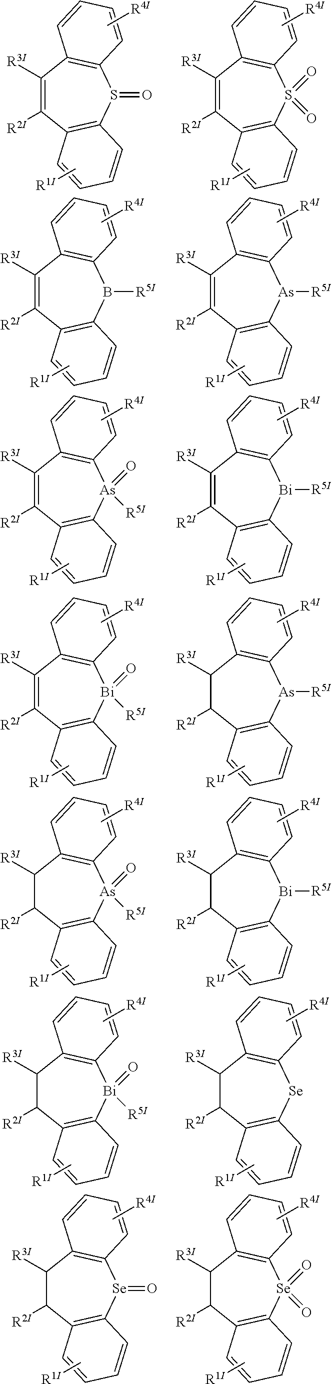

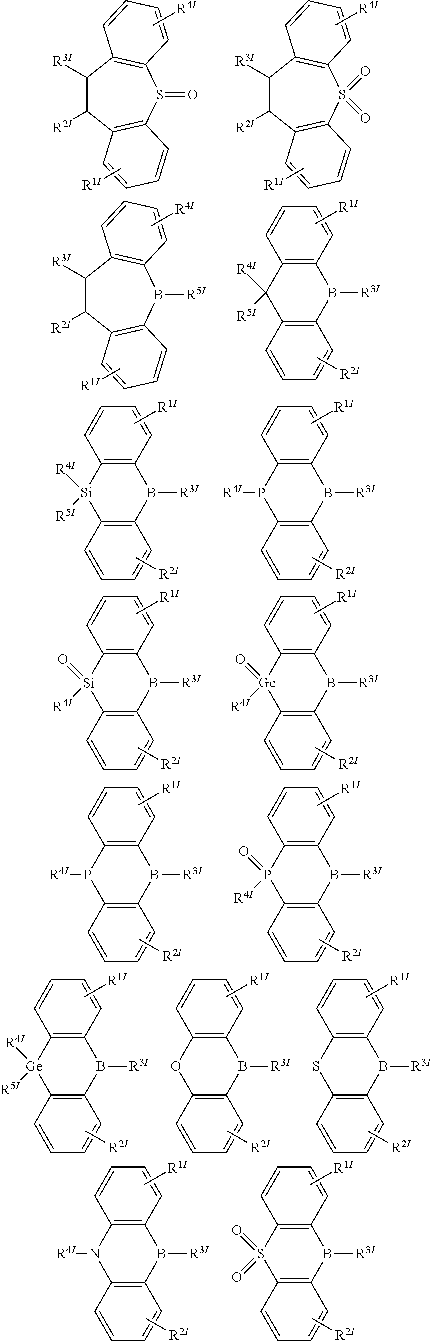

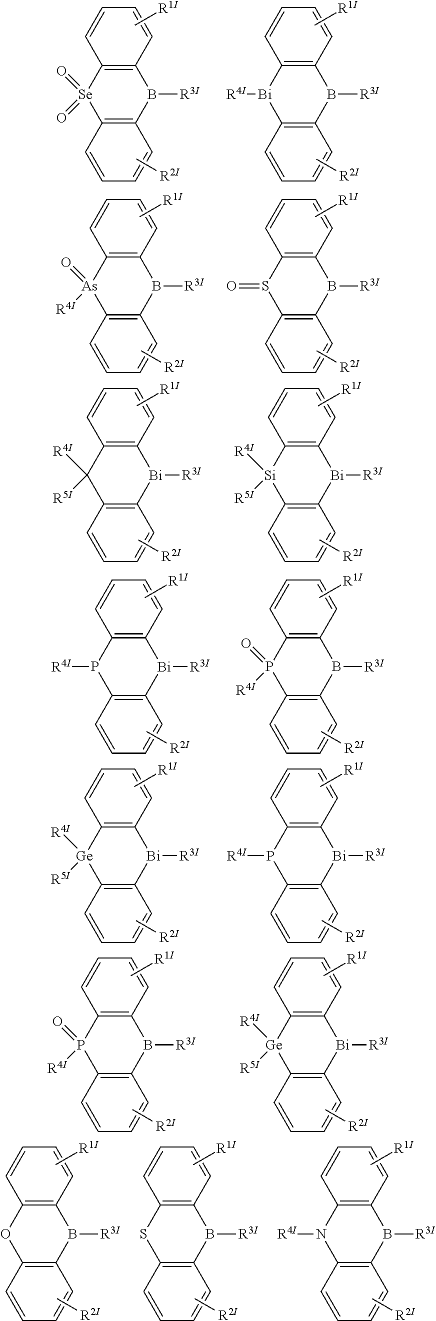

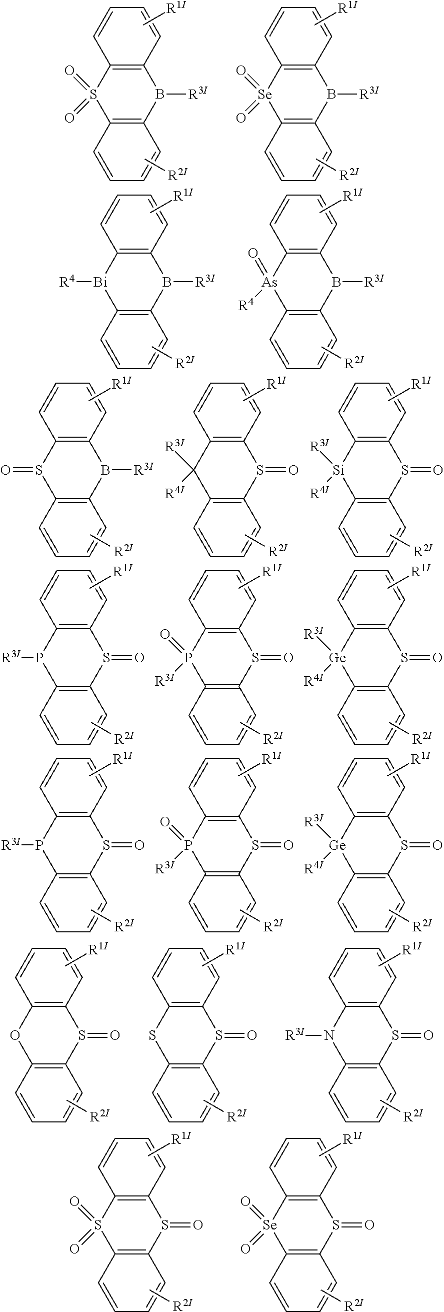

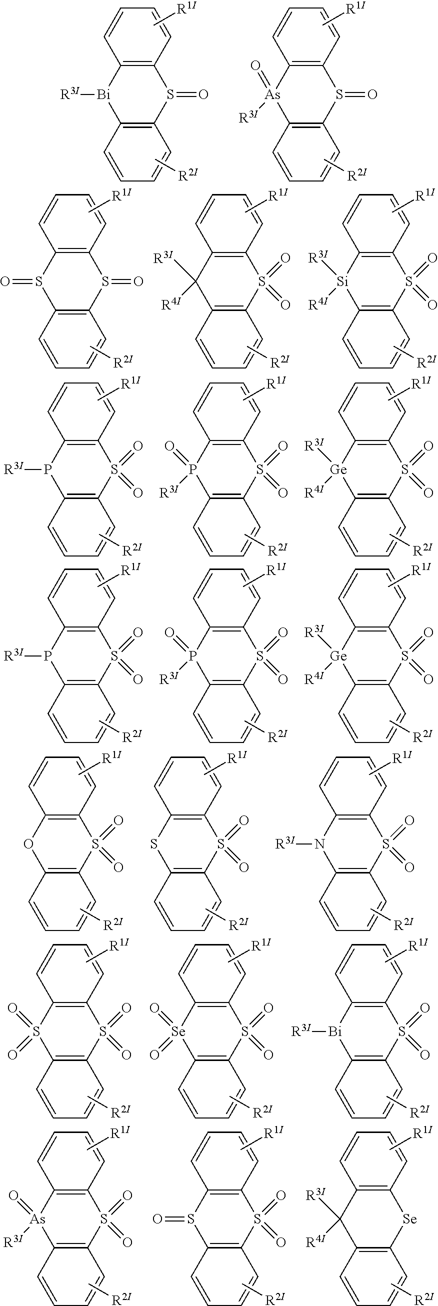

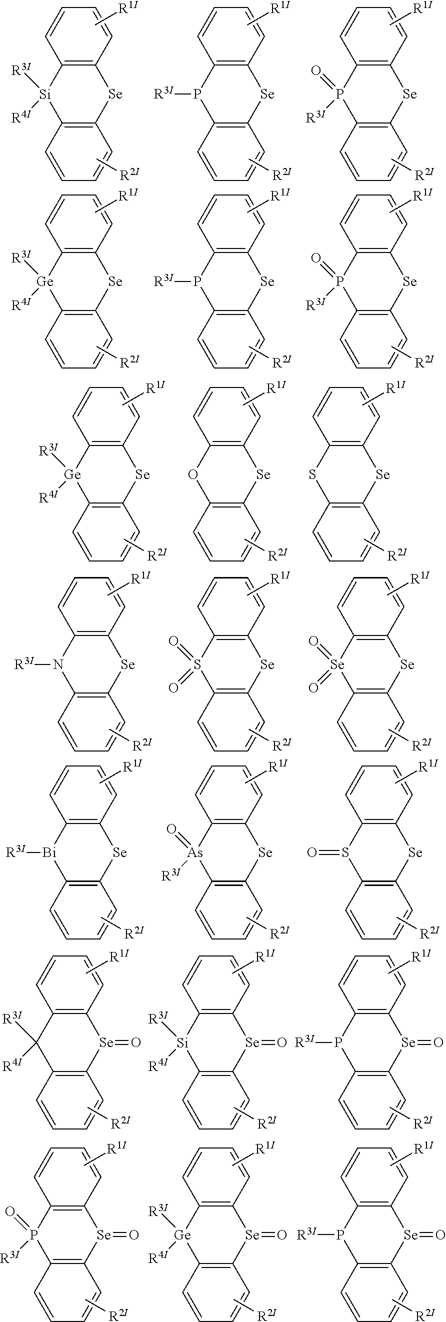

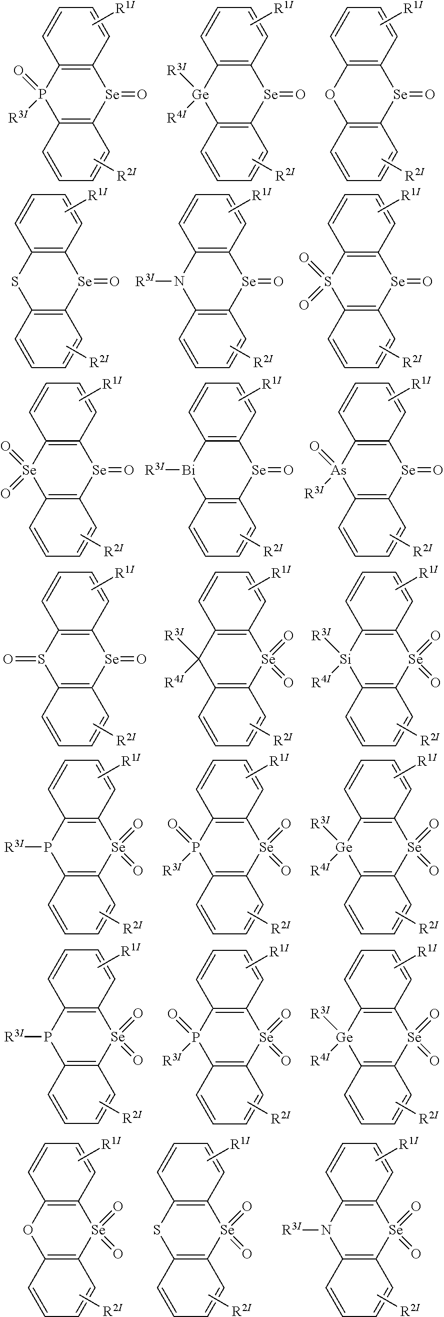

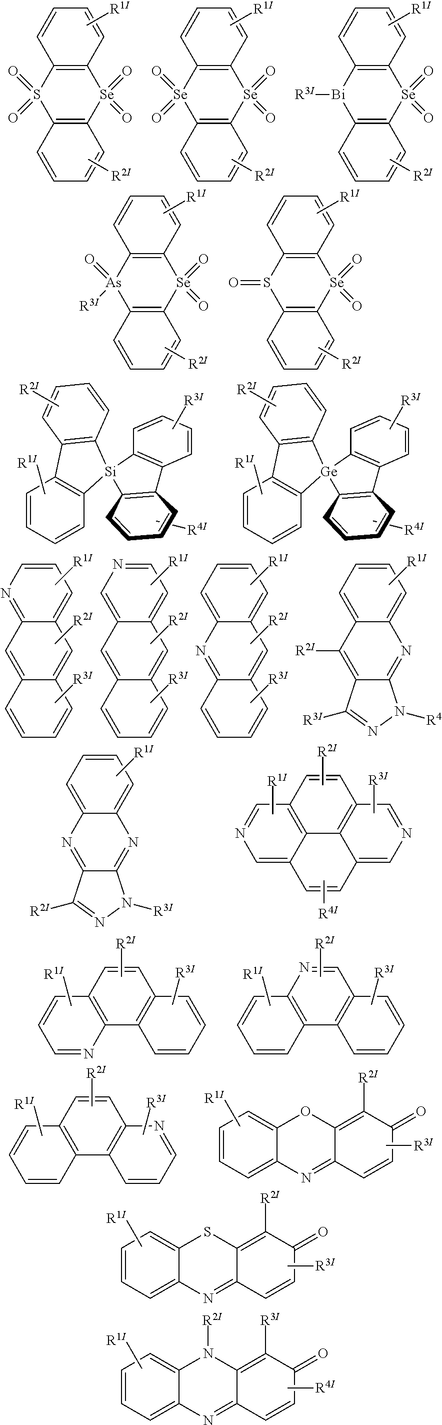

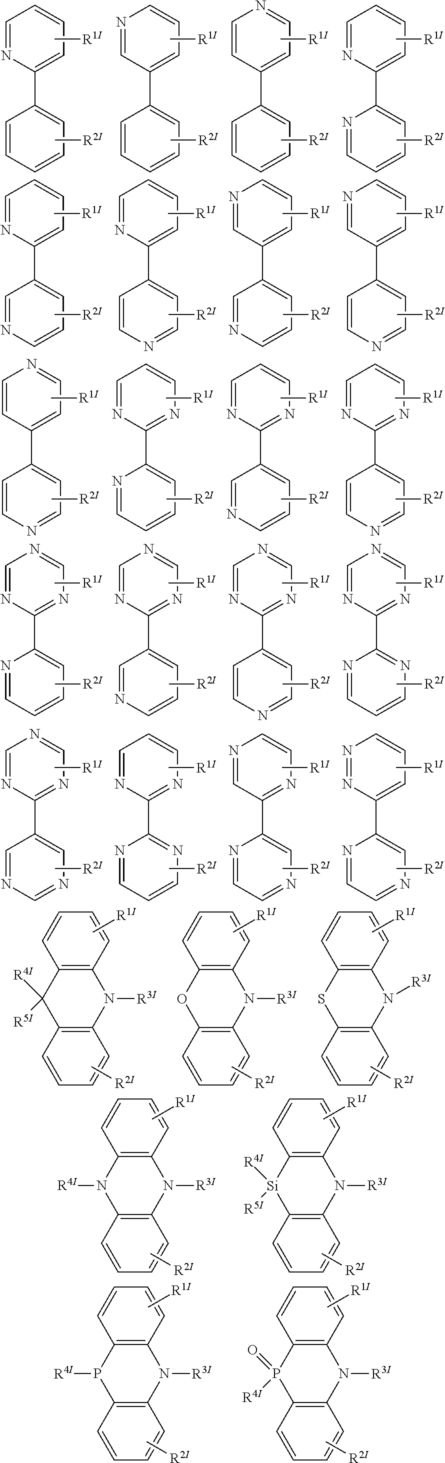

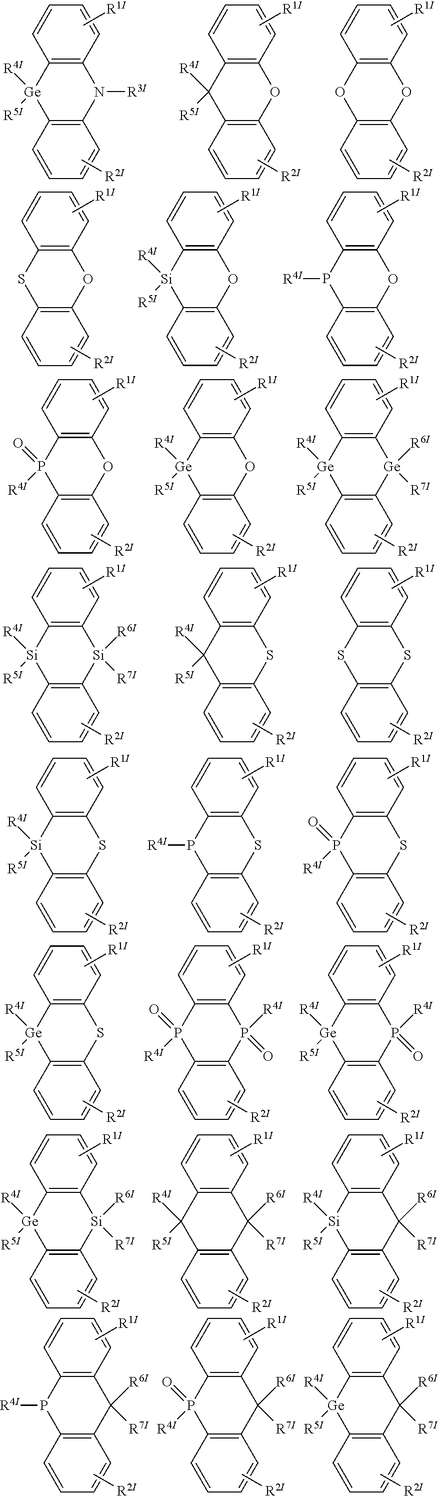

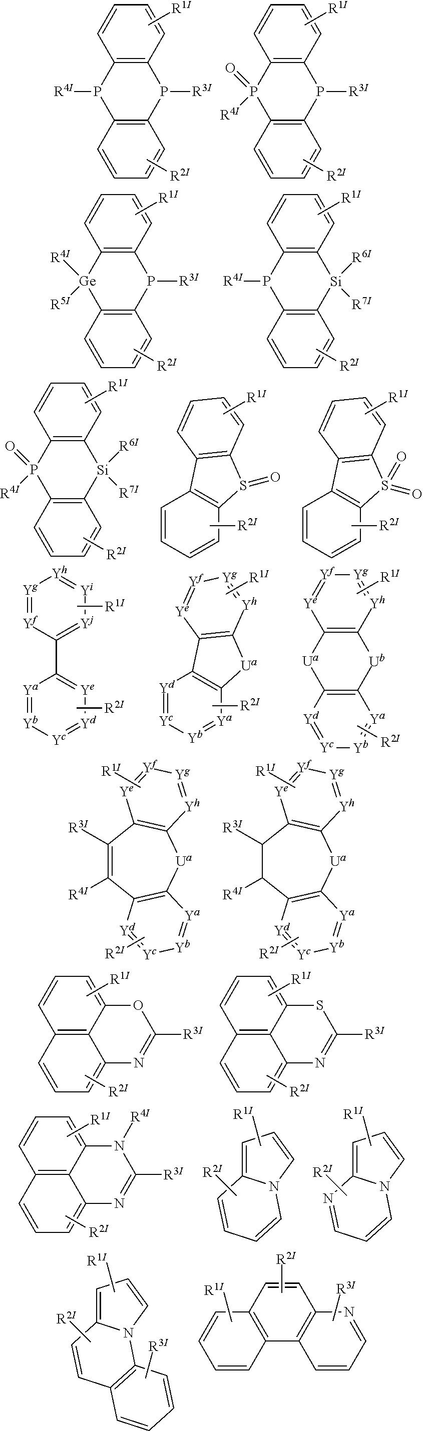

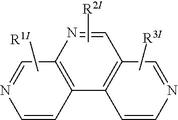

### 4. Other Fluorescent Luminophors

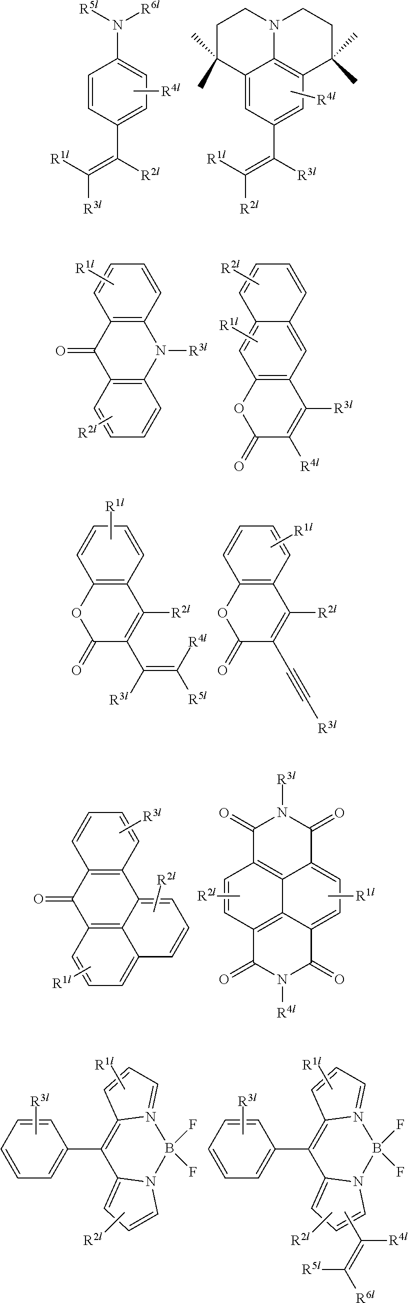

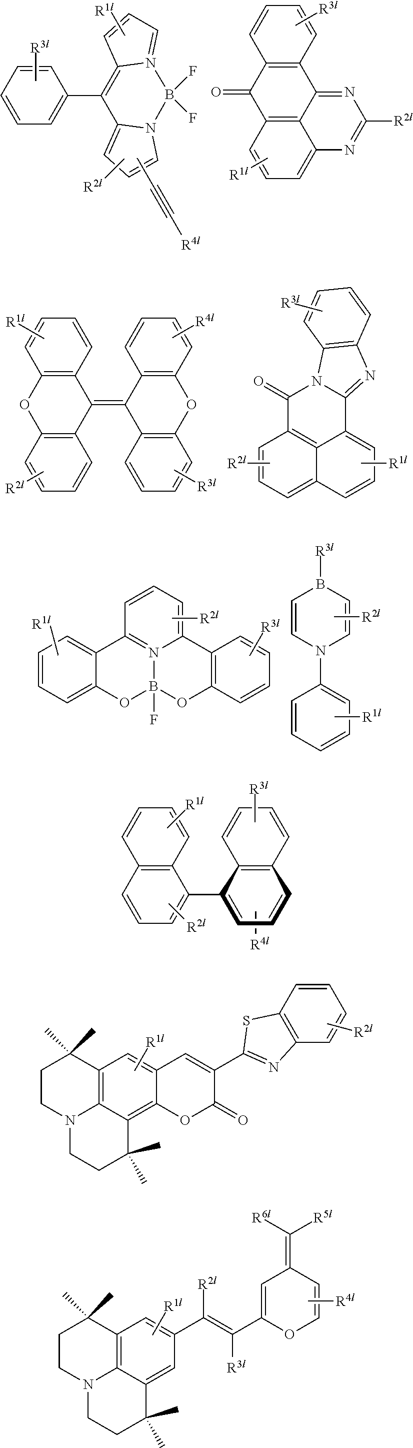

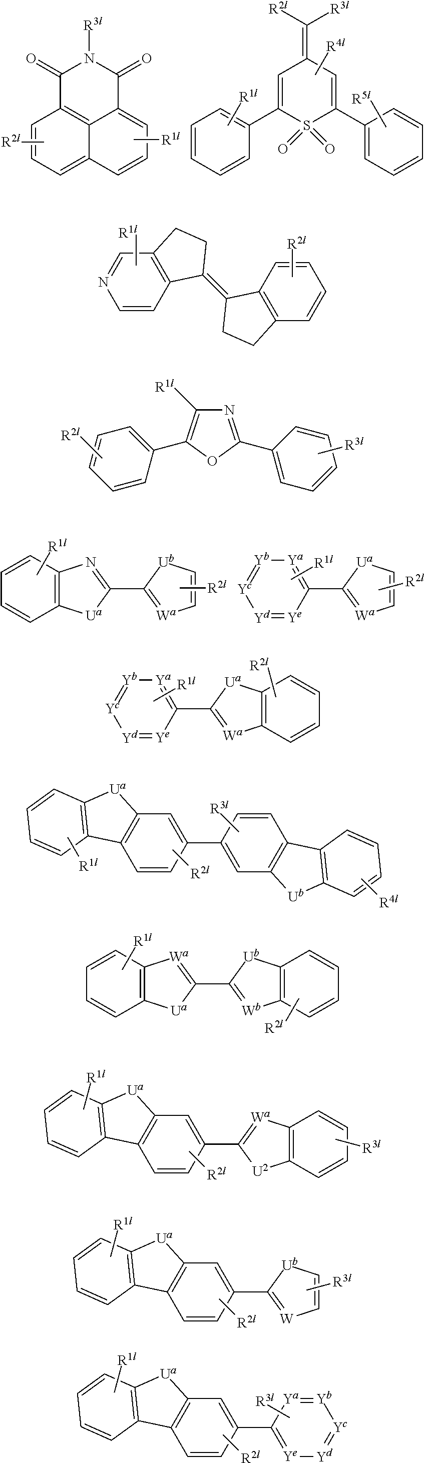

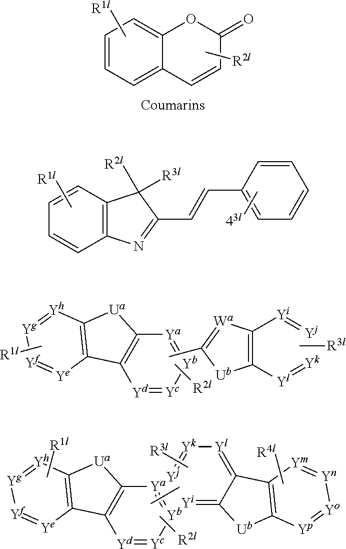

wherein:
each of R^{1I}, R^{2I}, R^{3I}, R^{4I}, R^{5I}, R^{6I}, R^{7I} and R^{8I} is independently hydrogen, deuterium, halogen, hydroxyl, thiol, nitro, cyano, nitrile, isonitrile, sulfinyl, mercapto, sulfo, carboxyl, hydrazino; substituted or unsubstituted: cycloalkyl, cycloalkenyl, heterocyclyl, heteroatyl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric, or any conjugate or combination thereof, and
each of Y^{a}, Y^{b}, Y^{c}, Y^{d}, Y^{e}, Y^{f}, Y^{g}, Y^{h}, Yⁱ, Y^{j}, Y^{k}, Y^{l}, Y^{m}, Yⁿ, Y^{o} and Y^{p} is independently C, N or B; and
each of Ua, Uh and Ue is independently CH₂, CRR, C═O, SiRR, GeH₂, GeRR, NH, NR, PH, PR, RP═O, AsR, RAs═O, O, S, S═O, SO₂, Se, Se═O, SeO₂, BH, BR, RBi═O, BiH, or BiR, wherein each R is independently hydrogen, deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric, or any conjugate or combination thereof.

In some embodiments, the OLED has one or more characteristics selected from the group consisting of being flexible, being rollable, being foldable, being stretchable, and being curved. In some embodiments, the OLED is transparent or semi-transparent. In some embodiments, the OLED further comprises a layer comprising carbon nanotubes.

In some embodiments, the OLED further comprises a layer comprising a delayed fluorescent emitter. In some embodiments, the OLED comprises a RGB pixel arrangement or white plus color filter pixel arrangement. In some embodiments, the OLED is a mobile device, a hand held device, or a wearable device. In some embodiments, the OLED is a display panel having less than 10 inch diagonal or 50 square inch area. In some embodiments, the OLED is a display panel having at least 10 inch diagonal or 50 square inch area. In some embodiments, the OLED is a lighting panel.

The OLED disclosed herein can be incorporated into one or more of a consumer product, an electronic component module, and a lighting panel. The organic layer can be an emissive layer and the compound can be an emissive dopant in some embodiments, while the compound can be a non-emissive dopant in other embodiments.

In some embodiments, the at least one organic layer further comprises a host.

In some embodiments, the organic layer may further comprise a host, wherein the host comprises a triphenylene containing benzo-fused thiophene or benzo-fused furan, wherein any substituent in the host is an unfused substituent independently selected from the group consisting of CₙH₂ₙ₊, OCₙH₂ₙ₊, OAr₁, N(CₙH₂ₙ₊₁)₂, N(Ar₁)(Ar₂), CH═CH—CₙH₂ₙ₊, C≡CₙH₂ₙ₊, Ar₁, Ar₁-Ar₂,CₙH₂ₙ—Ar₁, or no substitution, wherein n is an integer from 1 to 10; and wherein Ar₁ and Ar₂ are independently selected from the group consisting of benzene, biphenyl, naphthalene, triphenylene, carbazole, and heteroaromatic analogs thereof.

In some embodiments, the organic layer may further comprise a host, wherein host comprises at least one chemical group selected from the group consisting of triphenylene, carbazole, indolocarbazole, dibenzothiophene, dibenzofuran, dibenzoselenophene, 5λ2-benzo[d]benzo[4,5]imidazo[3,2-a]imidazole, 5,9-dioxa-13b-boranaphtho[3,2,1-de]anthracene, triazine, botyl, silyl, aza-triphenylene, aza-carbazole, aza-indolocarbazole, aza-dibenzothiophene, aza-dibenzofuran, aza-dibenzoselenophene, aza-5λ2-benzo[d]benzo[4,5]imidazo[3,2-a]imidazole, and aza-(5,9-dioxa-13b-boranaphtho[3,2,1-de]anthracene).

In some embodiments, the host may be selected from the group consisting of:

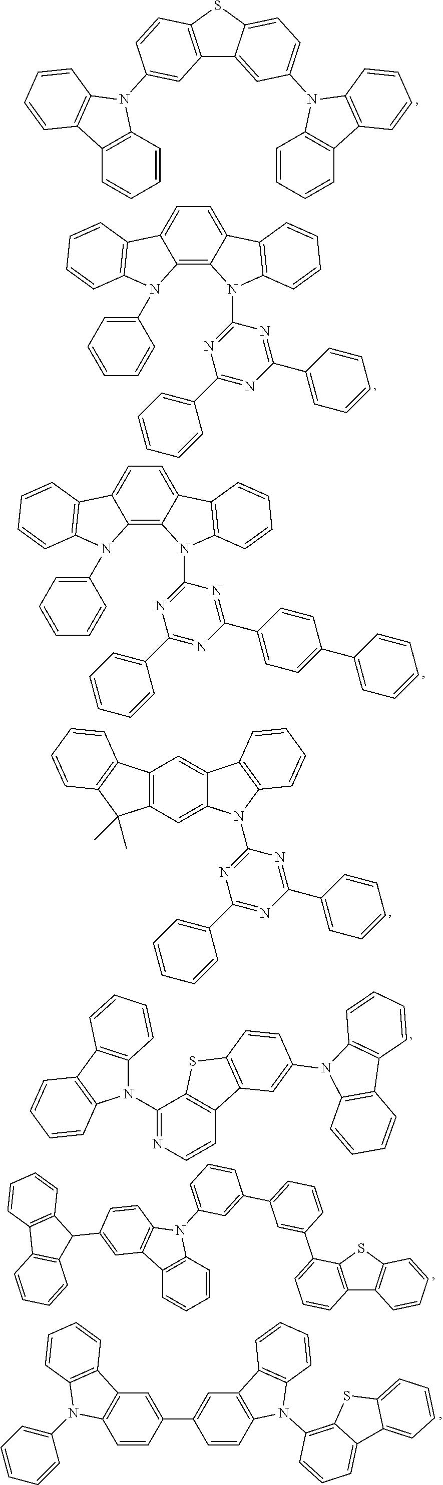

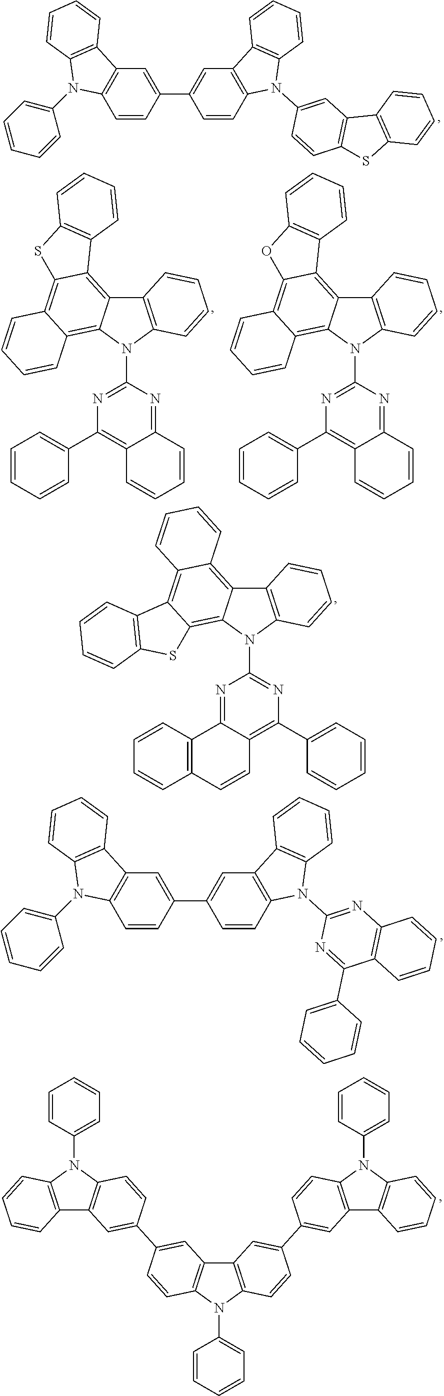

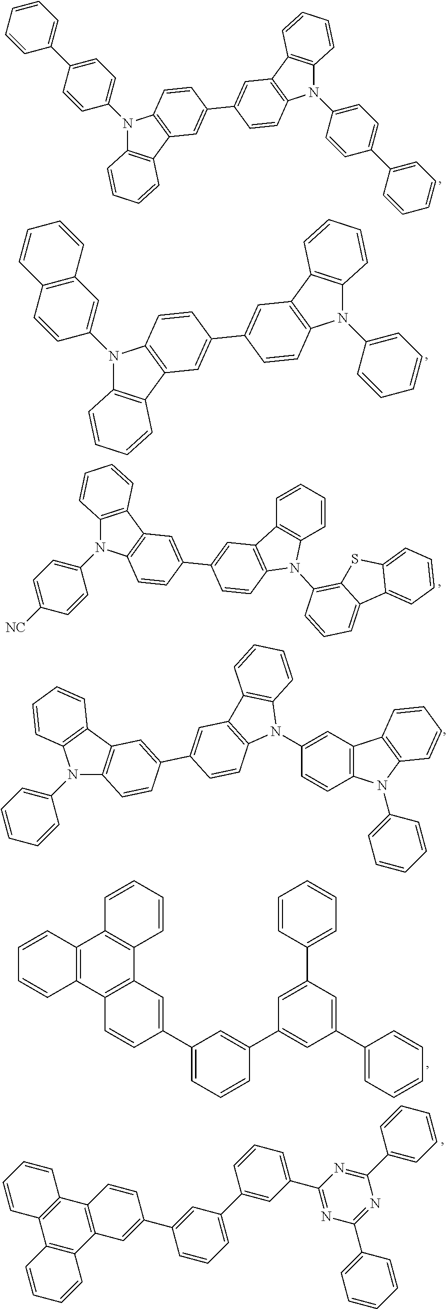

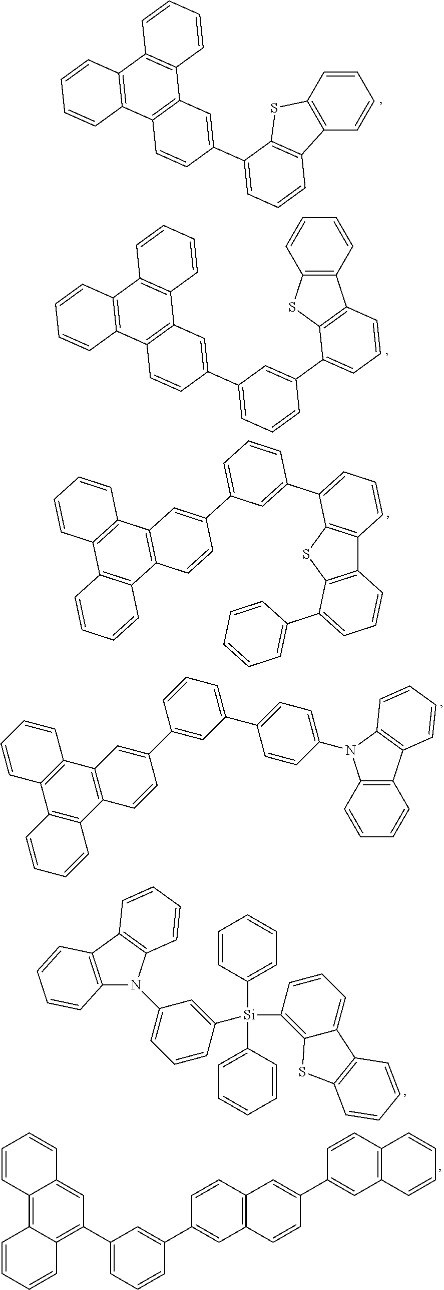

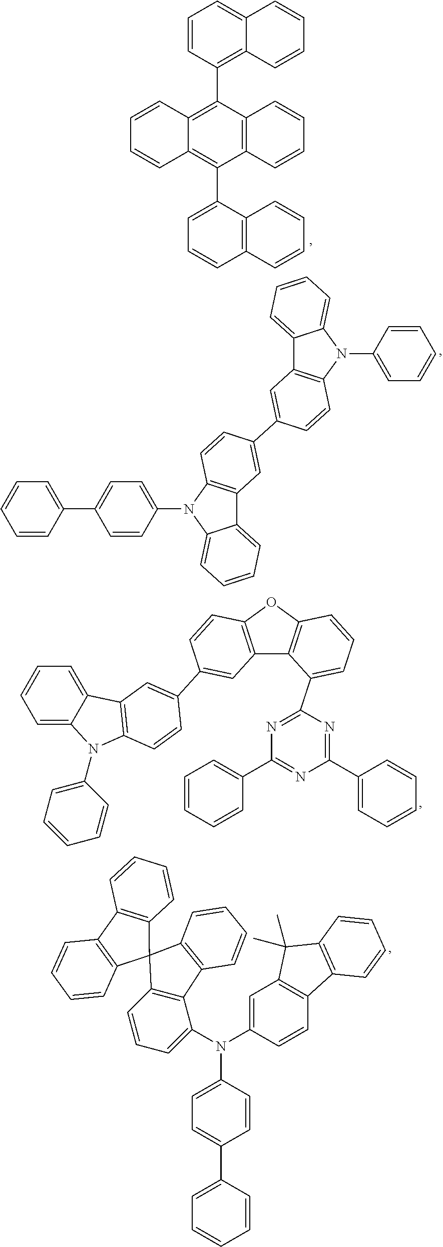

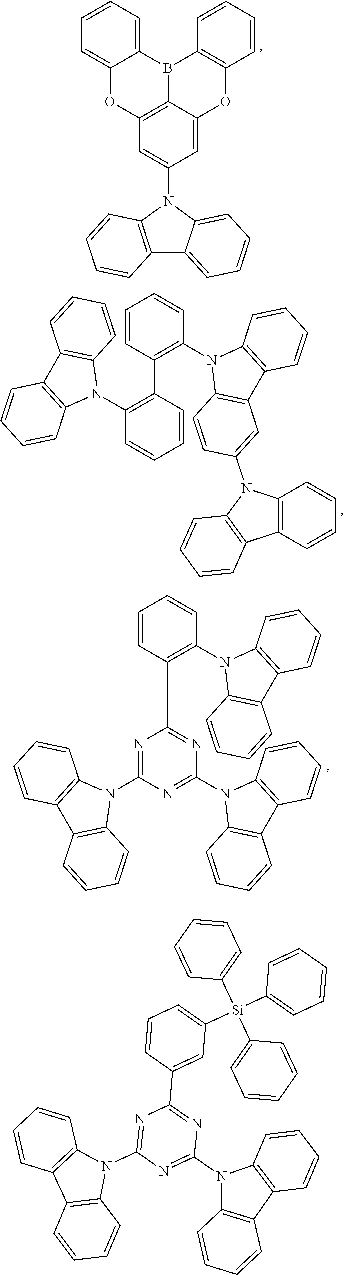

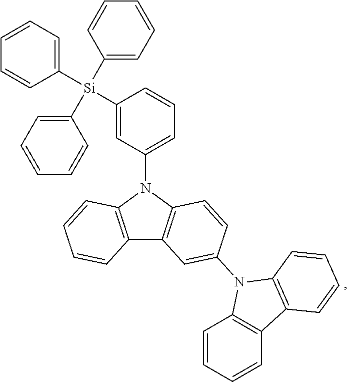 [SMILES: c1ccc([Si](c2ccccc2)(c2ccccc2)c2cccc(-n3c4ccccc4c4cc(-n5c6ccccc6c6ccccc65)ccc43)c2)cc1]

and combinations thereof.

In some embodiments, the organic layer may further comprise a host, wherein the host comprises a metal complex.

In some embodiments, the emissive layer can comprise two hosts, a first host and a second host. In some embodiments, the first host is a hole transporting host, and the second host is an electron transporting host. In some embodiments, the first host and the second host can form an exciplex.

In some embodiments, any compound described herein may be a sensitizer; wherein the device may further comprise an acceptor; and wherein the acceptor may be selected from the group consisting of fluorescent emitter, delayed fluorescence emitter, and combination thereof.

Combination of the Compounds of the Present Disclosure with Other Materials

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

### Conductivity Dopants:

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

Non-limiting examples of the conductivity dopants that may be used in an OLED in combination with materials disclosed herein are exemplified below together with references that disclose those materials: EP01617493, EP01968131, EP2020694, EP2684932, US20050139810, US20070160905, US20090167167, US2010288362, WO06081780, WO2009003455, WO2009008277, WO2009011327, WO2014009310, US2007252140, US2015060804, US20150123047, and US2012146012.

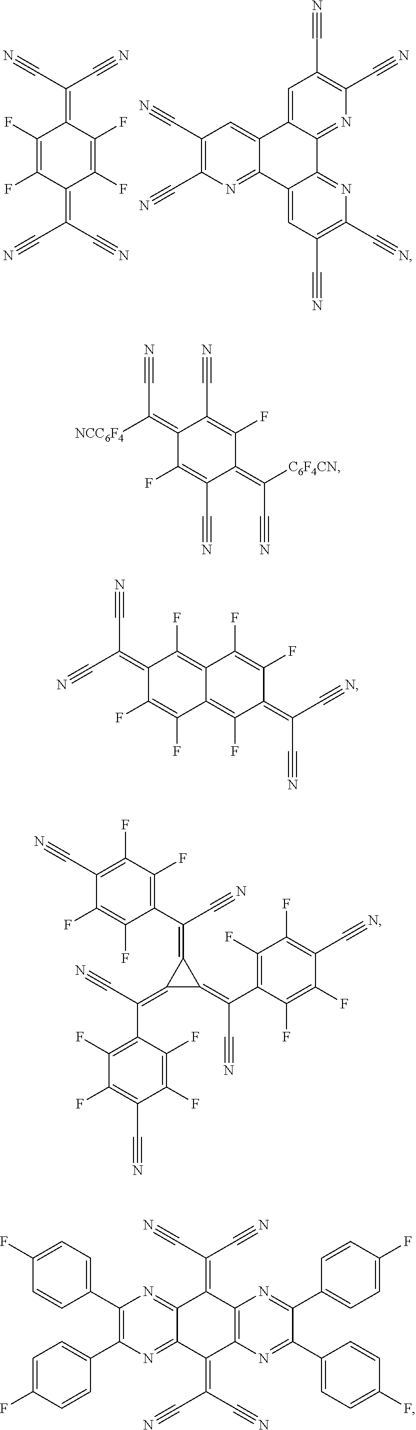

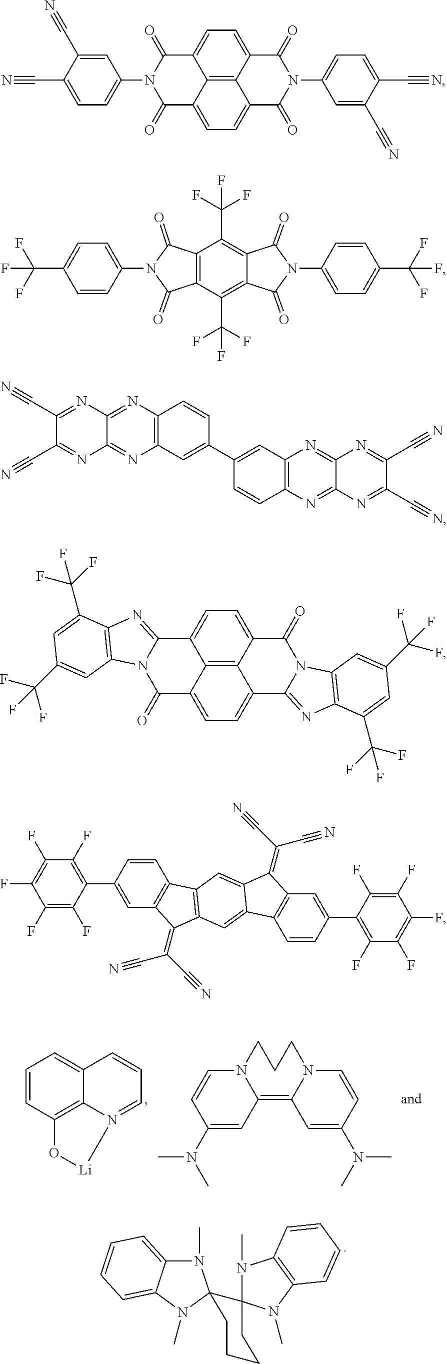

### HIL/HTL:

A hole injecting/transporting material to be used in the present disclosure is not particularly limited, and any compound may be used as long as the compound is typically used as a hole injecting/transporting material. Examples of the material include, but are not limited to: a phthalocyanine or porphyrin derivative; an aromatic amine derivative; an indolocarbazole derivative; a polymer containing fluorohydrocarbon; a polymer with conductivity dopants; a conducting polymer, such as PEDOT/PSS; a self-assembly monomer derived from compounds such as phosphoric acid and silane derivatives; a metal oxide derivative, such as MoOₓ; a p-type semiconducting organic compound, such as 1,4,5,8,9,12-Hexaazatriphenylenehexacarbonitrile; a metal complex, and a cross-linkable compounds.

Examples of aromatic amine derivatives used in HIL or HTL include, but not limit to the following general structures:

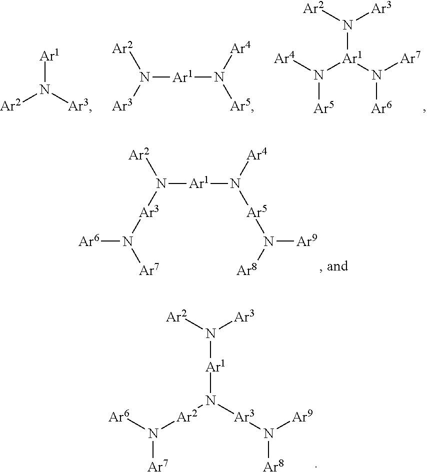

Each of Ar₁ to Ar₉ is selected from the group consisting of aromatic hydrocarbon cyclic compounds such as benzene, biphenyl, triphenyl, triphenylene, naphthalene, anthracene, phenalene, phenanthrene, fluorene, pyrene, cluysene, petylene, and azulene; the group consisting of aromatic heterocyclic compounds such as dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine; and the group consisting of 2 to 10 cyclic structural units which are groups of the same type or different types selected from the aromatic hydrocarbon cyclic group and the aromatic heterocyclic group and are bonded to each other directly or via at least one of oxygen atom, nitrogen atom, sulfur atom, silicon atom, phosphorus atom, boron atom, chain structural unit and the aliphatic cyclic group. Each Ar may be unsubstituted or may be substituted by a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acids, ether, ester, nitrile, isonitrile, sulfanyl, sulfinyl, sulfonyl, phosphino, and combinations thereof.

In one aspect, Ar₁ to Ar₉ is independently selected from the group consisting of:

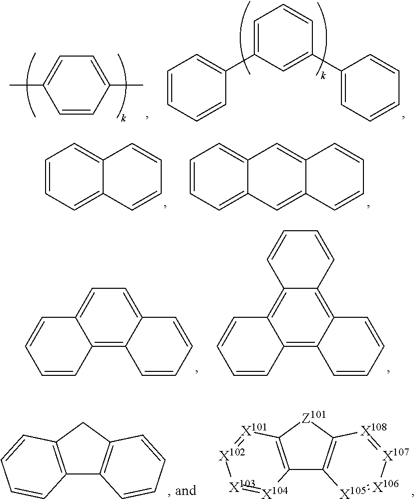

wherein k is an integer from 1 to 20; X₁₀₁ to X₁₀₈ is C (including CH) or N; Z₁₀₁ is NAr¹, O, or S; Ar¹ has the same group defined above.

Examples of metal complexes used in HIL or HTL include, but are not limited to the following general formula:

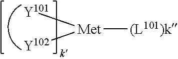

wherein Met is a metal, which can have an atomic weight greater than 40; (Y₁₀₁-Y₁₀₂) is a bidentate ligand, Y₁₀₁ and Y₁₀₂ are independently selected from C, N, O, P, and S; L₁₀₁ is an ancillary ligand; k′ is an integer value from 1 to the maximum number of ligands that may be attached to the metal; and k′+k″ is the maximum number of ligands that may be attached to the metal.

In one aspect, (Y₁₀₁-Y₁₀₂) is a 2-phenylpyridine derivative. In another aspect, (Y₁₀₁-Y₁₀₂) is a carbene ligand. In another aspect, Met is selected from Ir, Pt, Os, and Zn. In a further aspect, the metal complex has a smallest oxidation potential in solution vs. Fc⁺/Fc couple less than about 0.6 V.

Non-limiting examples of the HIL and HTL materials that may be used in an OLED in combination with materials disclosed herein are exemplified below together with references that disclose those materials: CN102702075, DE102012005215, EP01624500, EP01698613, EP01806334, EP01930964, EP01972613, EP01997799, EP02011790, EP02055700, EP02055701, EP1725079, EP2085382, EP2660300, EP650955, JP07-073529, JP2005112765, JP2007091719, JP2008021687, JP2014-009196, KR20110088898, KR20130077473, TW201139402, US06517957, US20020158242, US20030162053, US20050123751, US20060182993, US20060240279, US20070145888, US20070181874, US20070278938, US20080014464, US20080091025, US20080106190, US20080124572, US20080145707, US20080220265, US20080233434, US20080303417, US2008107919, US20090115320, US20090167161, US2009066235, US2011007385, US20110163302, US2011240968, US2011278551, US2012205642, US2013241401, US20140117329, US2014183517, U.S. Pat. Nos. 5,061,569, 5,639,914, WO05075451, WO07125714, WO08023550, WO08023759, WO2009145016, WO2010061824, WO2011075644, WO2012177006, WO2013018530, WO2013039073, WO2013087142, WO2013118812, WO2013120577, WO2013157367, WO2013175747, WO2014002873, WO2014015935, WO2014015937, WO2014030872, WO2014030921, WO2014034791, WO2014104514, WO2014157018.

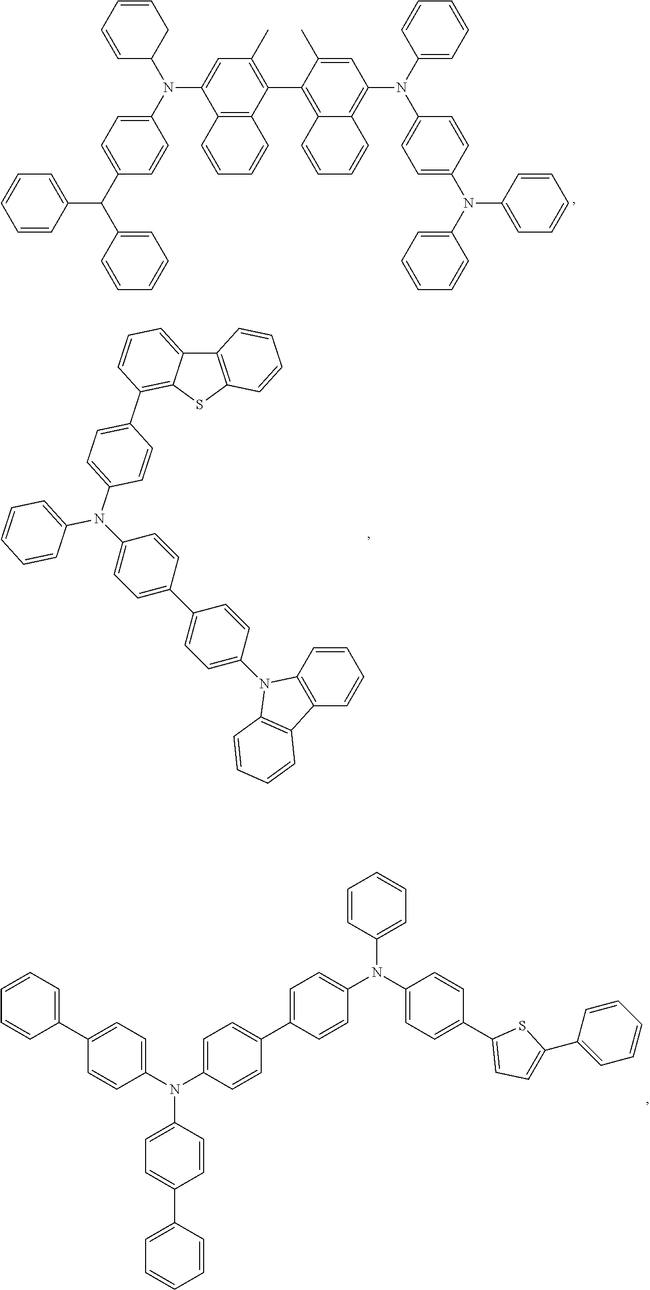

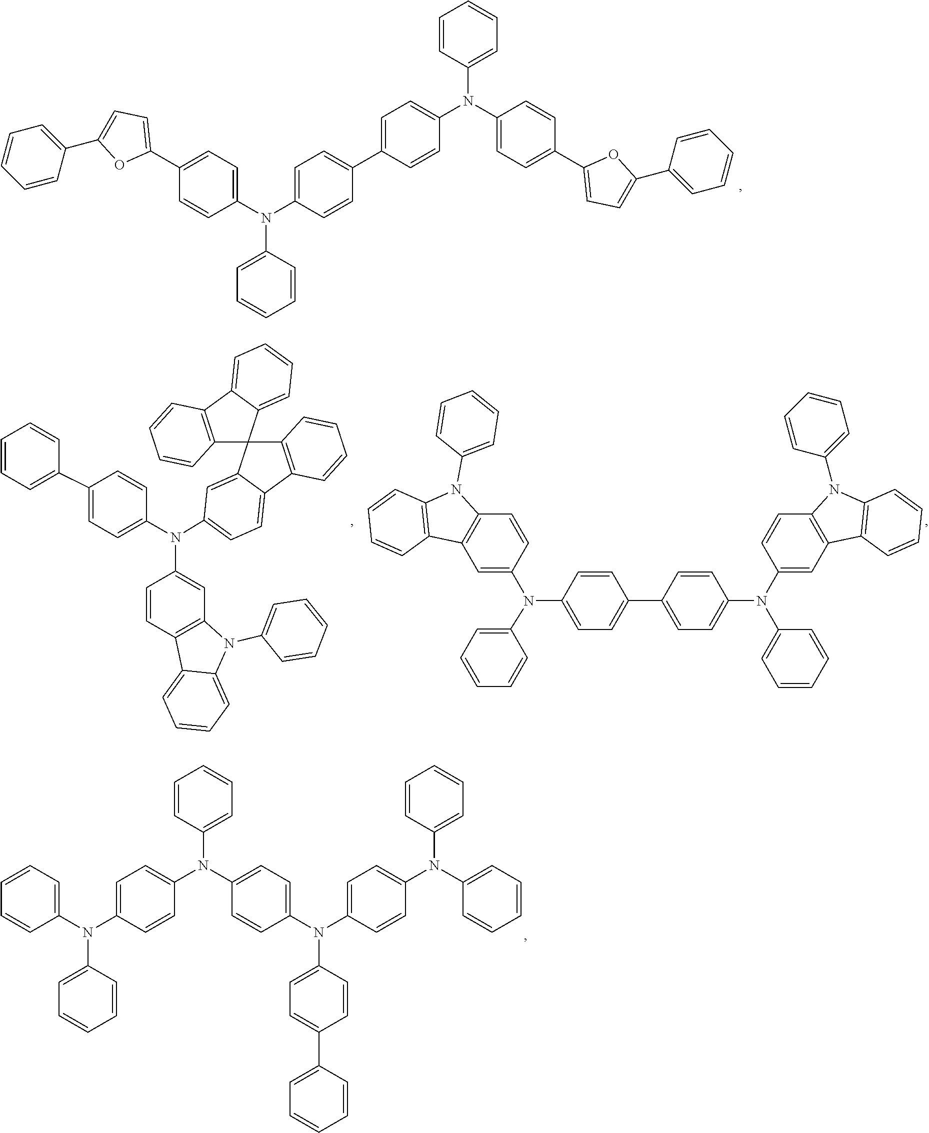

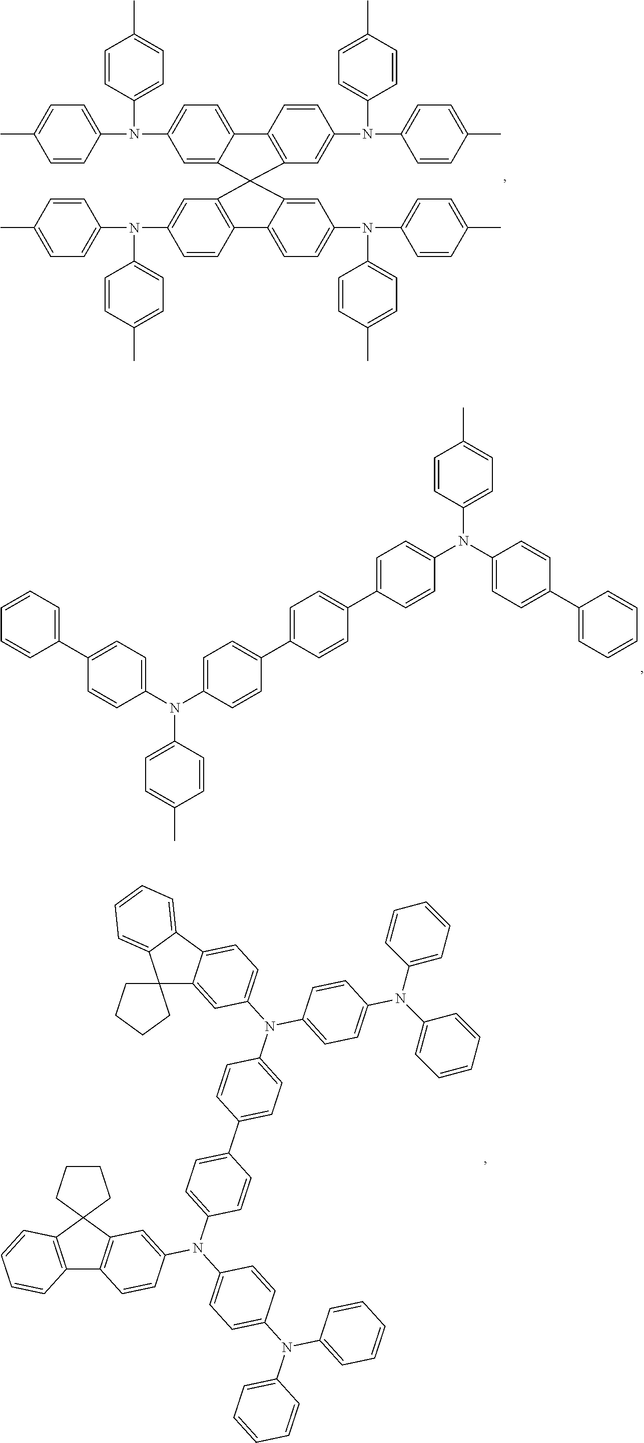

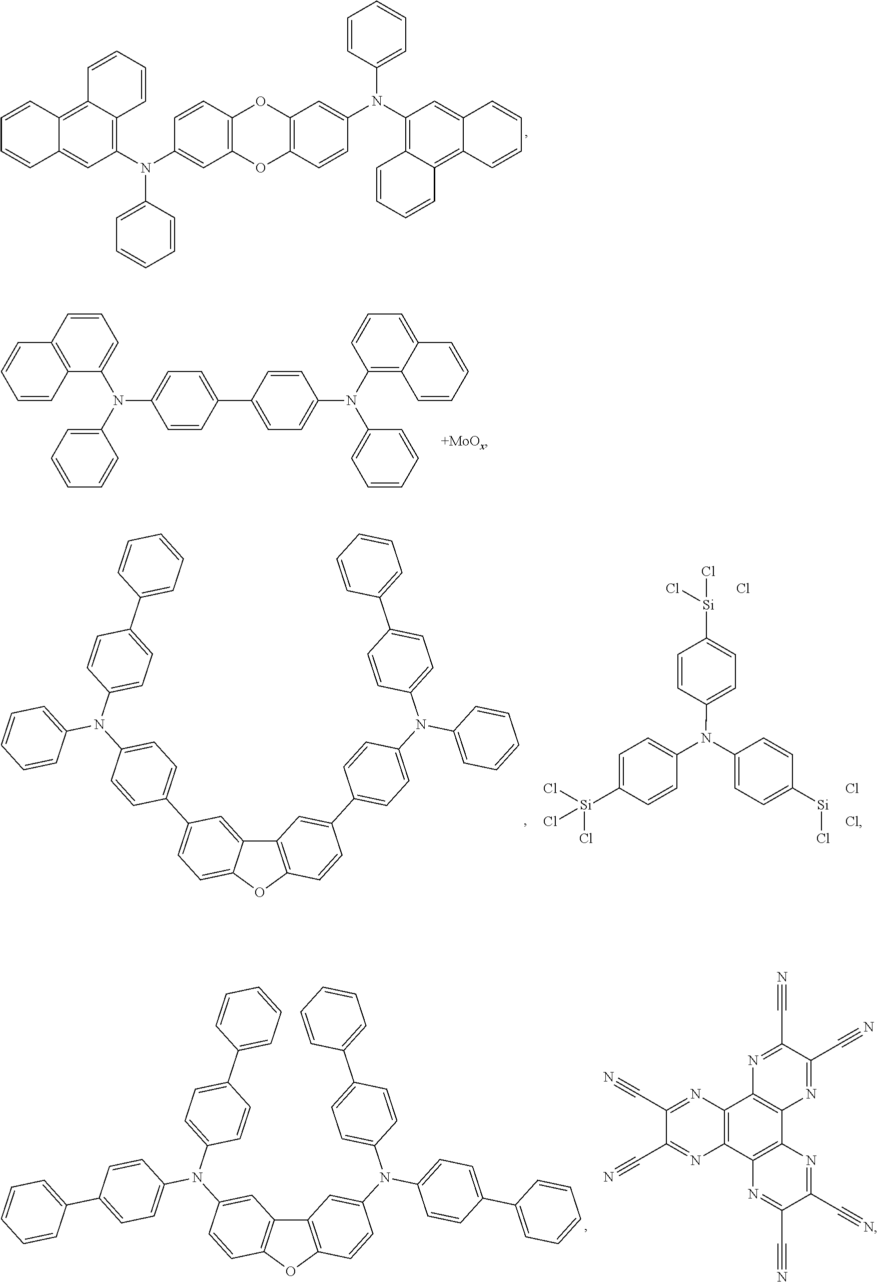

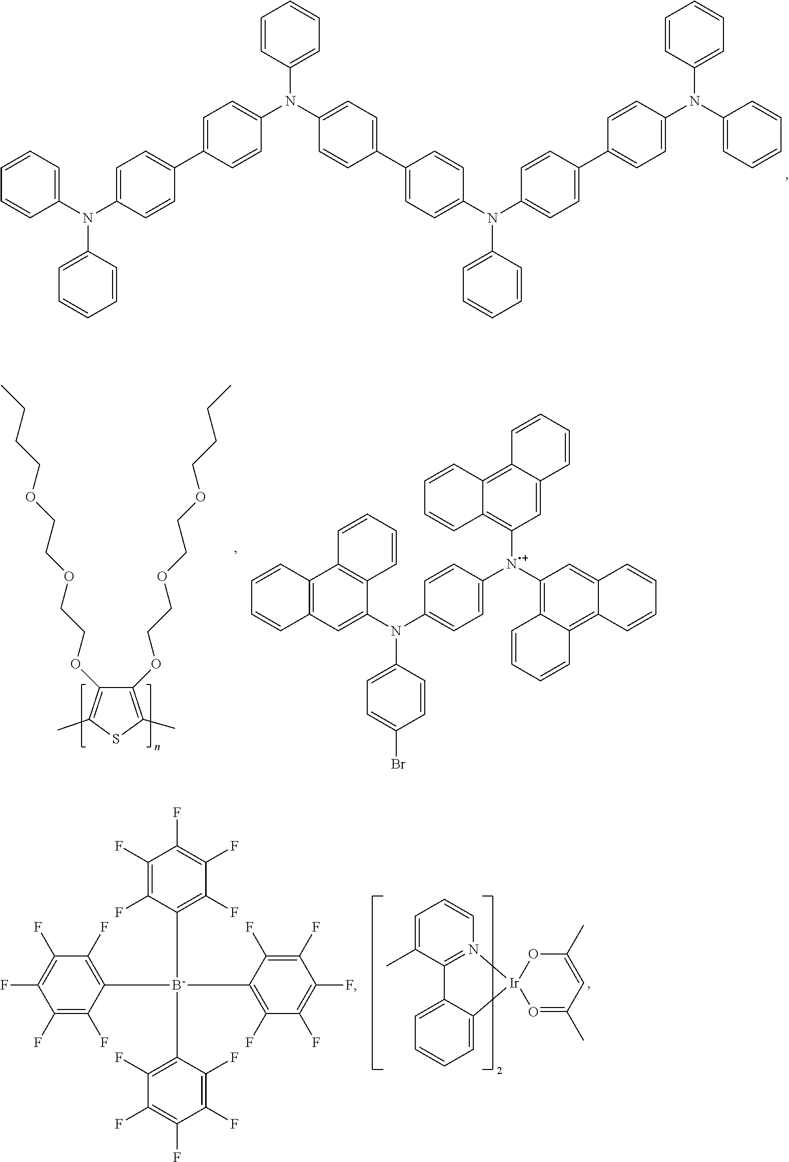

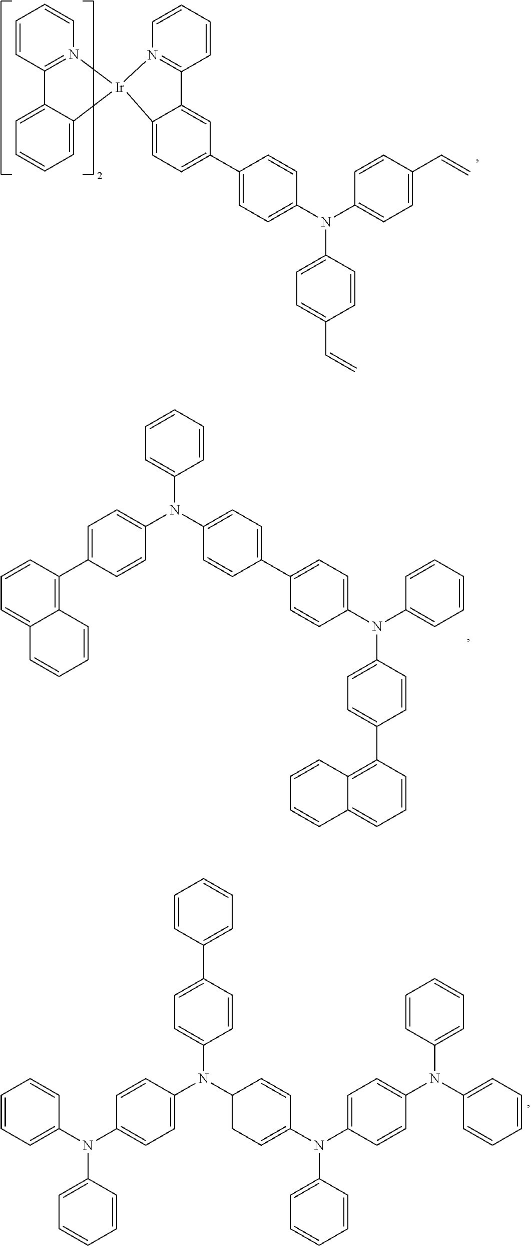

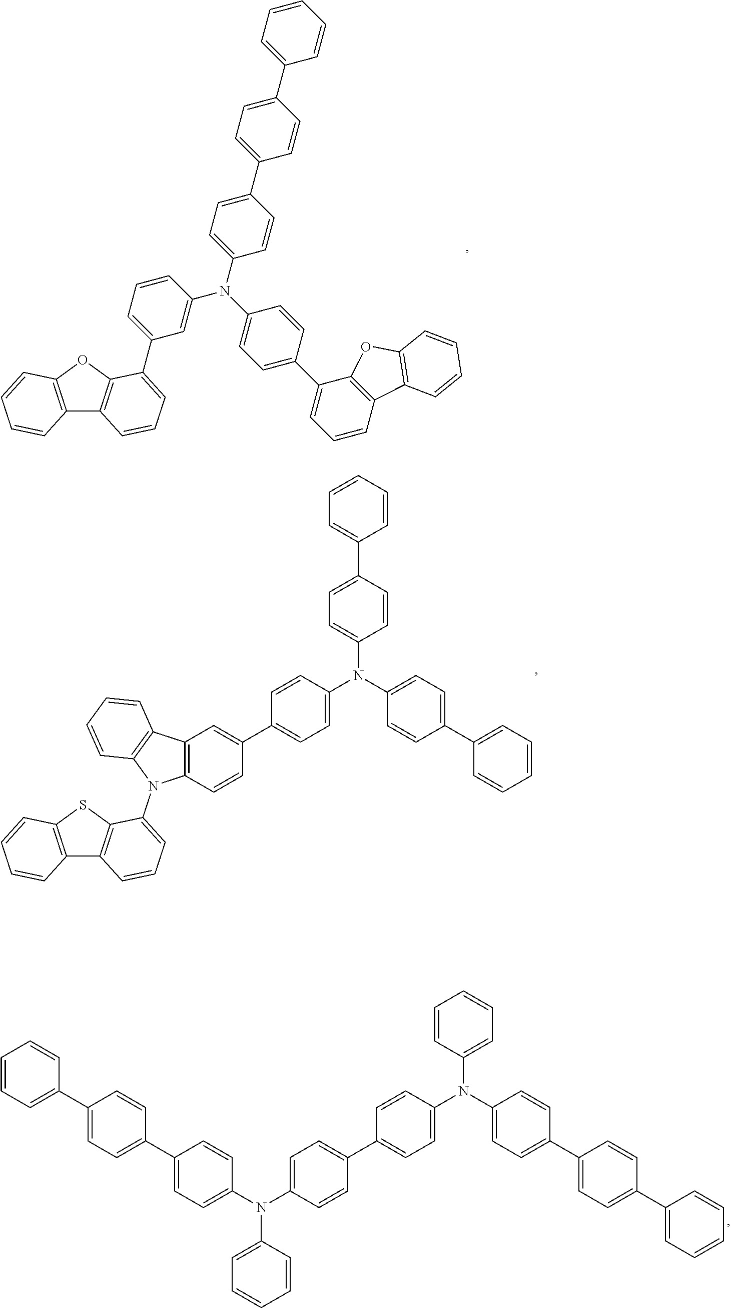

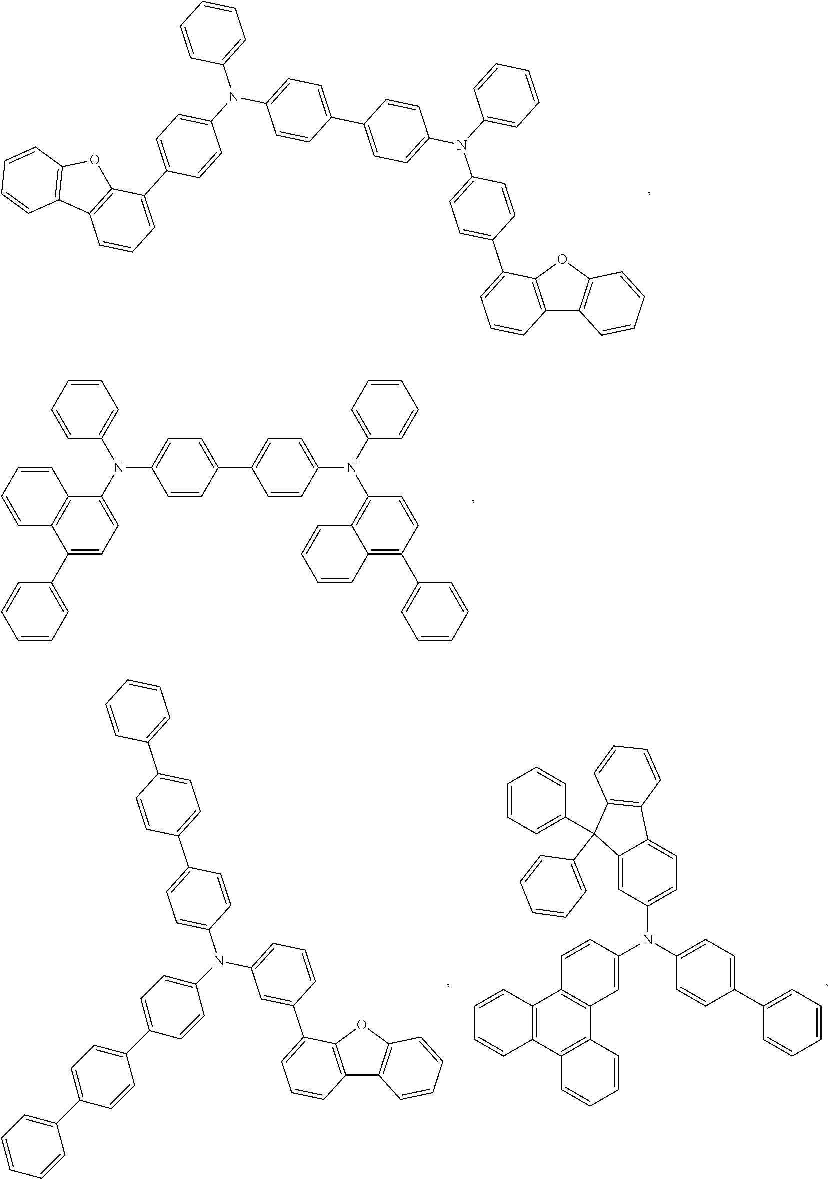

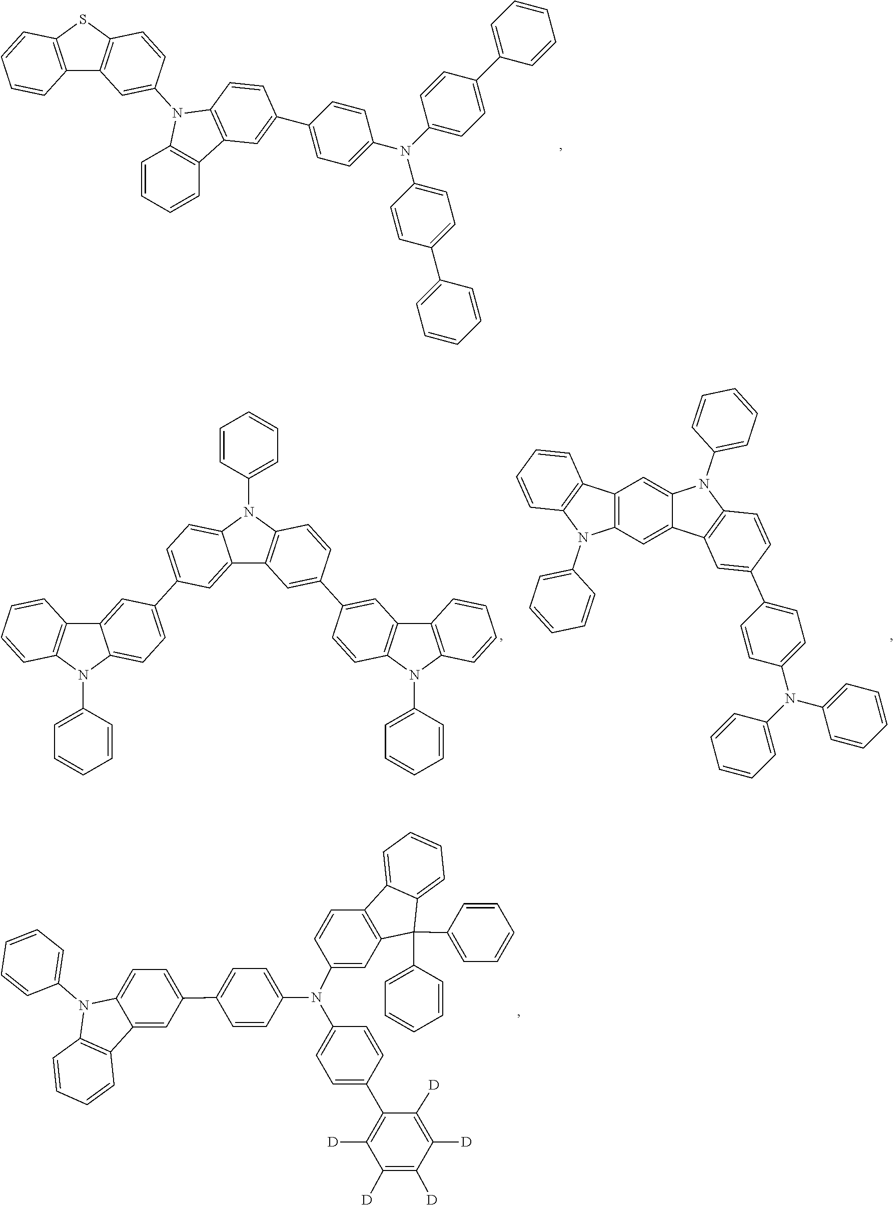

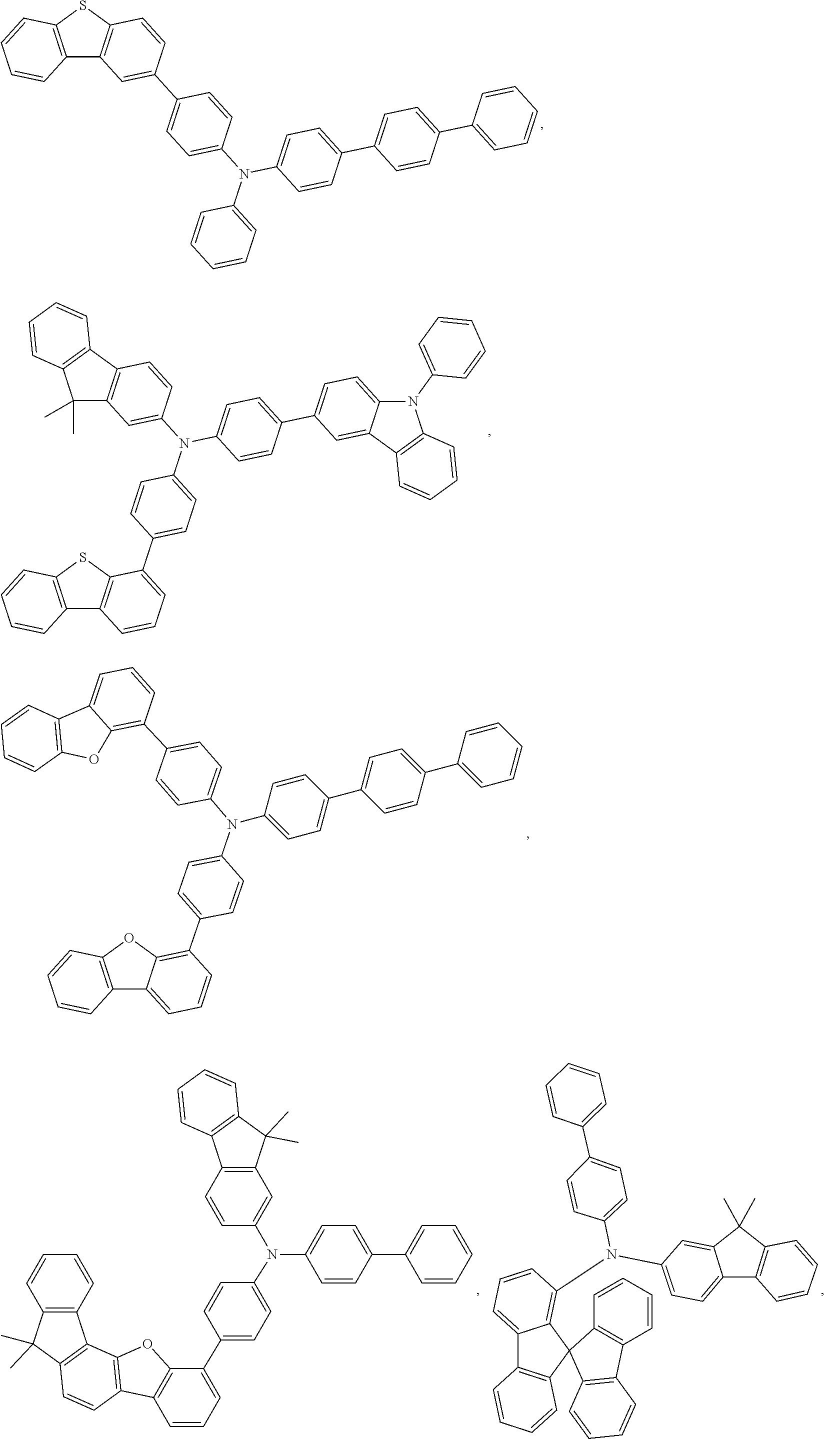

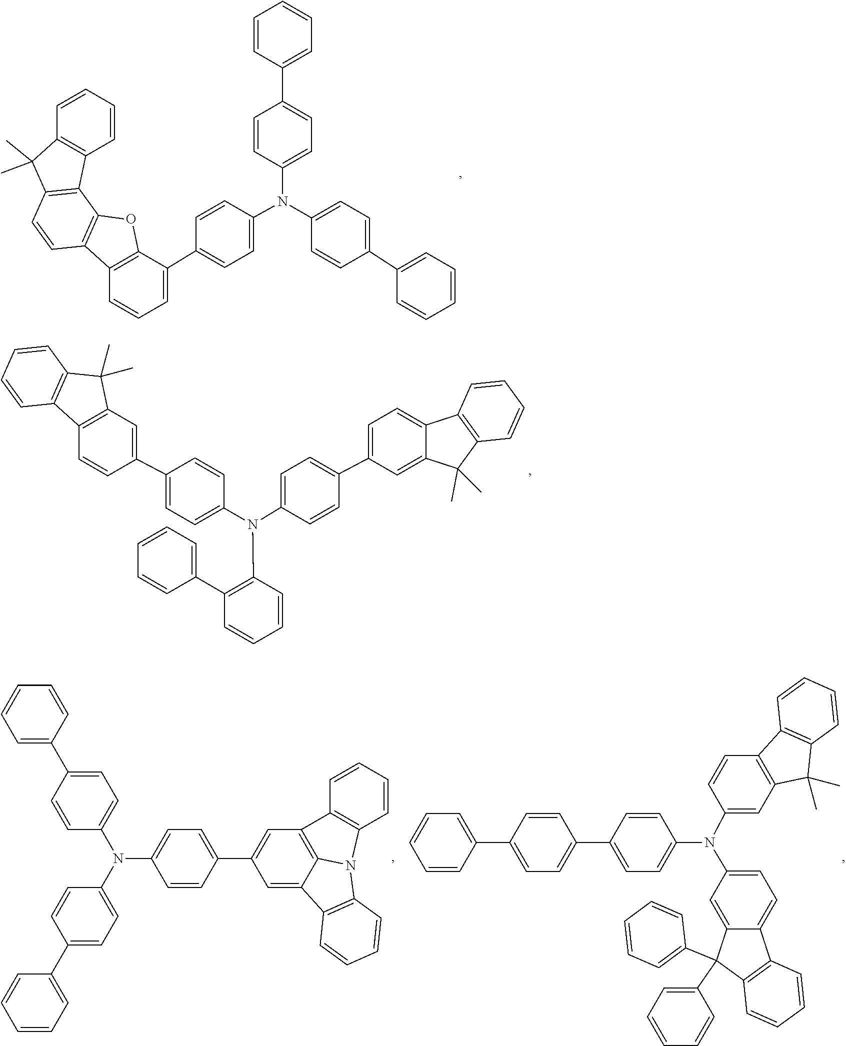

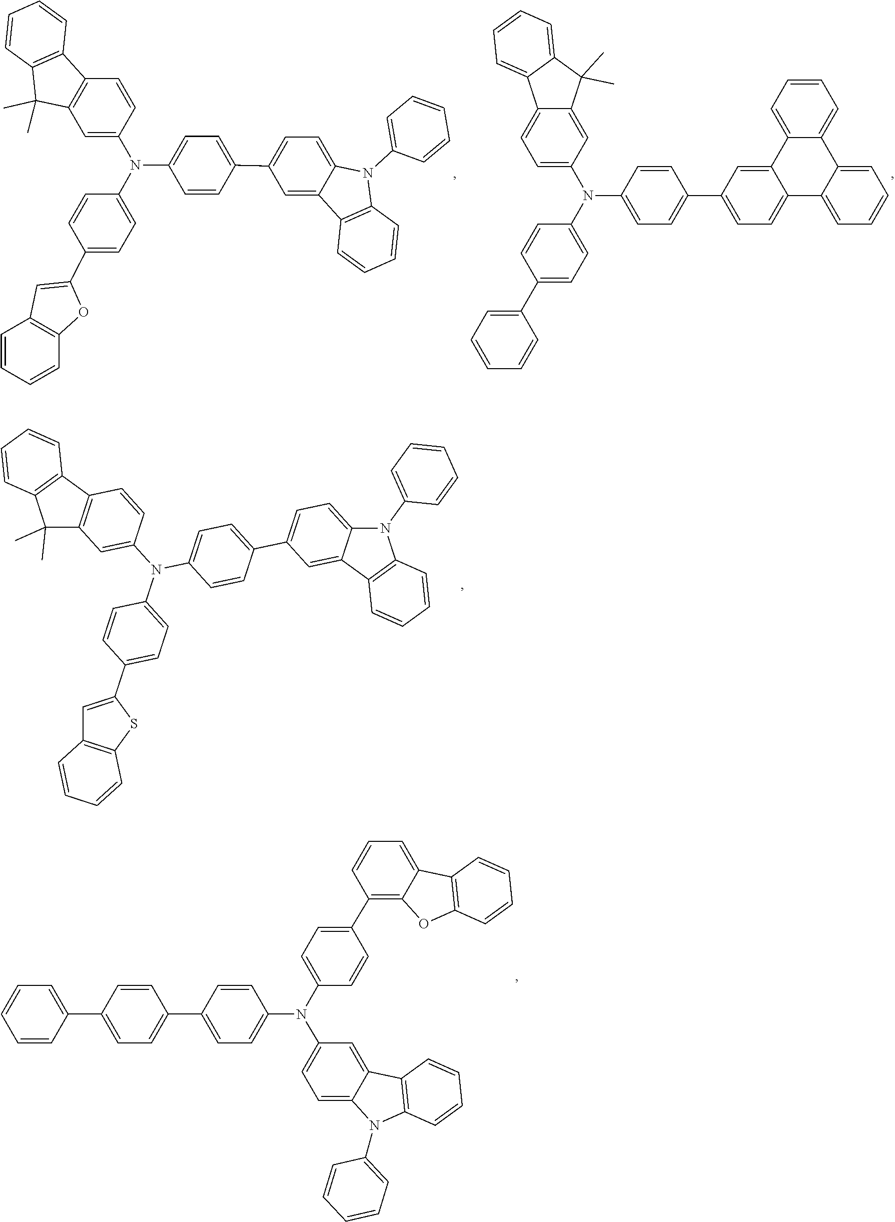

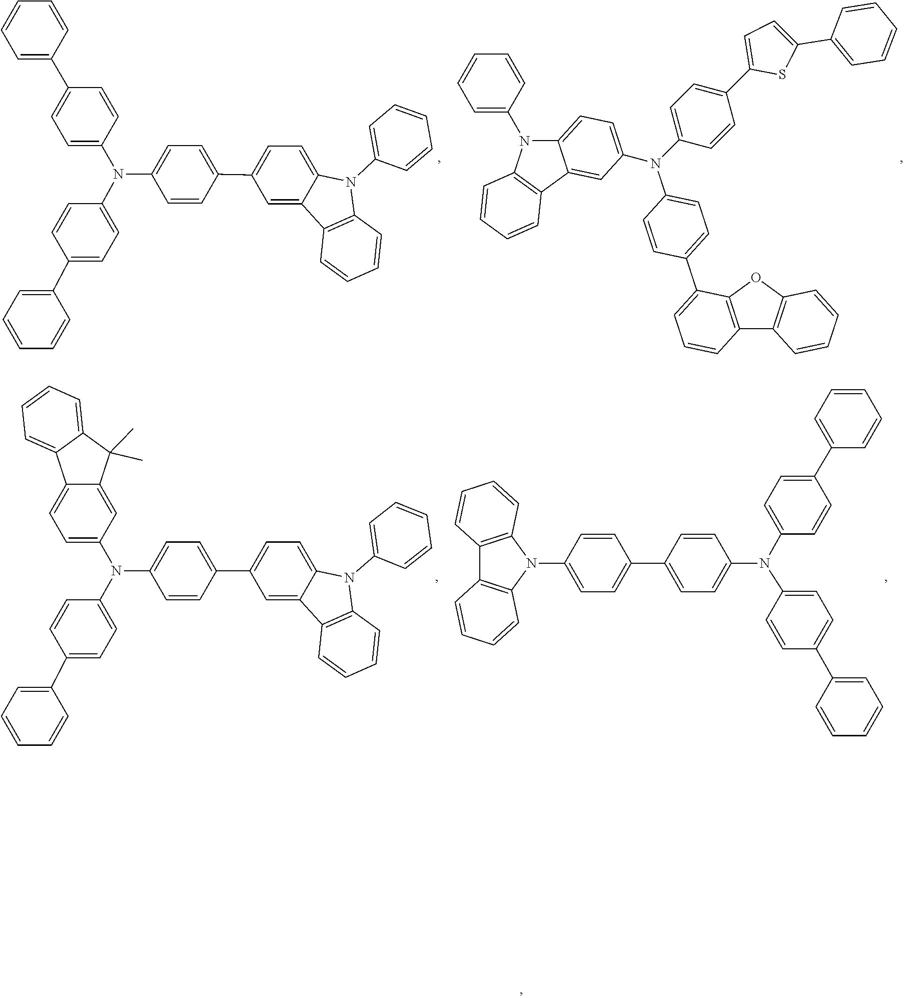

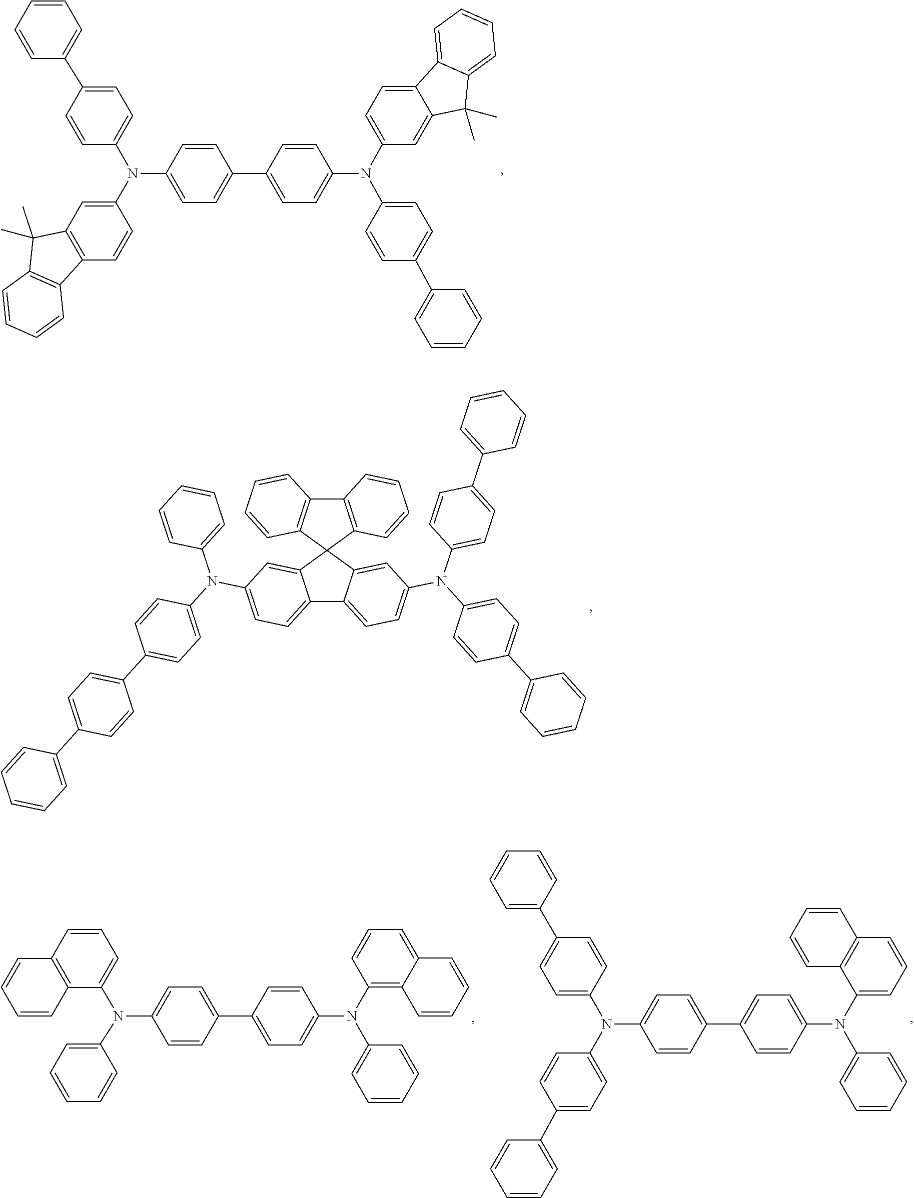

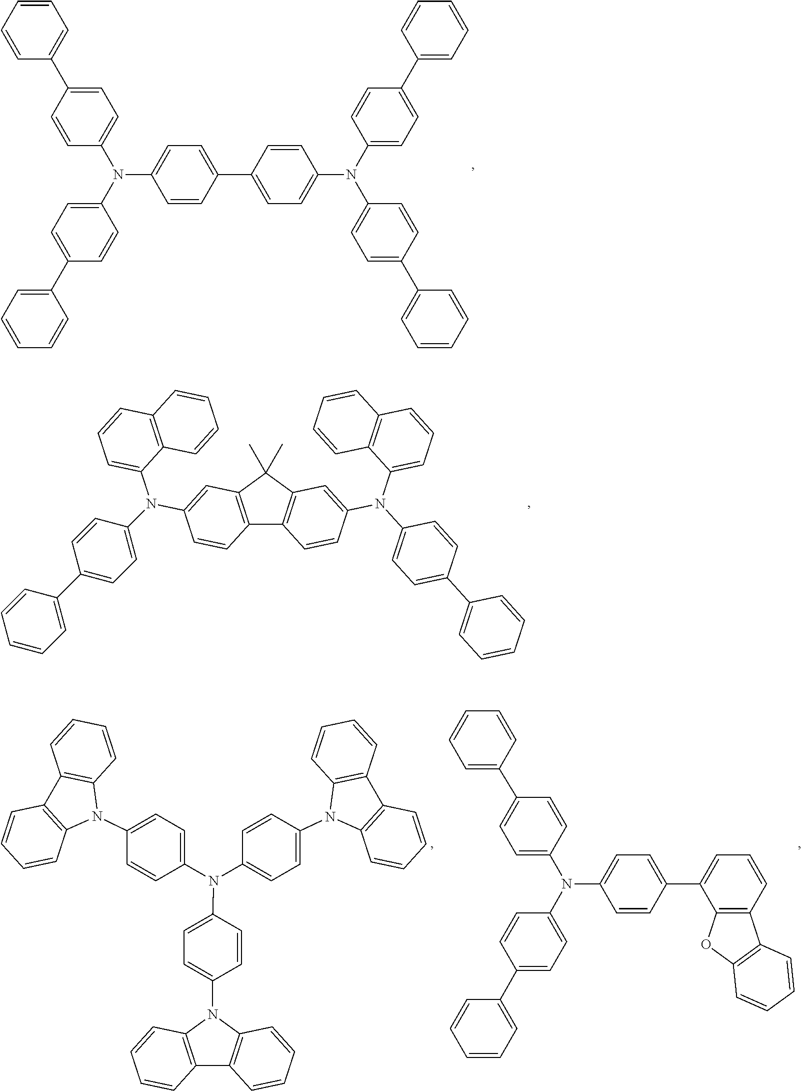 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; CC1(C)c2cc(N(c3ccc(-c4ccccc4)cc3)c3cccc4ccccc34)ccc2-c2ccc(N(c3ccc(-c4ccccc4)cc3)c3cccc4ccccc34)cc21 ; c1ccc2c(c1)c1ccccc1n2-c1ccc(N(c2ccc(-n3c4ccccc4c4ccccc43)cc2)c2ccc(-n3c4ccccc4c4ccccc43)cc2)cc1 ; c1ccc(-c2ccc(N(c3ccc(-c4ccccc4)cc3)c3ccc(-c4cccc5c4oc4ccccc45)cc3)cc2)cc1]

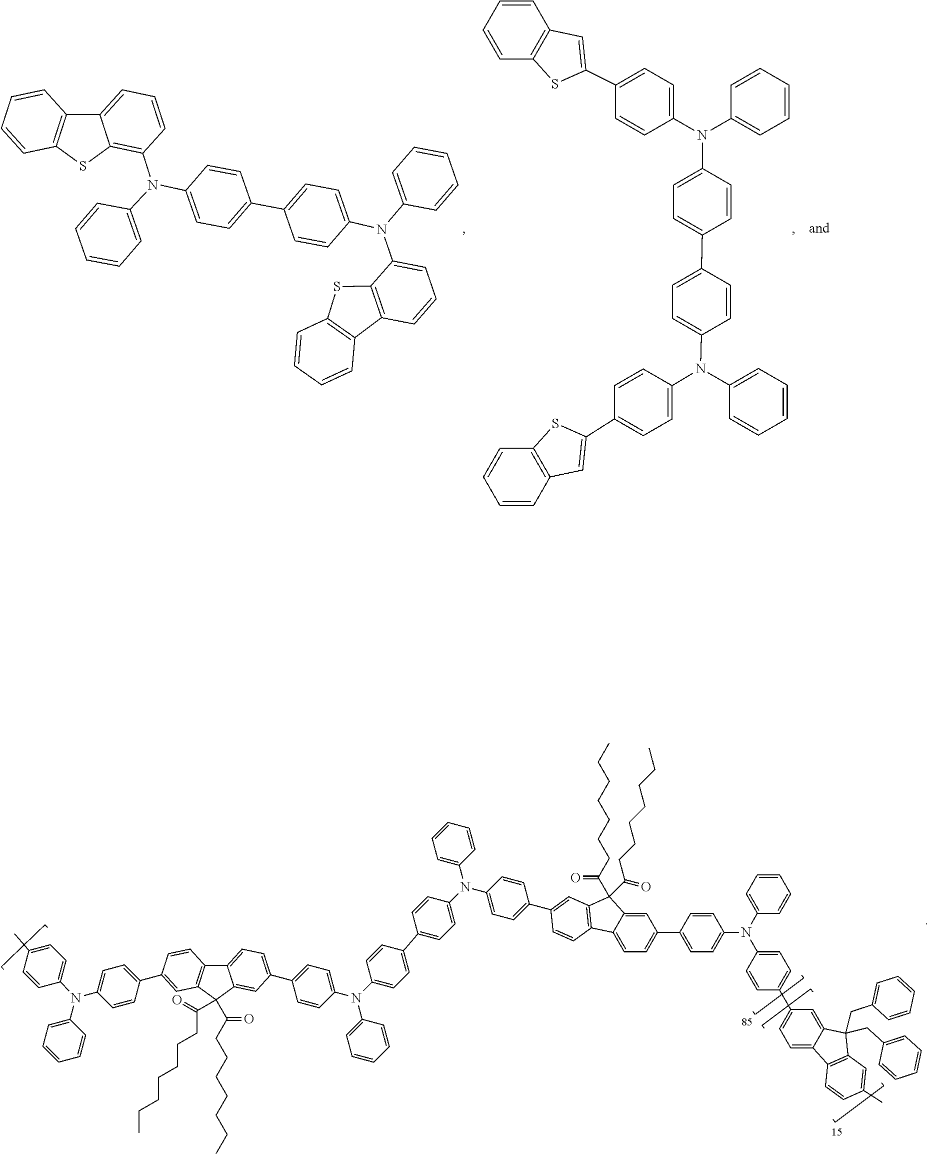

### EBL:

An electron blocking layer (EBL) may be used to reduce the number of electrons and/or excitons that leave the emissive layer. The presence of such a blocking layer in a device may result in substantially higher efficiencies, and/or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than the emitter closest to the EBL interface. In some embodiments, the EBL material has a higher LUMO (closer to the vacuum level) and/or higher triplet energy than one or more of the hosts closest to the EBL interface. In one aspect, the compound used in EBL contains the same molecule or the same functional groups used as one of the hosts described below.

### Hosts:

The light emitting layer of the organic EL device of the present disclosure preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. Any host material may be used with any dopant so long as the triplet criteria is satisfied.

Examples of metal complexes used as host are preferred to have the following general formula:

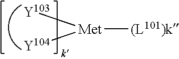

wherein Met is a metal; (Y₁₀₃-Y₁₀₄) is a bidentate ligand, Y₁₀₃ and Y₁₀₄ are independently selected from C, N, O, P, and S; L_{1101 03}is an another ligand; k′ is an integer value from 1 to the maximum number of ligands that may be attached to the metal; and k′+k″ is the maximum number of ligands that may be attached to the metal. In one aspect, the metal complexes are:

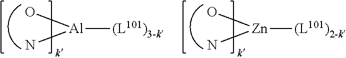

wherein (O—N) is a bidentate ligand, having metal coordinated to atoms O and N. In another aspect, Met is selected from Ir and Pt. In a further aspect, (Y₁₀₃-Y₁₀₄) is a carbene ligand.

In one aspect, the host compound contains at least one of the following groups selected from the group consisting of aromatic hydrocarbon cyclic compounds such as benzene, biphenyl, triphenyl, triphenylene, tetraphenylene, naphthalene, anthracene, phenalene, phenanthrene, fluorene, pyrene, cluysene, perylene, and azulene; the group consisting of aromatic heterocyclic compounds such as dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine; and the group consisting of 2 to 10 cyclic structural units which are groups of the same type or different types selected from the aromatic hydrocarbon cyclic group and the aromatic heterocyclic group and are bonded to each other directly or via at least one of oxygen atom, nitrogen atom, sulfur atom, silicon atom, phosphorus atom, boron atom, chain structural unit and the aliphatic cyclic group. Each option within each group may be unsubstituted or may be substituted by a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acids, ether, ester, nitrile, isonitrile, sulfanyl, sulfinyl, sulfonyl, phosphino, and combinations thereof.

In one aspect, the host compound contains at least one of the following groups in the molecule:

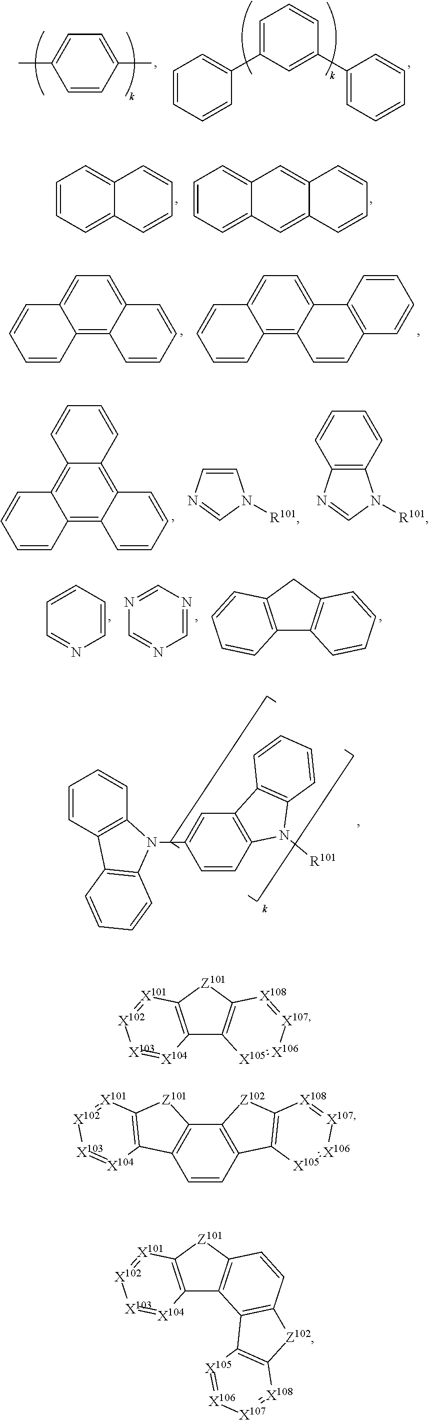

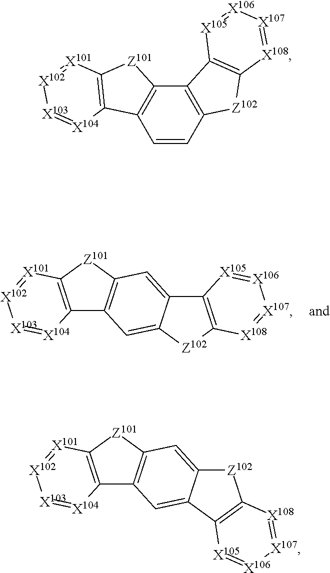

wherein R¹⁰¹ is selected from the group consisting of hydrogen, deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acids, ether, ester, nitrile, isonitrile, sulfanyl, sulfinyl, sulfonyl, phosphino, and combinations thereof, and when it is aryl or heteroaryl, it has the similar definition as Ar's mentioned above. k is an integer from 0 to 20 or 1 to 20. X¹⁰¹ to X¹⁰⁸ are independently selected from C (including CH) or N. Z¹⁰¹ and Z¹⁰² are independently selected from NR¹⁰¹, O, or S.

Non-limiting examples of the host materials that may be used in an OLED in combination with materials disclosed herein are exemplified below together with references that disclose those materials: EP2034538, EP2034538A, EP2757608, JP2007254297, KR20100079458, KR20120088644, KR20120129733, KR20130115564, TW201329200, US20030175553, US20050238919, US20060280965, US20090017330, US20090030202, US20090167162, US20090302743, US20090309488, US20100012931, US20100084966, US20100187984, US2010187984, US2012075273, US2012126221, US2013009543, US2013105787, US2013175519, US2014001446, US20140183503, US20140225088, US2014034914, US7154114, WO2001039234, WO2004093207, WO2005014551, WO2005089025, WO2006072002, WO2006114966, WO2007063754, WO2008056746, WO2009003898, WO2009021126, WO2009063833, WO2009066778, WO2009066779, WO2009086028, WO2010056066, WO2010107244, WO2011081423, WO2011081431, WO2011086863, WO2012128298, WO2012133644, WO2012133649, WO2013024872, WO2013035275, WO2013081315, WO2013191404, WO2014142472, US20170263869, US20160163995, U.S. Pat. No. 9,466,803,

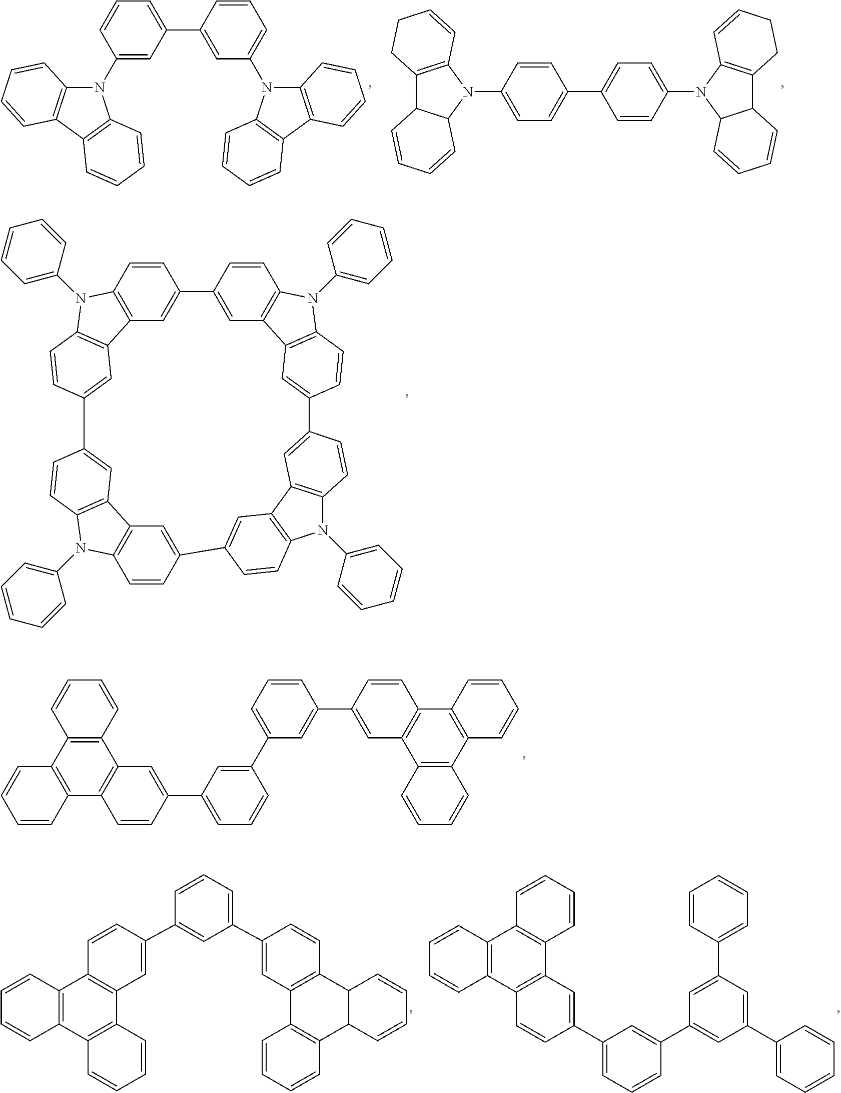

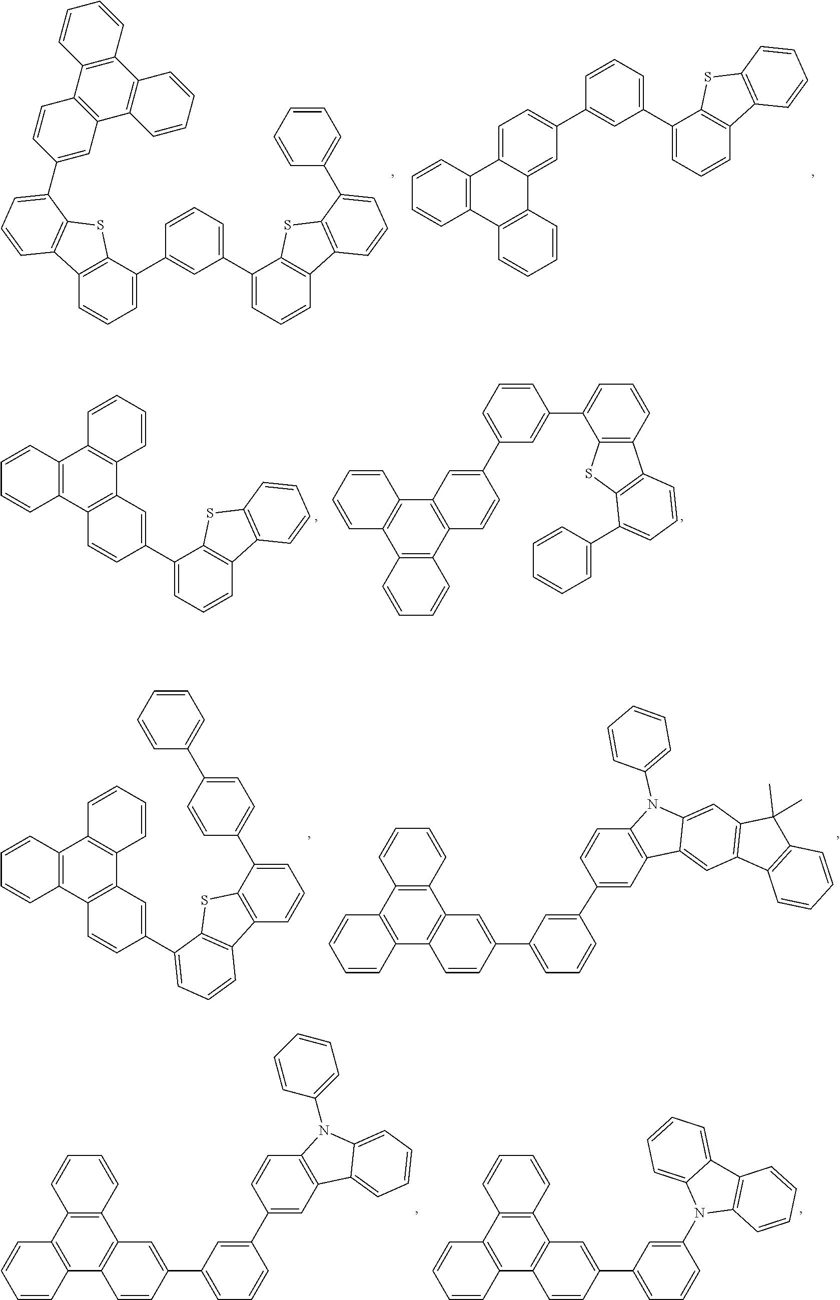

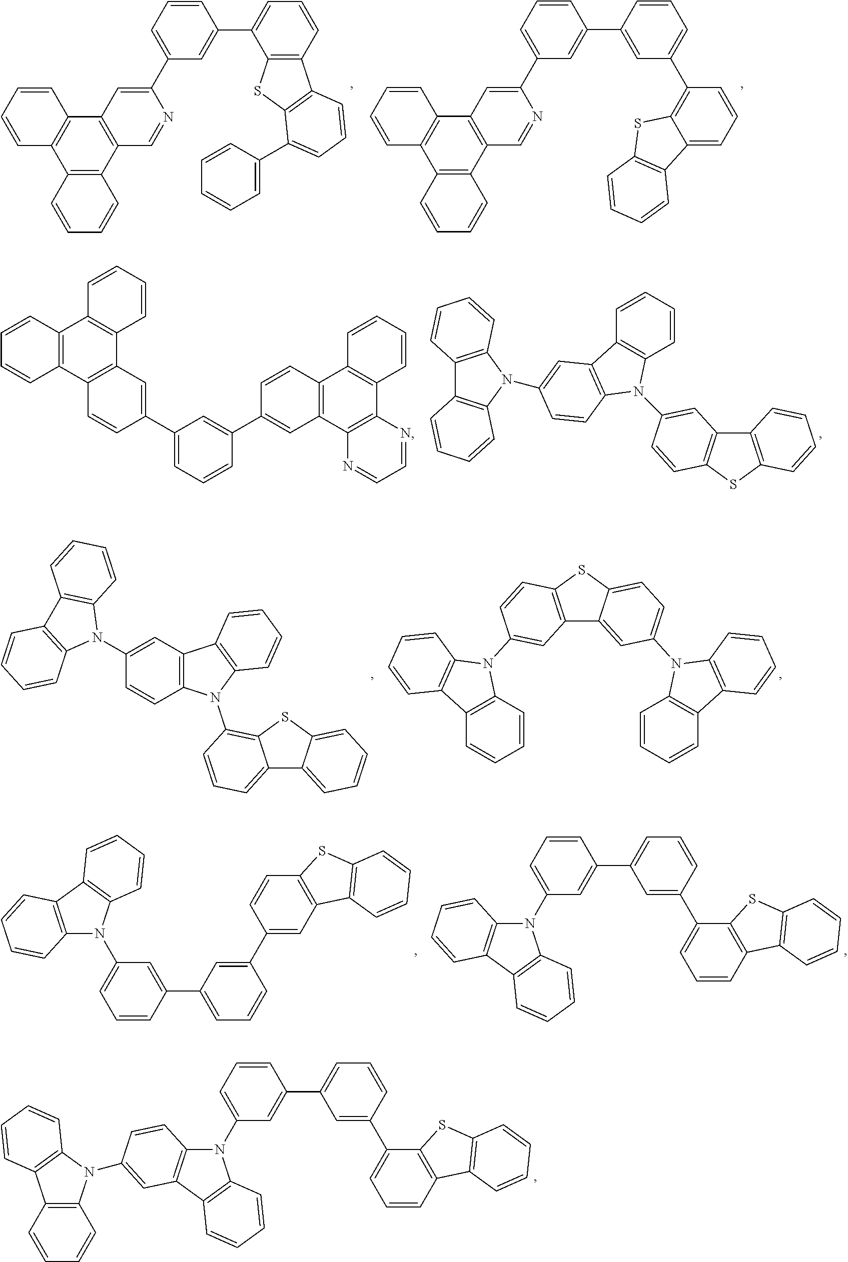

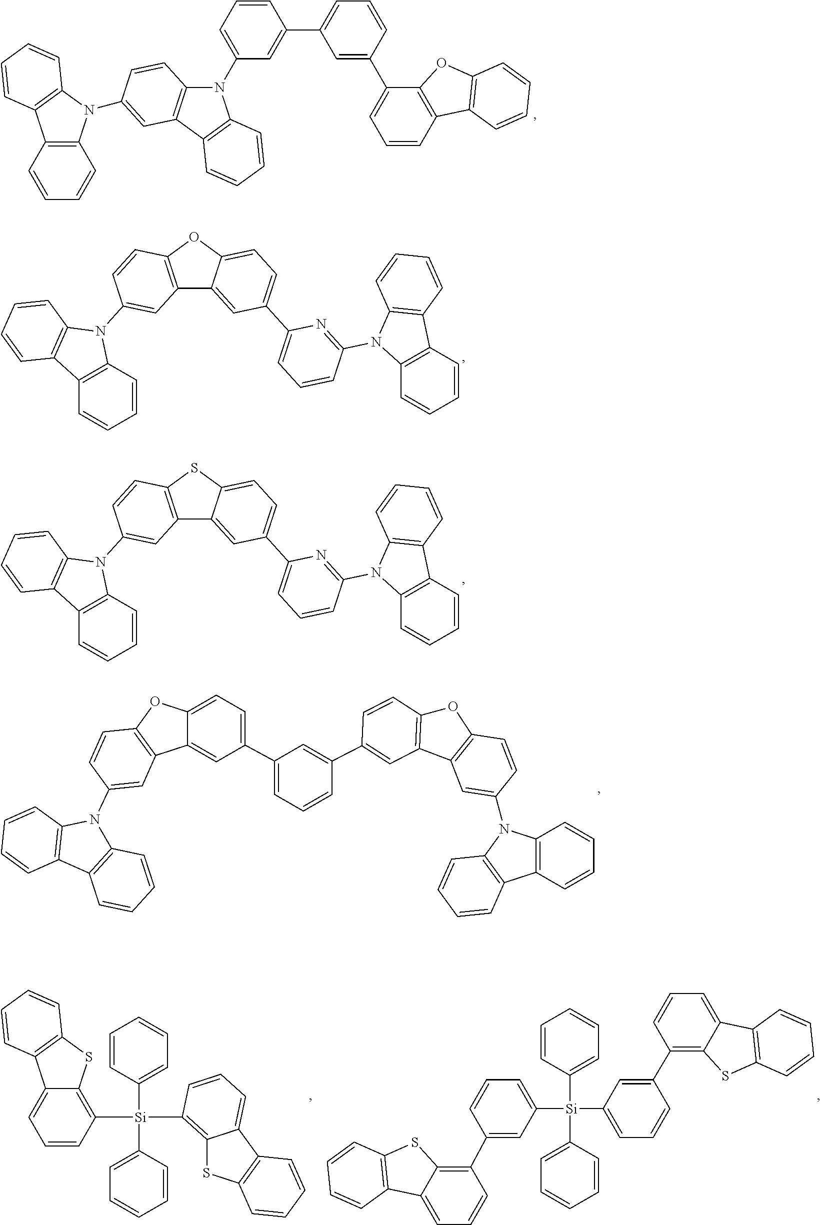

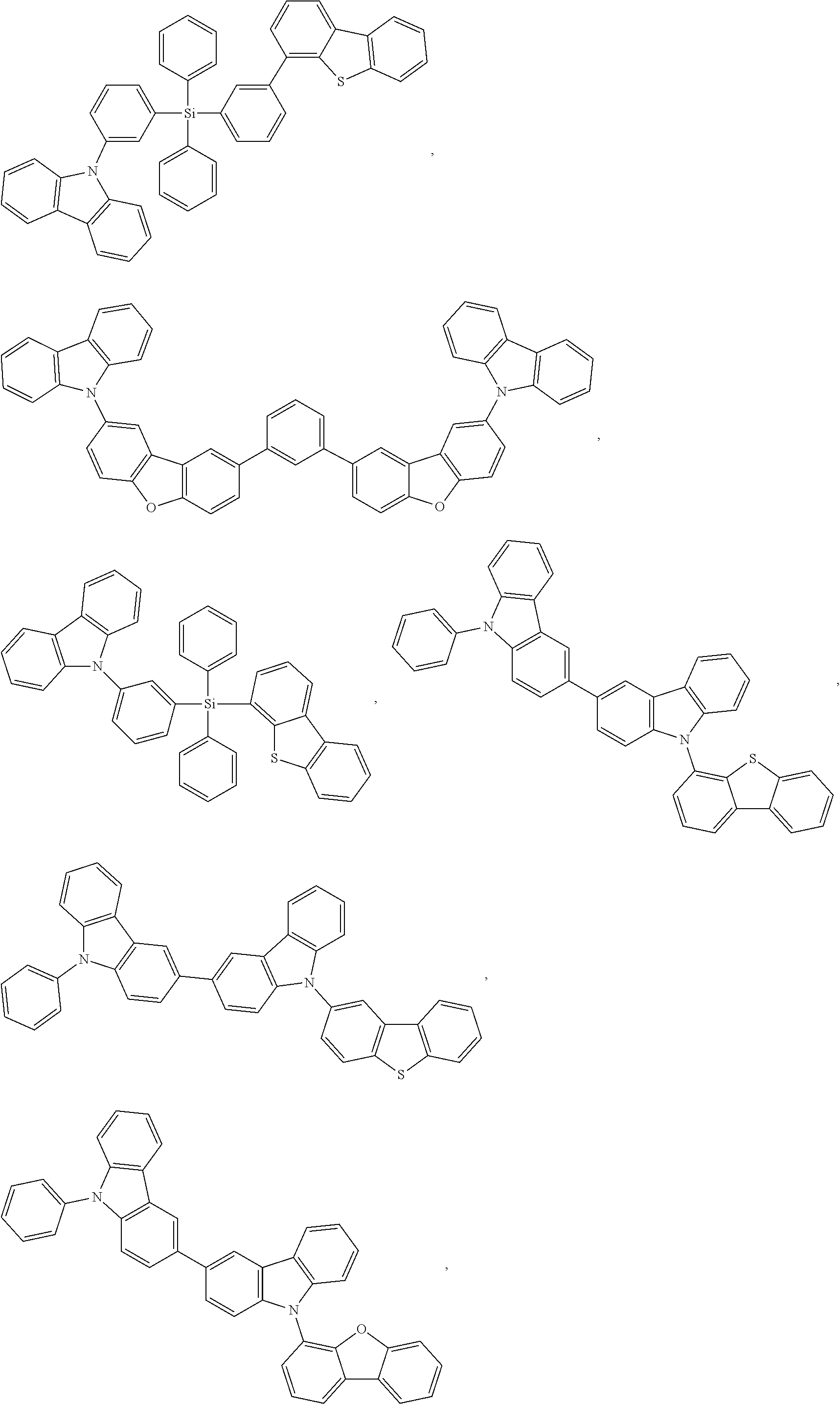

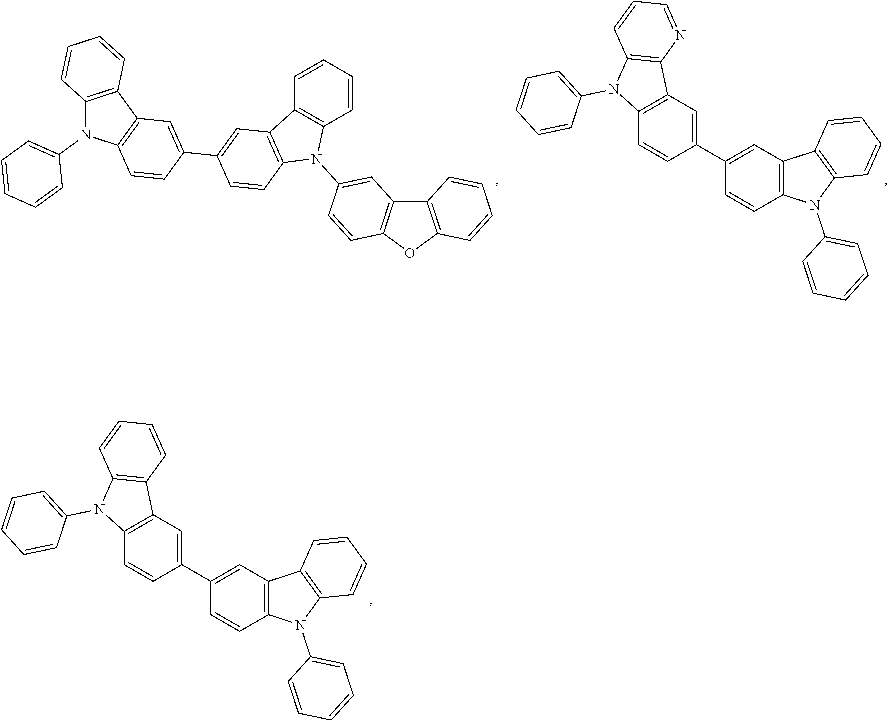 [SMILES: c1ccc(-n2c3ccccc3c3cc(-c4ccc5c(c4)c4ccccc4n5-c4ccc5oc6ccccc6c5c4)ccc32)cc1 ; c1ccc(-n2c3ccccc3c3cc(-c4ccc5c(c4)c4ncccc4n5-c4ccccc4)ccc32)cc1 ; c1ccc(-n2c3ccccc3c3cc(-c4ccc5c(c4)c4ccccc4n5-c4ccccc4)ccc32)cc1]

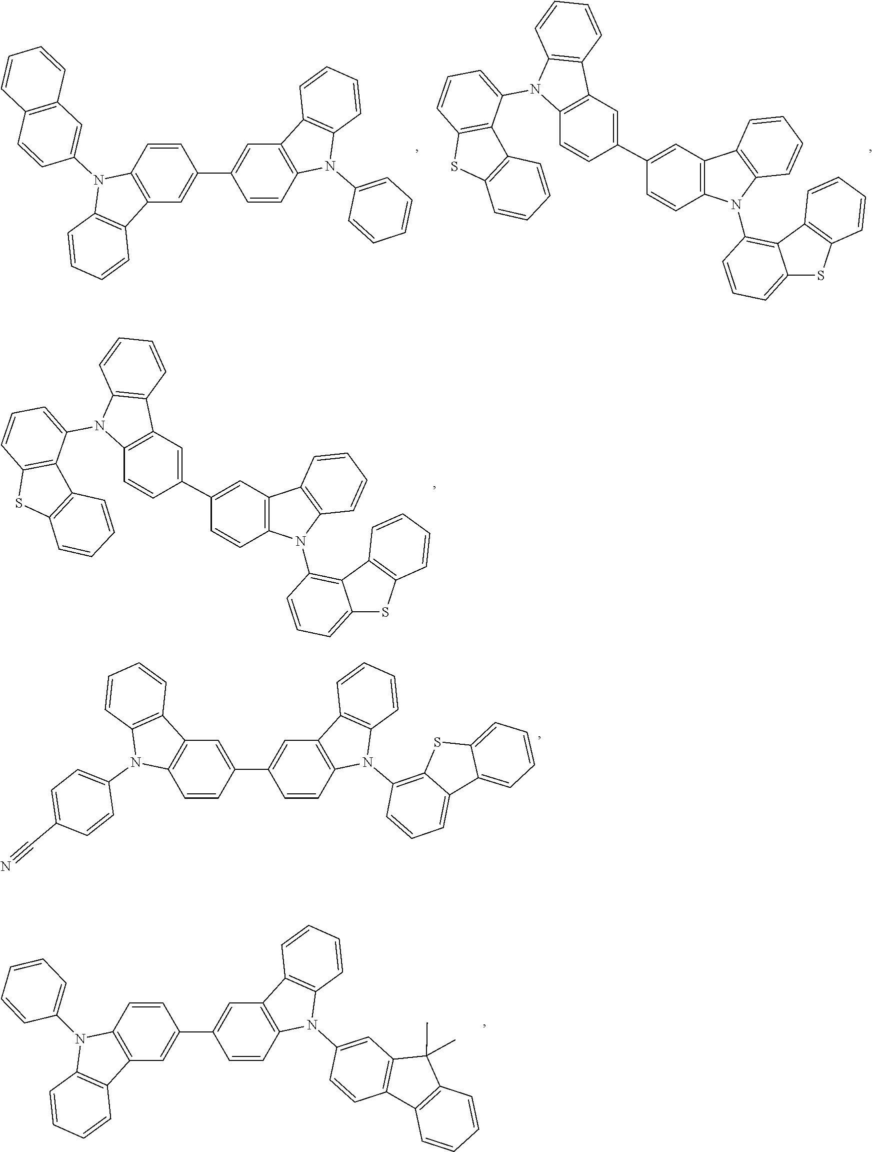

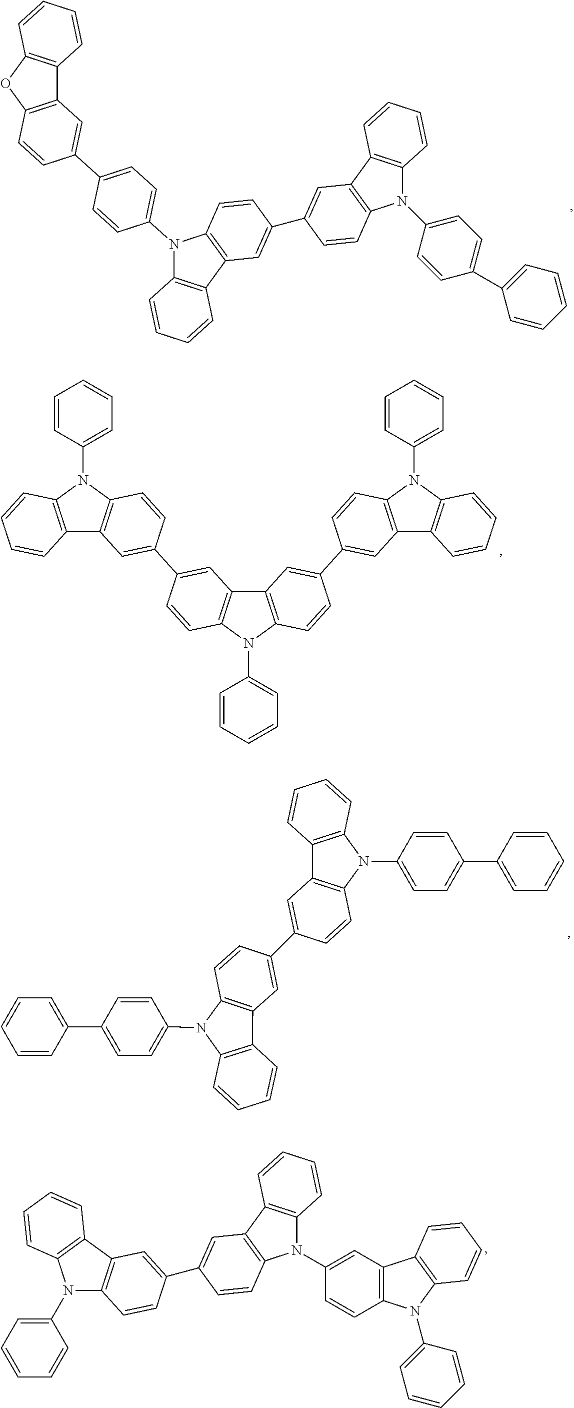 [SMILES: c1ccc(-c2ccc(-n3c4ccccc4c4cc(-c5ccc6c(c5)c5ccccc5n6-c5ccc(-c6ccc7oc8ccccc8c7c6)cc5)ccc43)cc2)cc1 ; c1ccc(-n2c3ccccc3c3cc(-c4ccc5c(c4)c4cc(-c6ccc7c(c6)c6ccccc6n7-c6ccccc6)ccc4n5-c4ccccc4)ccc32)cc1 ; c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-n2c3ccccc3c3cc(-c4ccc5c(c4)c4ccccc4n5-c4ccc5c(c4)c4ccccc4n5-c4ccccc4)ccc32)cc1]

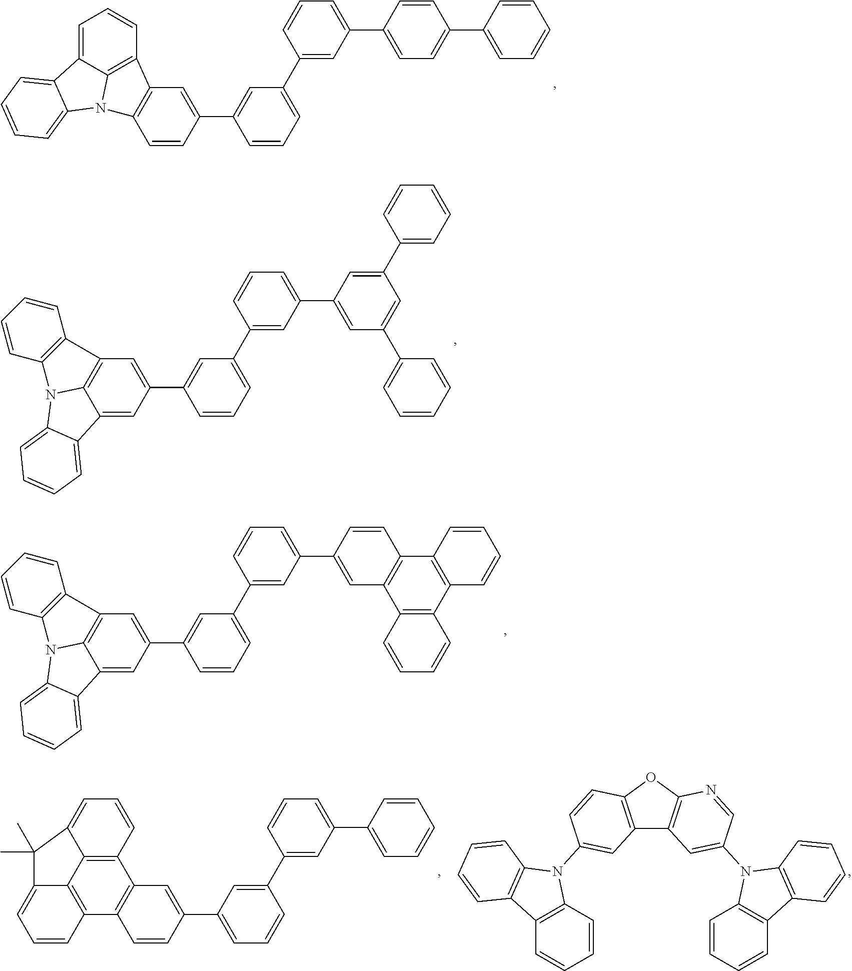

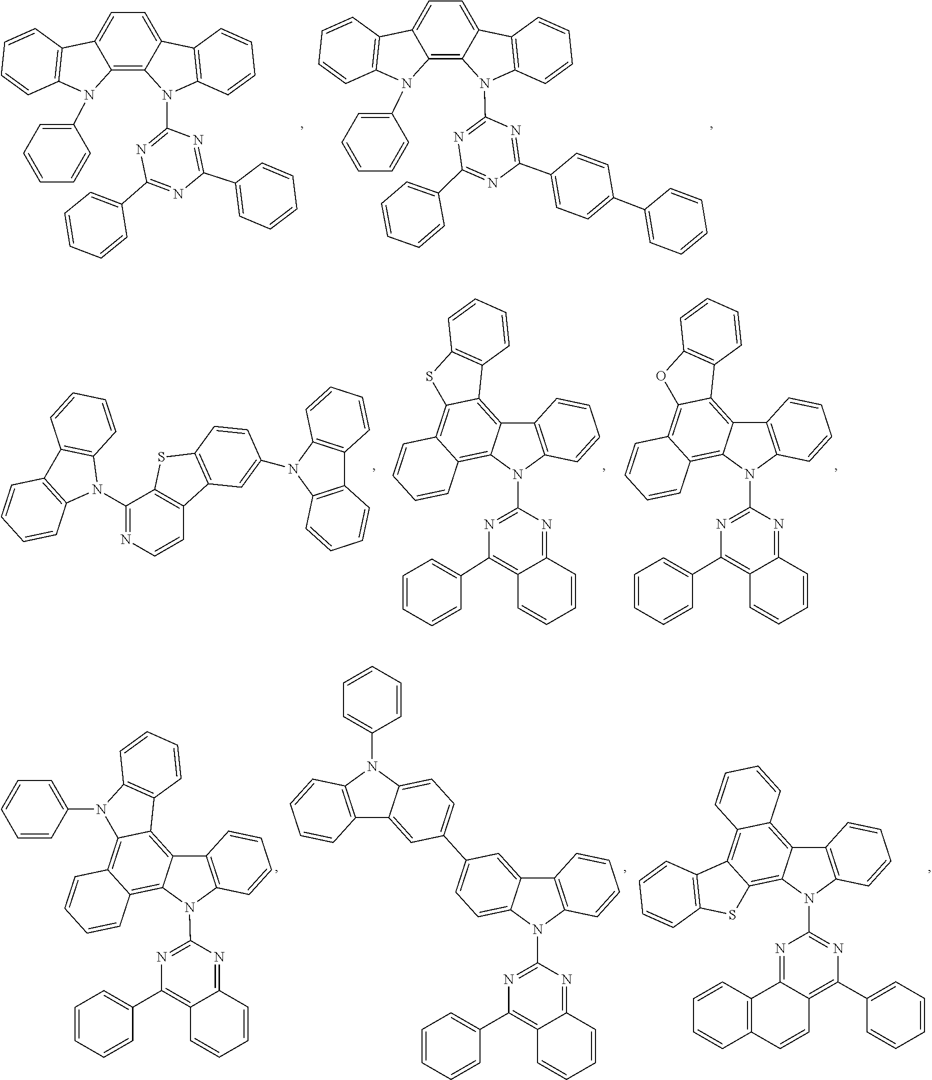

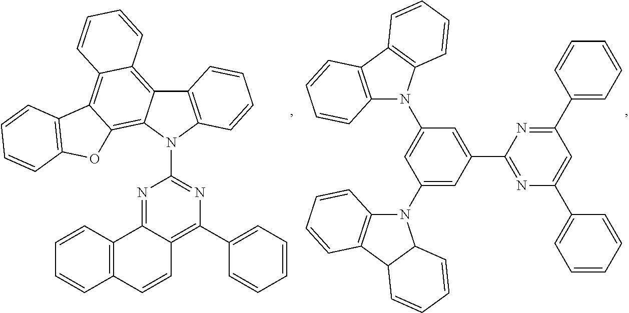

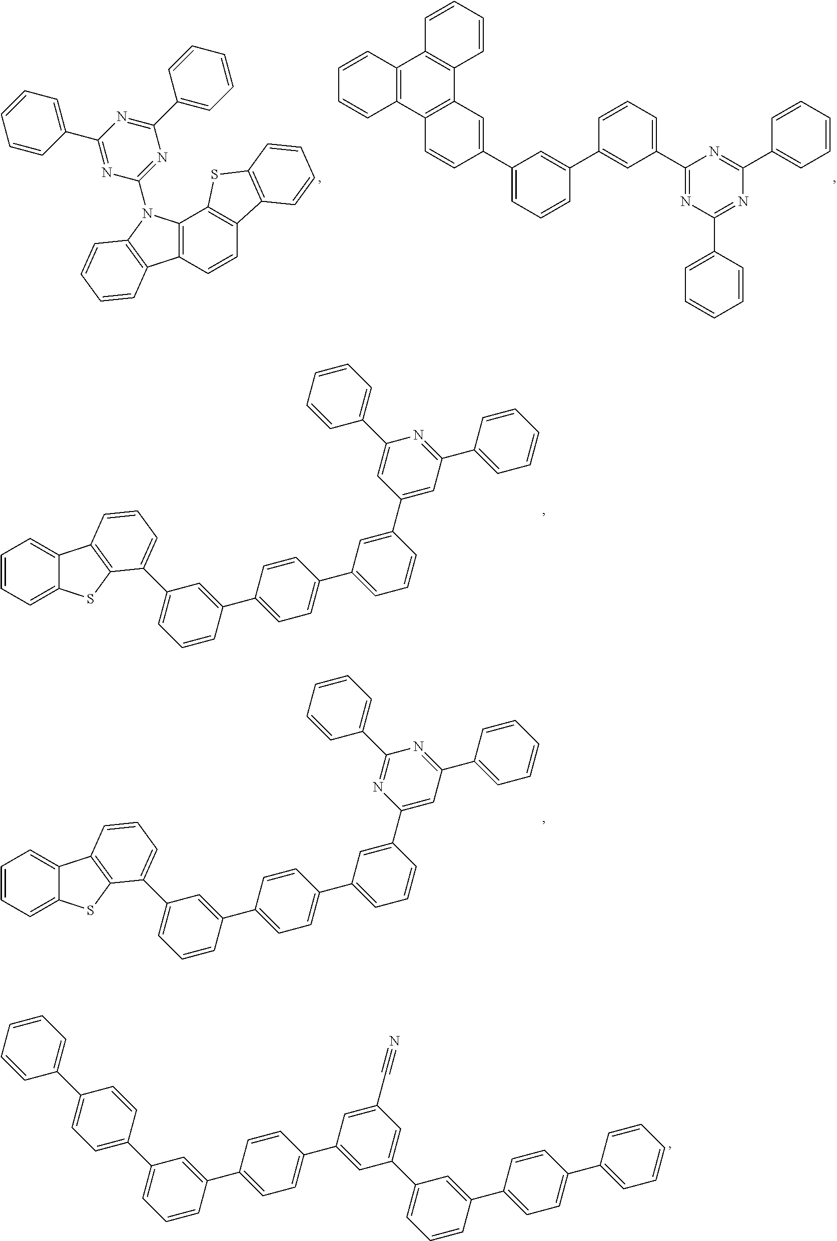 [SMILES: c1ccc(-c2nc(-c3ccccc3)nc(-n3c4ccccc4c4ccc5c6ccccc6sc5c43)n2)cc1 ; c1ccc(-c2nc(-c3ccccc3)nc(-c3cccc(-c4cccc(-c5ccc6c7ccccc7c7ccccc7c6c5)c4)c3)n2)cc1 ; c1ccc(-c2cc(-c3cccc(-c4ccc(-c5cccc(-c6cccc7c6sc6ccccc67)c5)cc4)c3)cc(-c3ccccc3)n2)cc1 ; c1ccc(-c2cc(-c3cccc(-c4ccc(-c5cccc(-c6cccc7c6sc6ccccc67)c5)cc4)c3)nc(-c3ccccc3)n2)cc1 ; N#Cc1cc(-c2ccc(-c3cccc(-c4ccc(-c5ccccc5)cc4)c3)cc2)cc(-c2cccc(-c3ccc(-c4ccccc4)cc3)c2)c1]

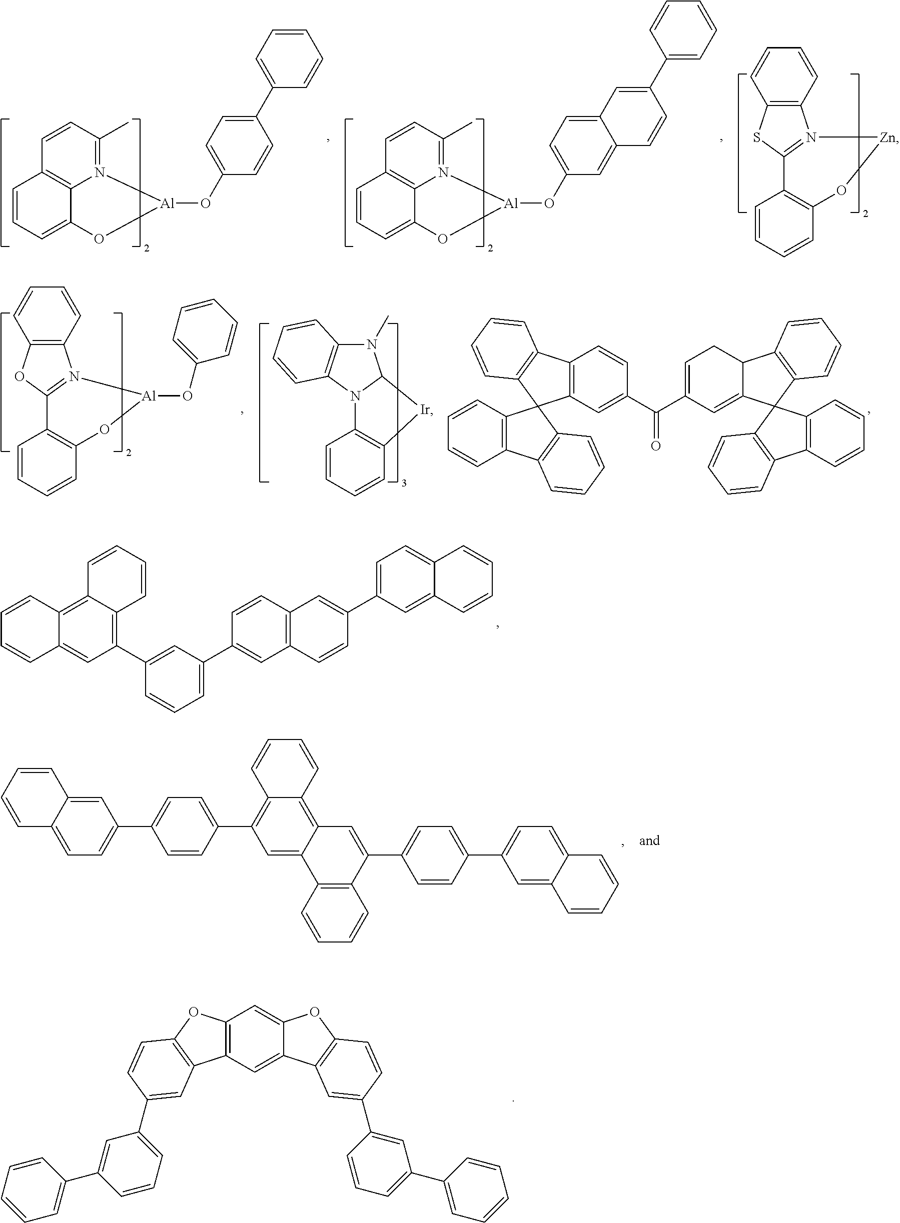

### Additional Emitters:

One or more emitter dopants may be used in the device of the present disclosure. Examples of the additional emitter dopants are not particularly limited, and any compounds may be used as long as the compounds are typically used as emitter materials. Examples of suitable emitter materials include, but are not limited to, compounds which can produce emissions via phosphorescence, fluorescence, thermally activated delayed fluorescence, i.e., TADF (also referred to as E-type delayed fluorescence), triplet-triplet annihilation, or combinations of these processes.

Non-limiting examples of the emitter materials that may be used in an OLED in combination with materials disclosed herein are exemplified below together with references that disclose those materials: CN103694277, CN1696137, EB01238981, EP01239526, EP01961743, EP1239526, EP1244155, EP1642951, EP1647554, EP1841834, EP1841834B, EP2062907, EP2730583, JP2012074444, JP2013110263, JP4478555, KR1020090133652, KR20120032054, KR20130043460, TW201332980, US06699599, US06916554, US20010019782, US20020034656, US20030068526, US20030072964, US20030138657, US20050123788, US20050244673, US2005123791, US2005260449, US20060008670, US20060065890, US20060127696, US20060134459, US20060134462, US20060202194, US20060251923, US20070034863, US20070087321, US20070103060, US20070111026, US20070190359, US20070231600, US2007034863, US2007104979, US2007104980, US2007138437, US2007224450, US2007278936, US20080020237, US20080233410, US20080261076, US20080297033, US200805851, US2008161567, US2008210930, US20090039776, US20090108737, US20090115322, US20090179555, US2009085476, US2009104472, US20100090591, US20100148663, US20100244004, US20100295032, US2010102716, US2010105902, US2010244004, US2010270916, US20110057559, US20110108822, US20110204333, US2011215710, US2011227049, US2011285275, US2012292601, US20130146848, US2013033172, US2013165653, US2013181190, US2013334521, US20140246656, US2014103305, U.S. Pat. Nos. 6,303,238, 6,413,656, 6,653,654, 6,670,645, 6,687,266, 6,835,469, 6,921,915, 7,279,704, 7,332,232, 7,378,162, 7,534,505, 7,675,228, 7,728,137, 7,740,957, 7,759,489, 7,951,947, 8,067,099, 8,592,586, 8,871,361, WO06081973, WO06121811, WO07018067, WO07108362, WO07115970, WO07115981, WO08035571, WO2002015645, WO2003040257, WO2005019373, WO2006056418, WO2008054584, WO2008078800, WO2008096609, WO2008101842, WO2009000673, WO2009050281, WO2009100991, WO2010028151, WO2010054731, WO2010086089, WO2010118029, WO2011044988, WO2011051404, WO2011107491, WO2012020327, WO2012163471, WO2013094620, WO2013107487, WO2013174471, WO2014007565, WO2014008982, WO2014023377, WO2014024131, WO2014031977, WO2014038456, WO2014112450.

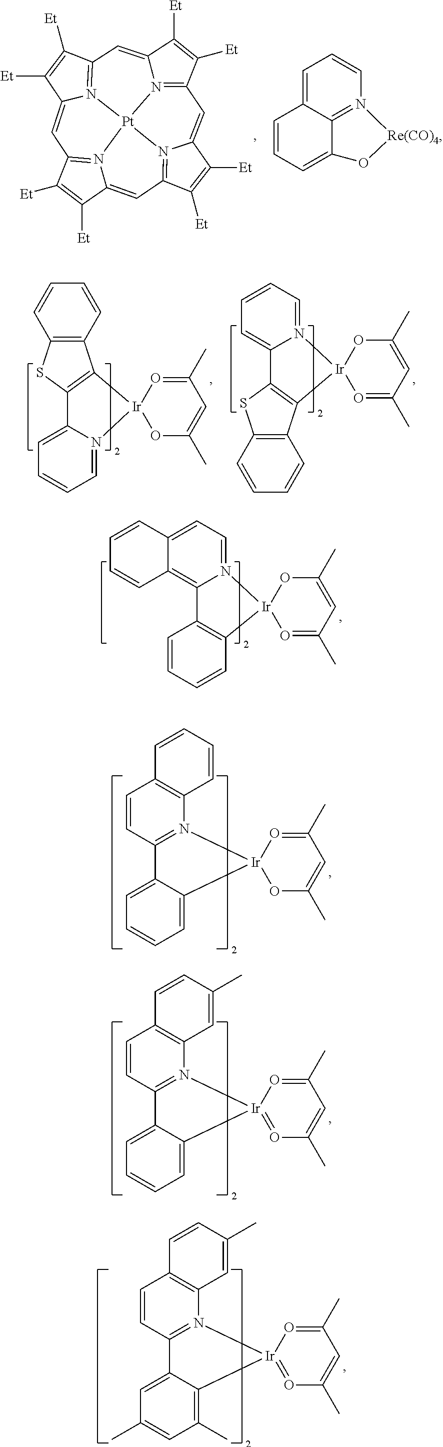

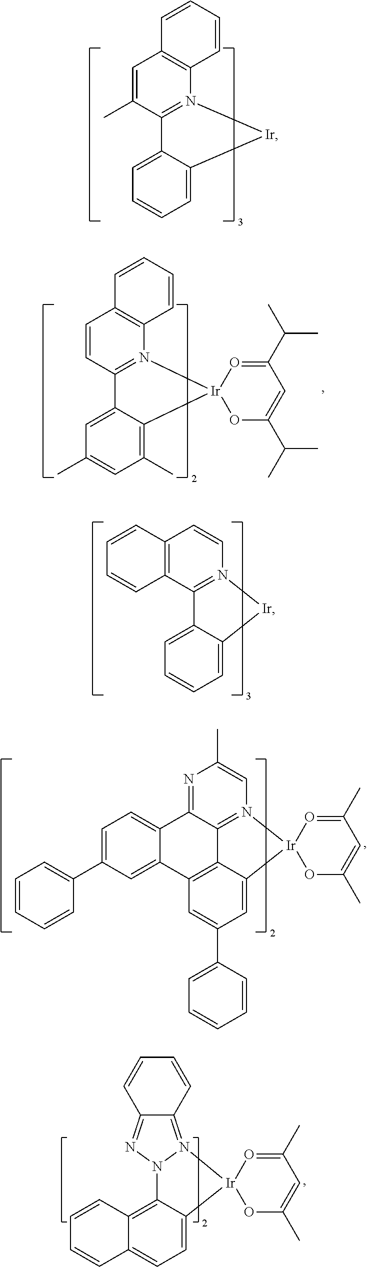

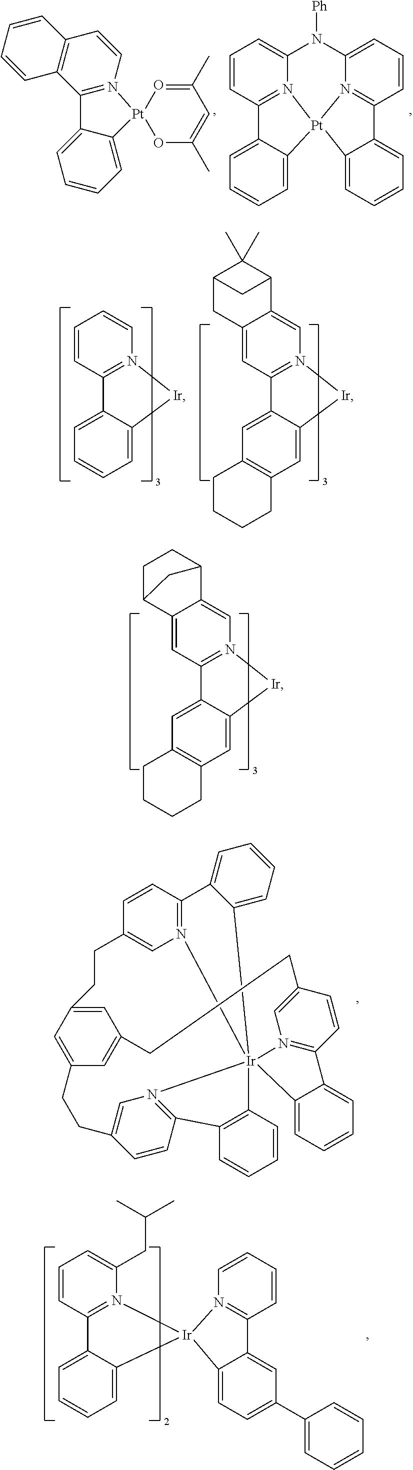

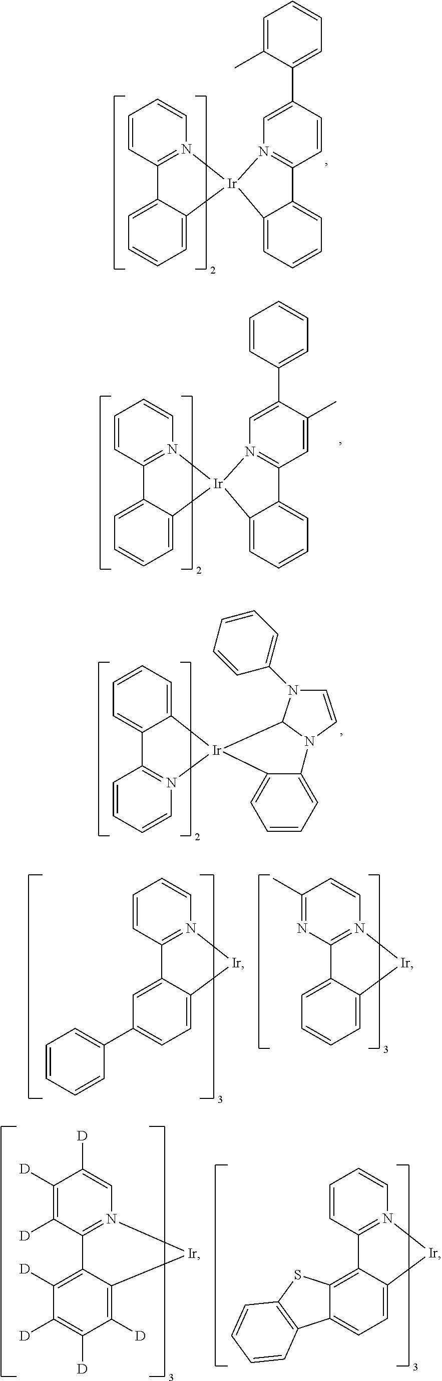

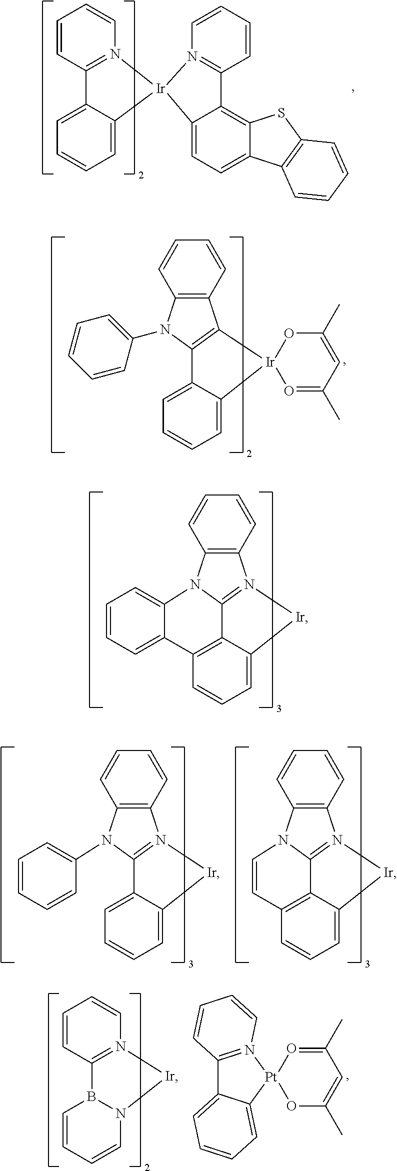

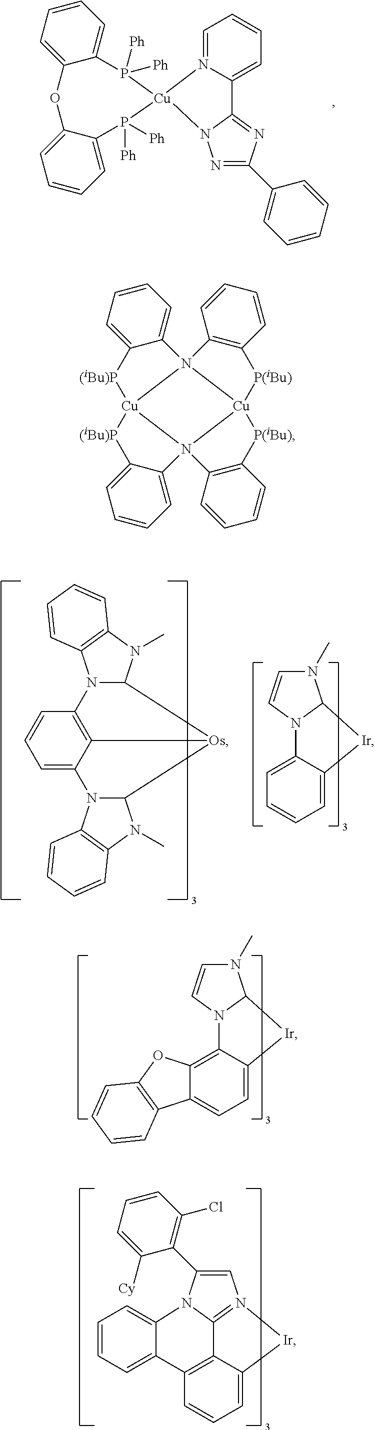

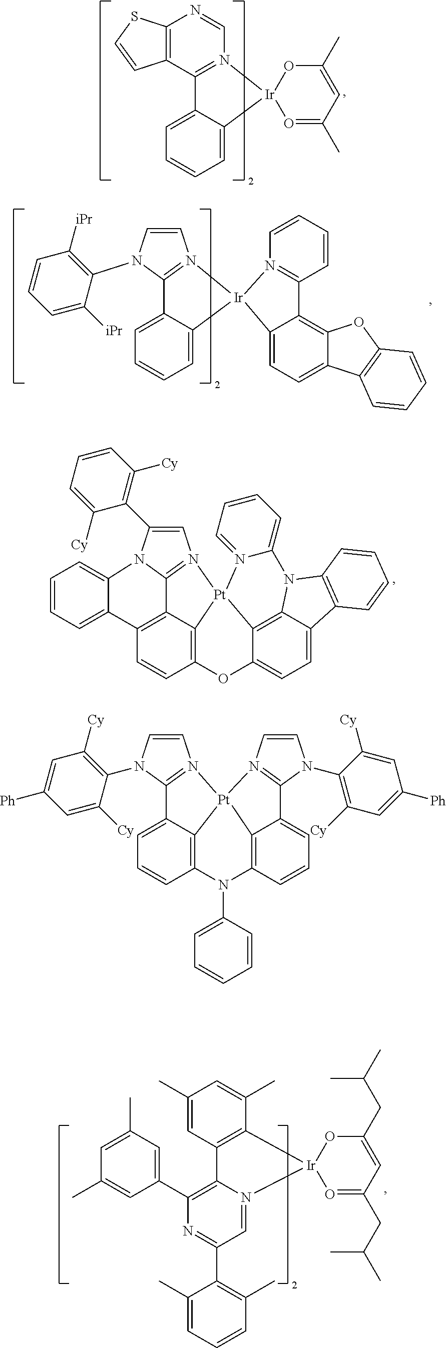

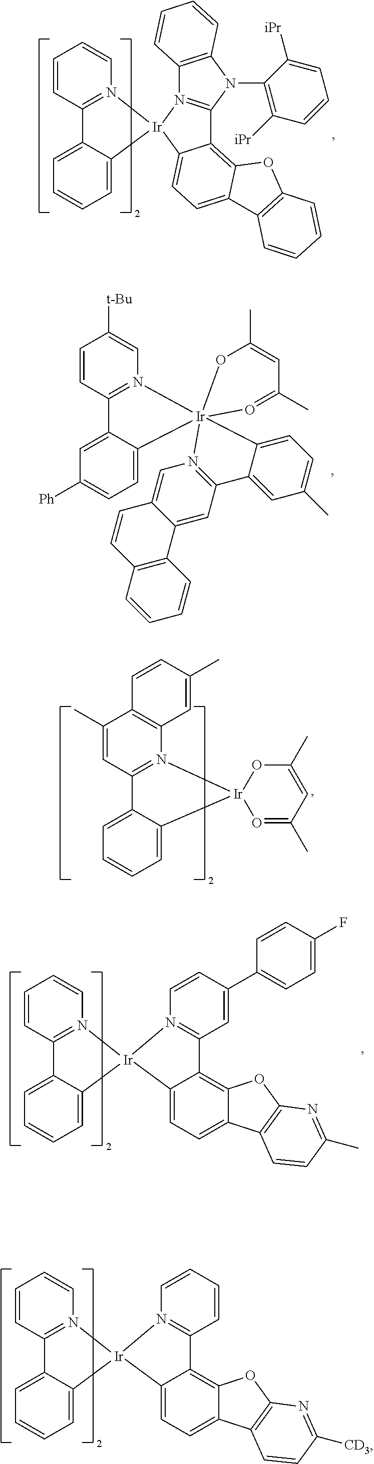

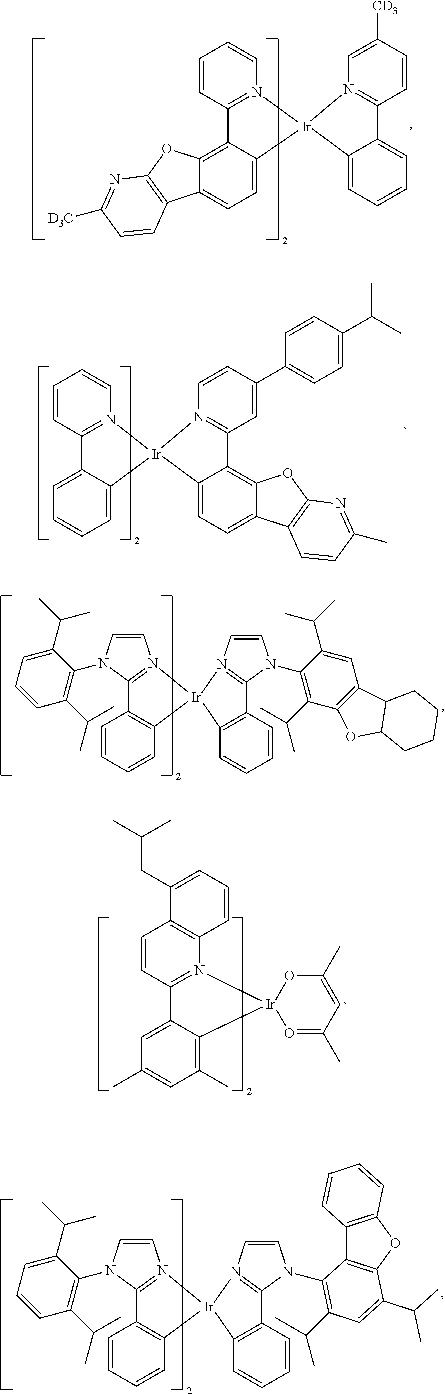

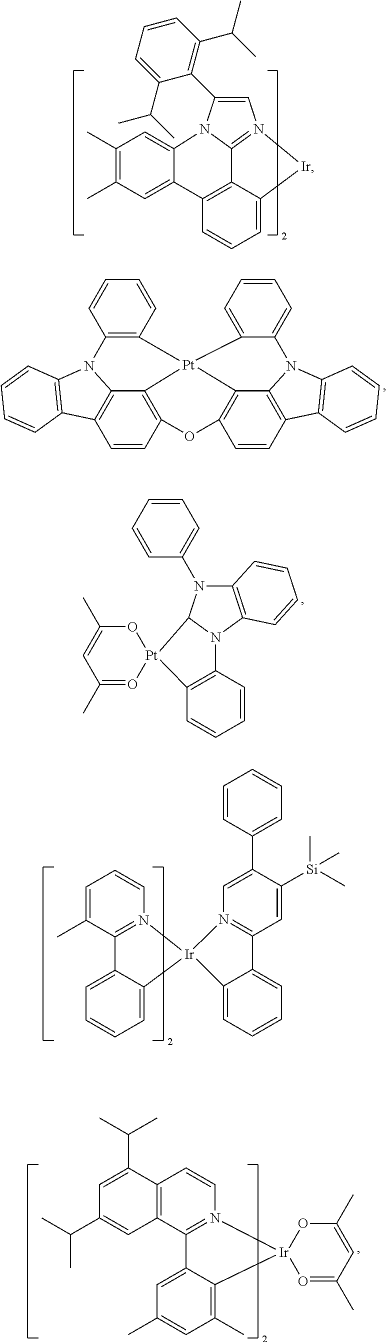

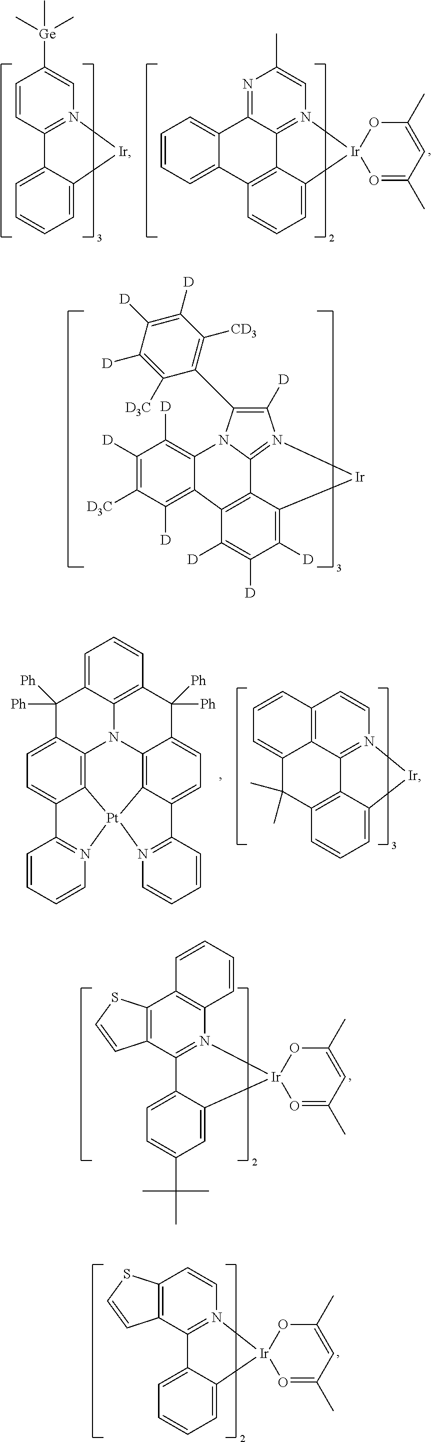

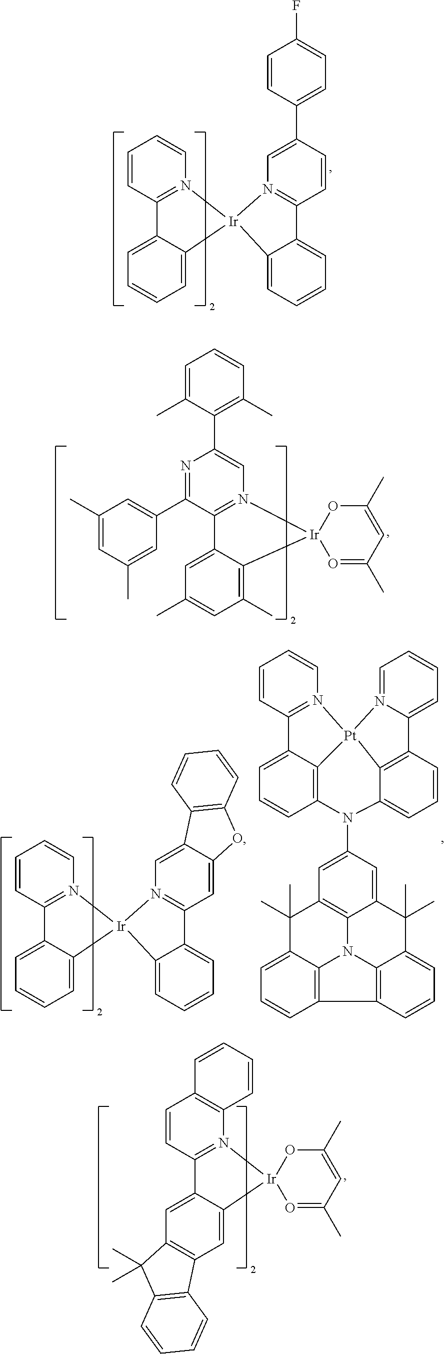

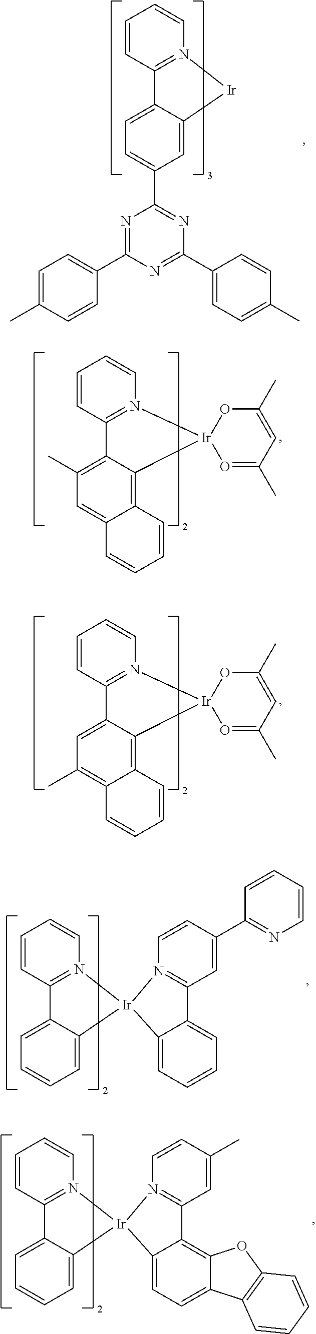

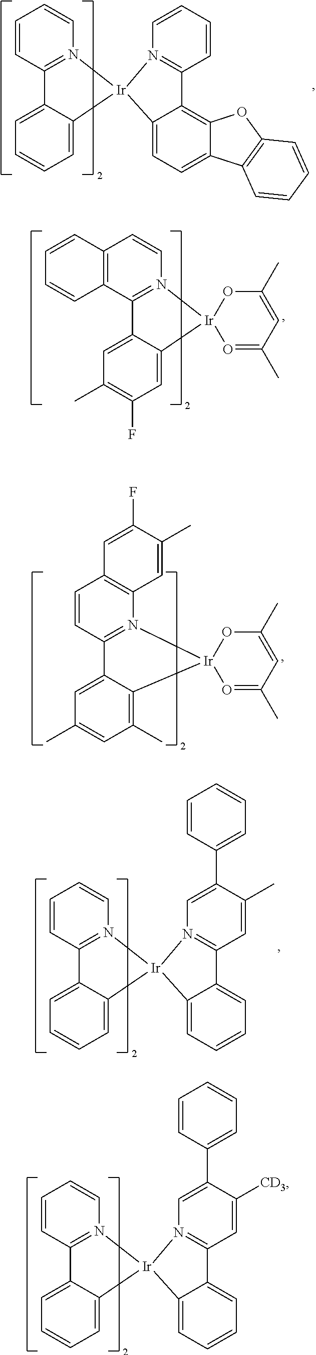

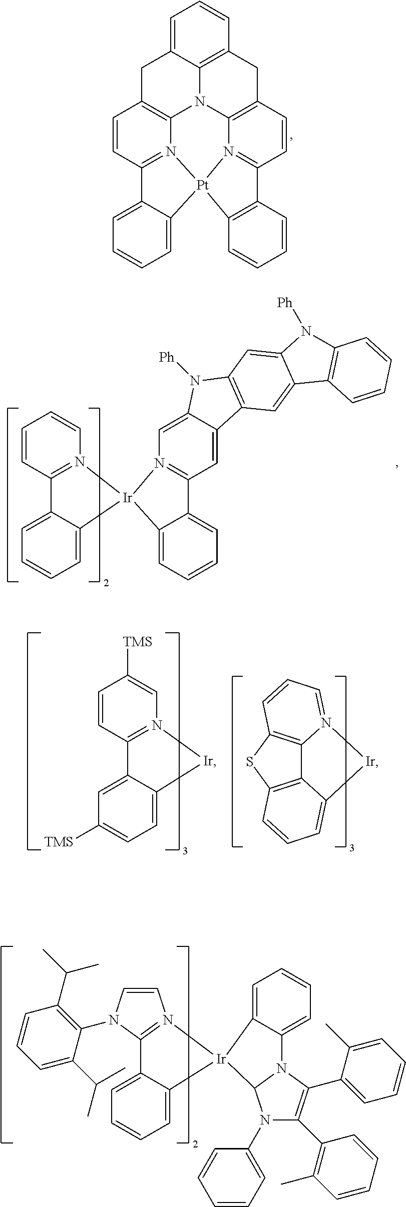

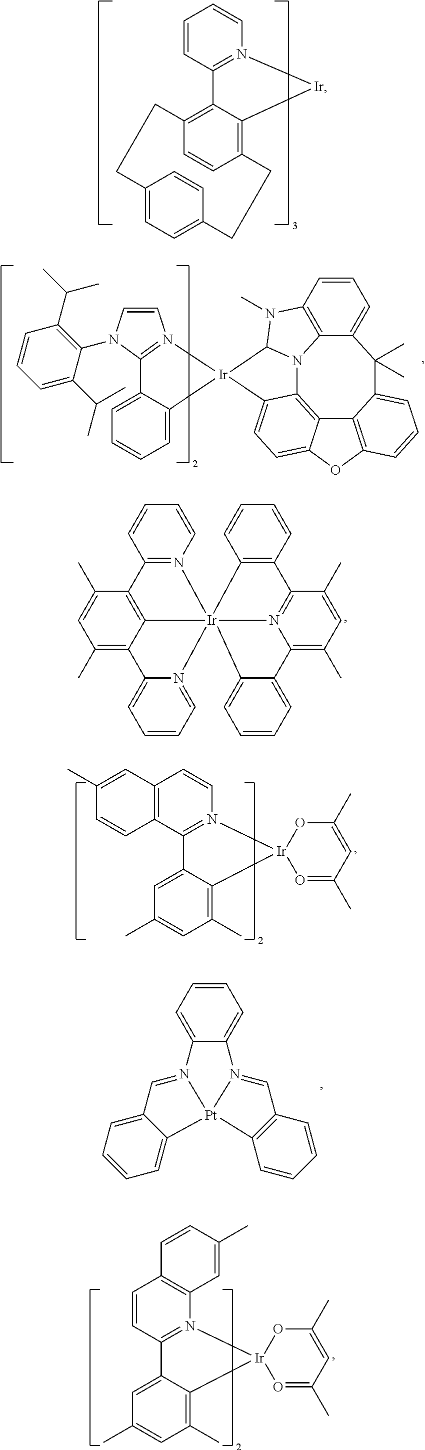

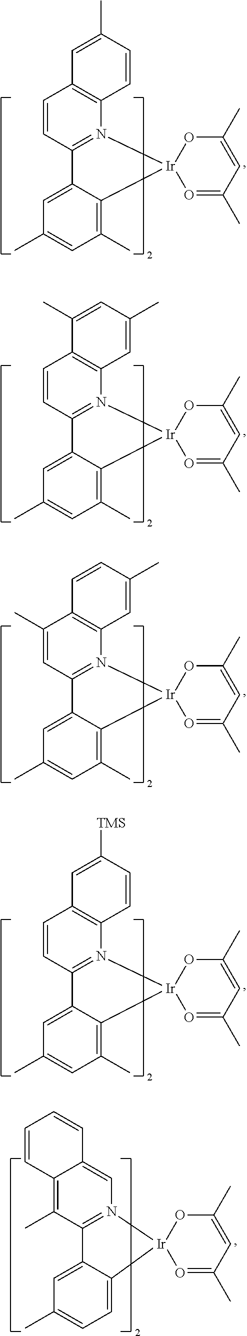

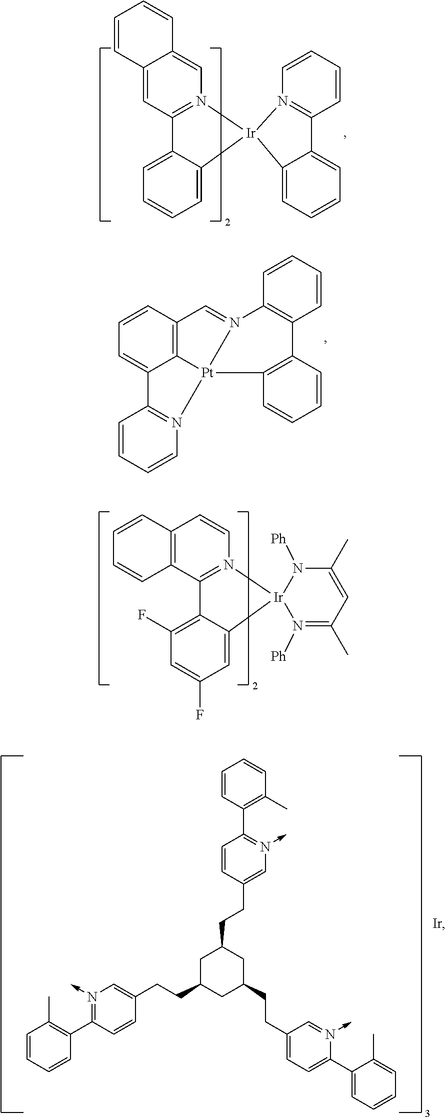

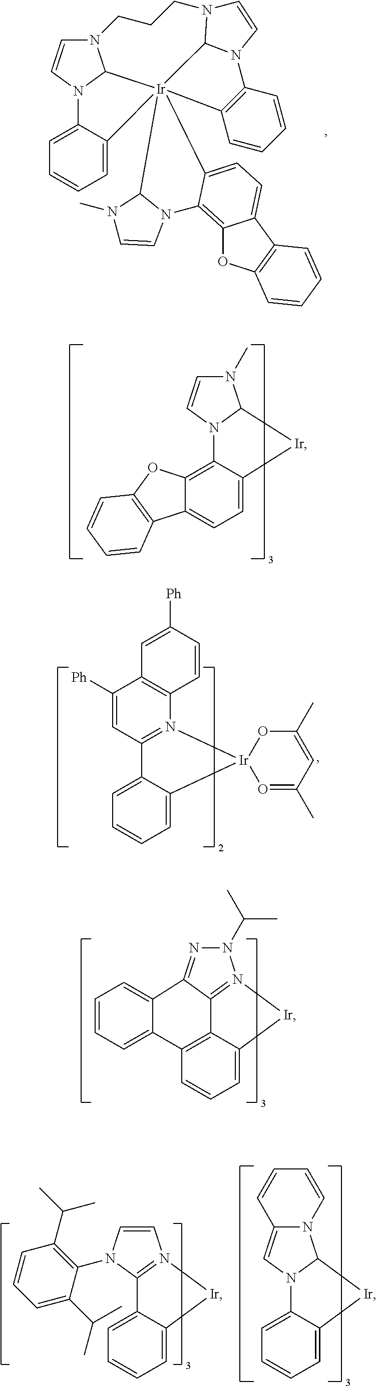

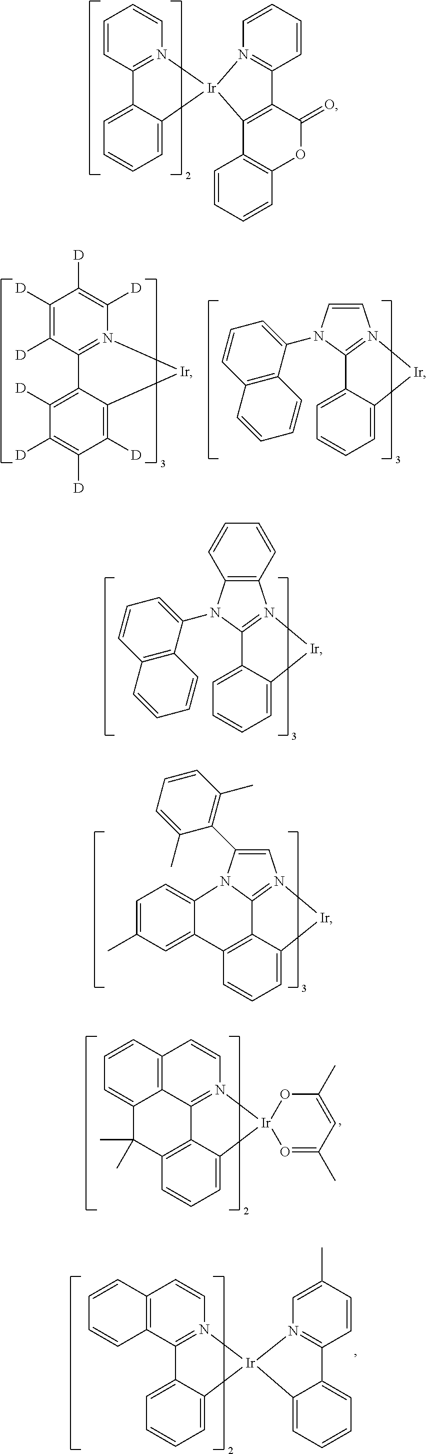

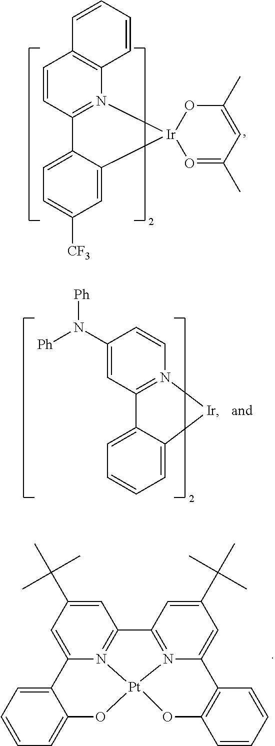

### HBL:

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further from the vacuum level) and/or higher triplet energy than the emitter closest to the HBL interface. In some embodiments, the HBL material has a lower HOMO (further from the vacuum level) and/or higher triplet energy than one or more of the hosts closest to the HBL interface.

In one aspect, compound used in HBL contains the same molecule or the same functional groups used as host described above.

In another aspect, compound used in HBL contains at least one of the following groups in the molecule:

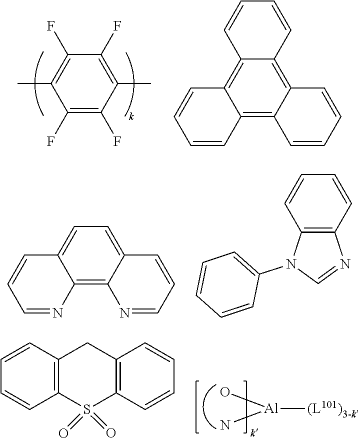

wherein k is an integer from 1 to 20; L¹⁰¹ is another ligand, k′ is an integer from 1 to 3.

### ETL:

Electron transport layer (ETL) may include a material capable of transporting electrons. Electron transport layer may be intrinsic (undoped), or doped. Doping may be used to enhance conductivity. Examples of the ETL material are not particularly limited, and any metal complexes or organic compounds may be used as long as they are typically used to transport electrons.

In one aspect, compound used in ETL contains at least one of the following groups in the molecule:

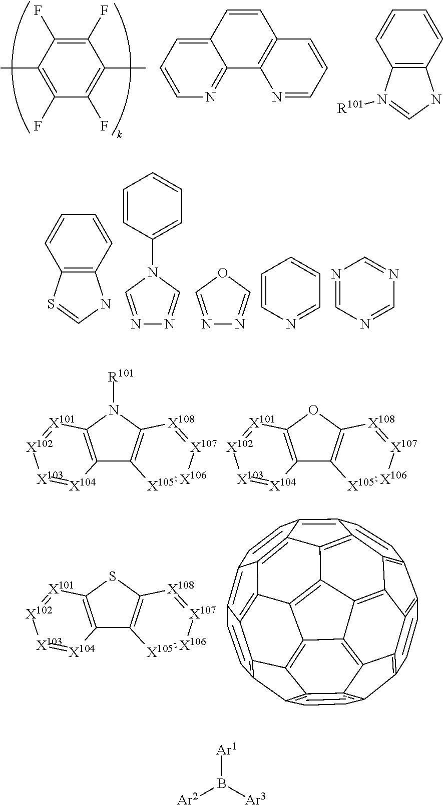

wherein R¹⁰¹ is selected from the group consisting of hydrogen, deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acids, ether, ester, nitrile, isonitrile, sulfanyl, sulfinyl, sulfonyl, phosphino, and combinations thereof, when it is aryl or heteroaryl, it has the similar definition as Ar's mentioned above. Ar¹ to Ar² has the similar definition as Ar's mentioned above. k is an integer from 1 to 20. X¹⁰¹ to X¹⁰⁸ is selected from C (including CH) or N.

In another aspect, the metal complexes used in ETL contains, but not limit to the following general formula:

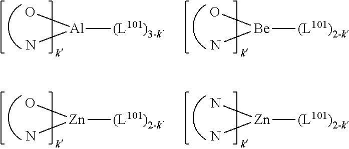

wherein (O—N) or (N—-N) is a bidentate ligand, having metal coordinated to atoms O, N or N, N; L¹⁰¹ is another ligand; k′ is an integer value from 1 to the maximum number of ligands that may be attached to the metal.

Non-limiting examples of the ETL materials that may be used in an OLED in combination with materials disclosed herein are exemplified below together with references that disclose those materials: CN103508940, EP01602648, EP01734038, EP01956007, JP2004-022334, JP2005149918, JP2005-268199, KR0117693, KR20130108183, US20040036077, US20070104977, US2007018155, US20090101870, US20090115316, US20090140637, US20090179554, US2009218940, US2010108990, US2011156017, US2011210320, US2012193612, US2012214993, US2014014925, US2014014927, US20140284580, U.S. Pat. Nos. 6,656,612, 8,415,031, WO2003060956, WO2007111263, WO2009148269, WO2010067894, WO2010072300, WO2011074770, WO2011105373, WO2013079217, WO2013145667, WO2013180376, WO2014104499, WO2014104535,

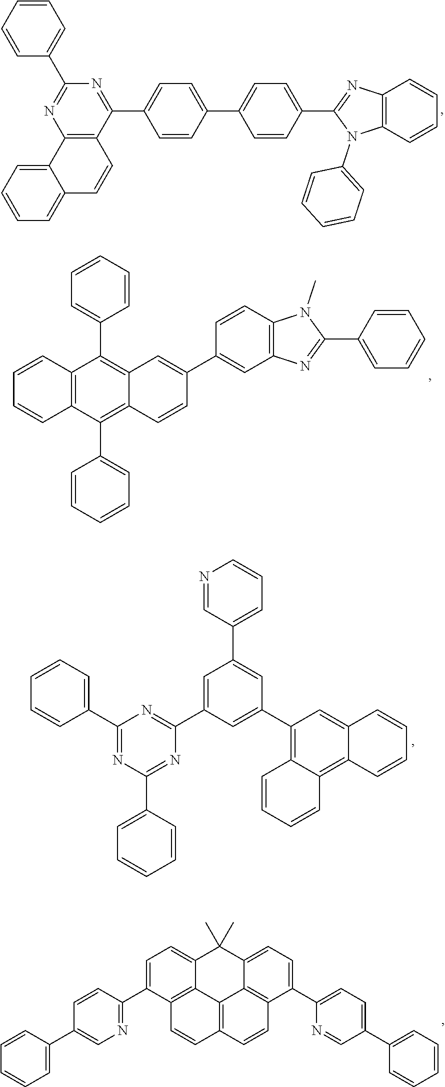 [SMILES: c1ccc(-c2nc(-c3ccc(-c4ccc(-c5nc6ccccc6n5-c5ccccc5)cc4)cc3)c3ccc4ccccc4c3n2)cc1 ; Cn1c(-c2ccccc2)nc2cc(-c3ccc4c(-c5ccccc5)c5ccccc5c(-c5ccccc5)c4c3)ccc21 ; c1ccc(-c2nc(-c3ccccc3)nc(-c3cc(-c4cccnc4)cc(-c4cc5ccccc5c5ccccc45)c3)n2)cc1 ; CC1(C)c2ccc(-c3ccc(-c4ccccc4)cn3)c3ccc4ccc5c(-c6ccc(-c7ccccc7)cn6)ccc1c5c4c23]

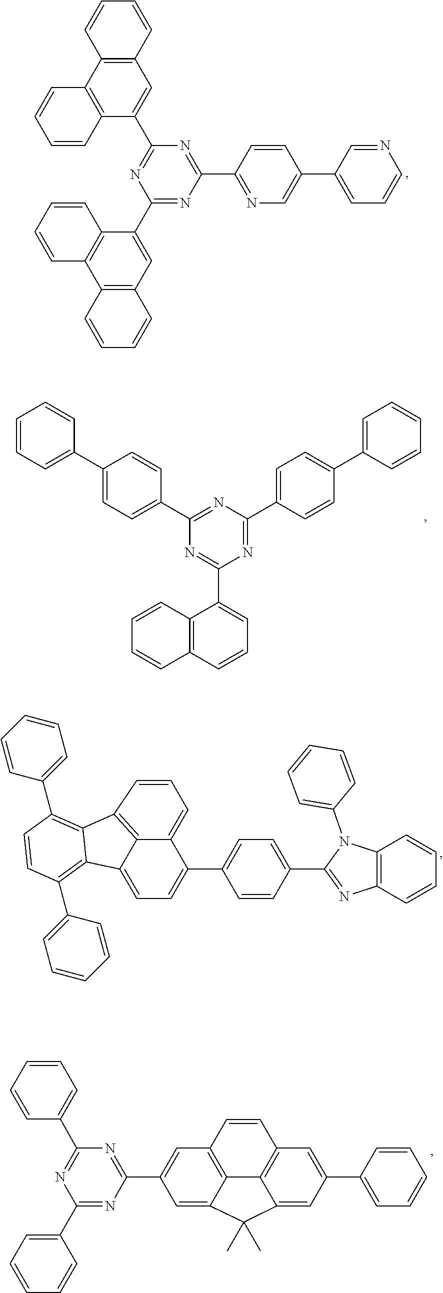 [SMILES: c1cncc(-c2ccc(-c3nc(-c4cc5ccccc5c5ccccc45)nc(-c4cc5ccccc5c5ccccc45)n3)nc2)c1 ; c1ccc(-c2ccc(-c3nc(-c4ccc(-c5ccccc5)cc4)nc(-c4cccc5ccccc45)n3)cc2)cc1 ; c1ccc(-c2ccc(-c3ccccc3)c3c2-c2cccc4c(-c5ccc(-c6nc7ccccc7n6-c6ccccc6)cc5)ccc-3c24)cc1 ; CC1(C)c2cc(-c3ccccc3)cc3ccc4cc(-c5nc(-c6ccccc6)nc(-c6ccccc6)n5)cc1c4c23]

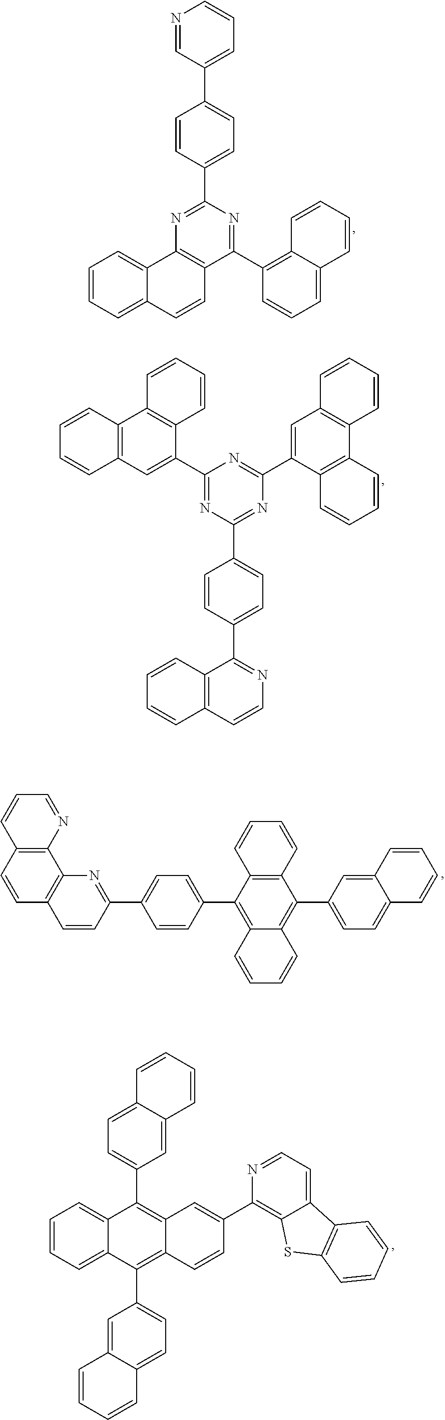

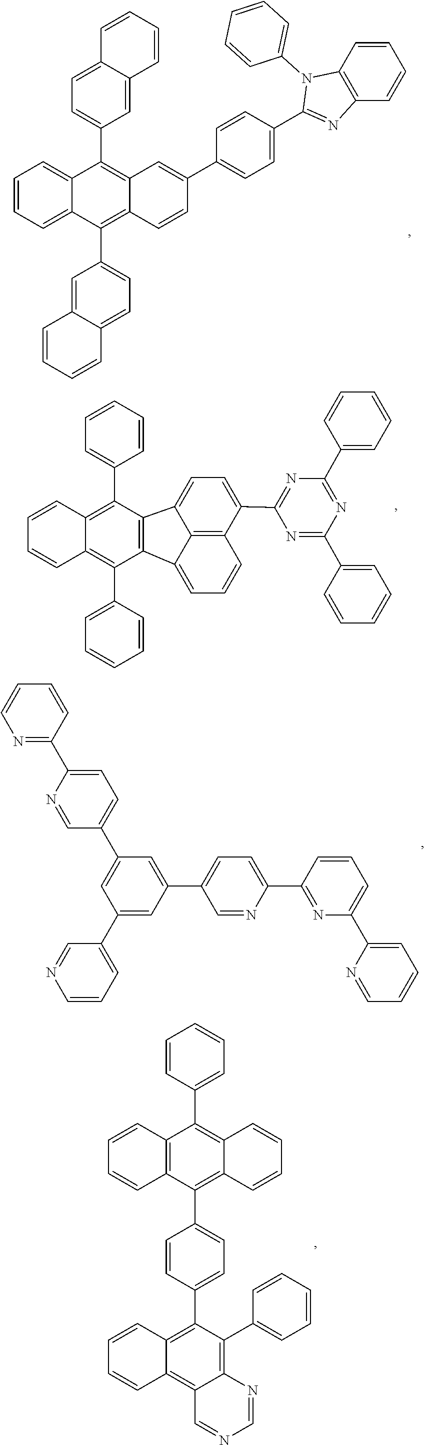

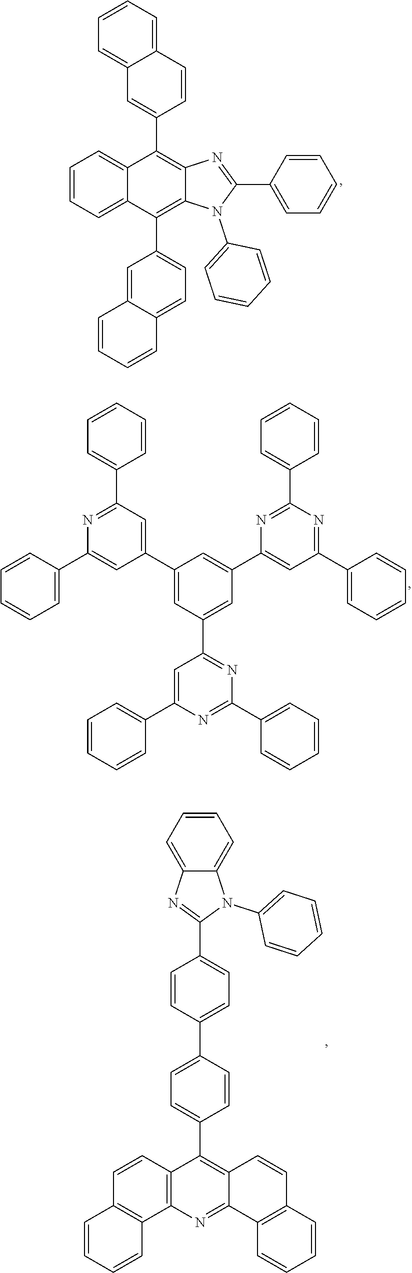

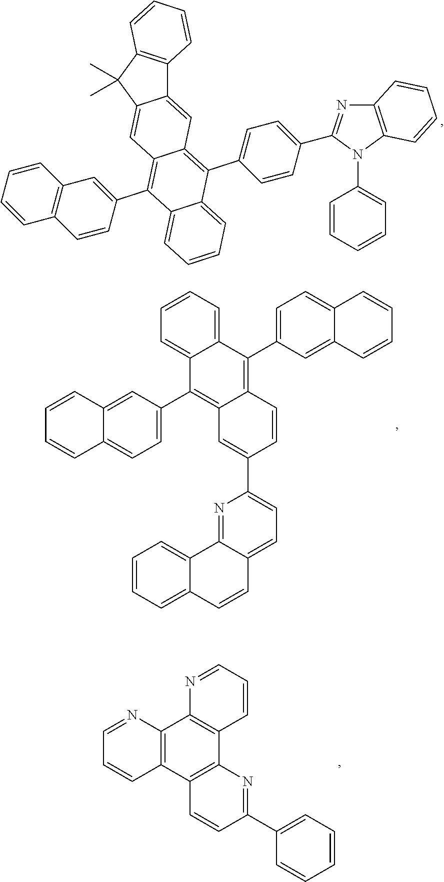

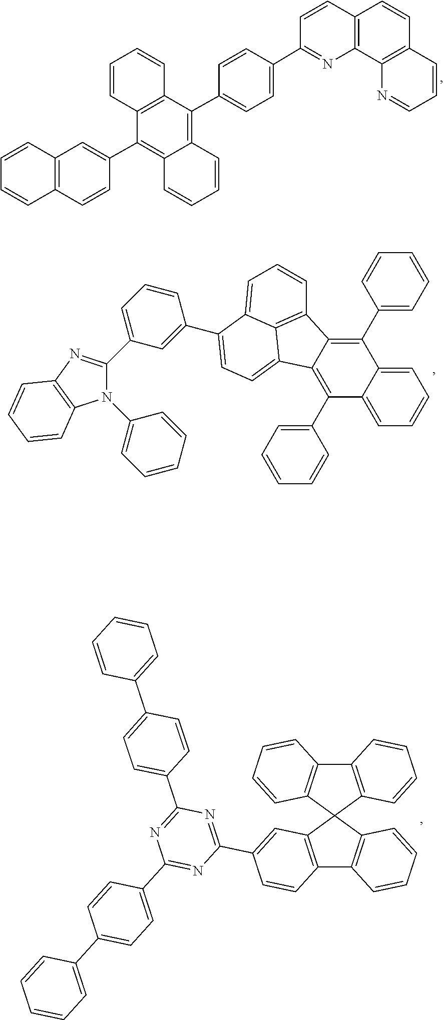 [SMILES: c1ccc2cc(-c3c4ccccc4c(-c4ccc(-c5ccc6ccc7cccnc7c6n5)cc4)c4ccccc34)ccc2c1 ; c1ccc(-c2c3c(c(-c4ccccc4)c4ccccc24)-c2ccc(-c4cccc(-c5nc6ccccc6n5-c5ccccc5)c4)c4cccc-3c24)cc1 ; c1ccc(-c2ccc(-c3nc(-c4ccc(-c5ccccc5)cc4)nc(-c4ccc5c(c4)C4(c6ccccc6-c6ccccc64)c4ccccc4-5)n3)cc2)cc1]

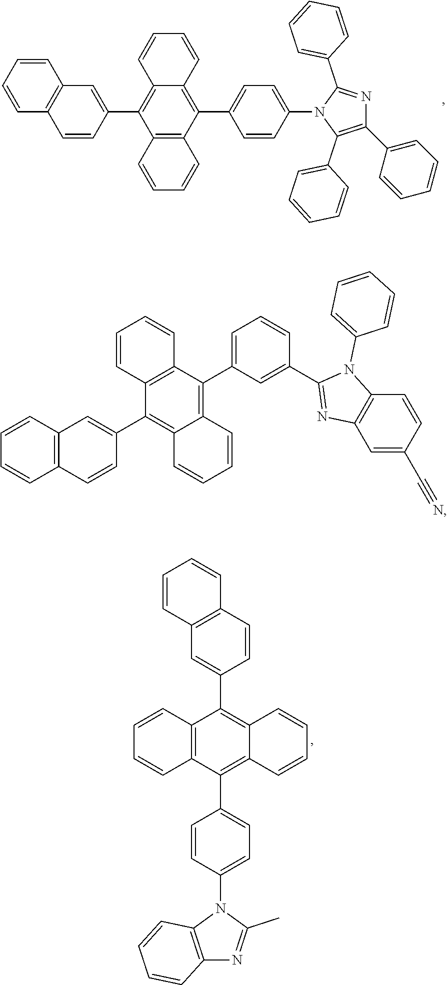 [SMILES: c1ccc(-c2nc(-c3ccccc3)n(-c3ccc(-c4c5ccccc5c(-c5ccc6ccccc6c5)c5ccccc45)cc3)c2-c2ccccc2)cc1 ; N#Cc1ccc2c(c1)nc(-c1cccc(-c3c4ccccc4c(-c4ccc5ccccc5c4)c4ccccc34)c1)n2-c1ccccc1 ; Cc1nc2ccccc2n1-c1ccc(-c2c3ccccc3c(-c3ccc4ccccc4c3)c3ccccc23)cc1]

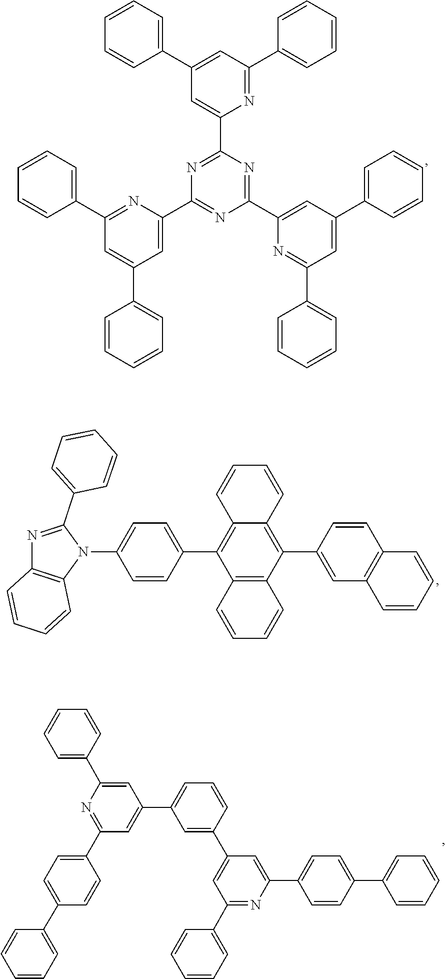 [SMILES: c1ccc(-c2cc(-c3ccccc3)nc(-c3nc(-c4cc(-c5ccccc5)cc(-c5ccccc5)n4)nc(-c4cc(-c5ccccc5)cc(-c5ccccc5)n4)n3)c2)cc1 ; c1ccc(-c2nc3ccccc3n2-c2ccc(-c3c4ccccc4c(-c4ccc5ccccc5c4)c4ccccc34)cc2)cc1 ; c1ccc(-c2ccc(-c3cc(-c4cccc(-c5cc(-c6ccccc6)nc(-c6ccc(-c7ccccc7)cc6)c5)c4)cc(-c4ccccc4)n3)cc2)cc1]

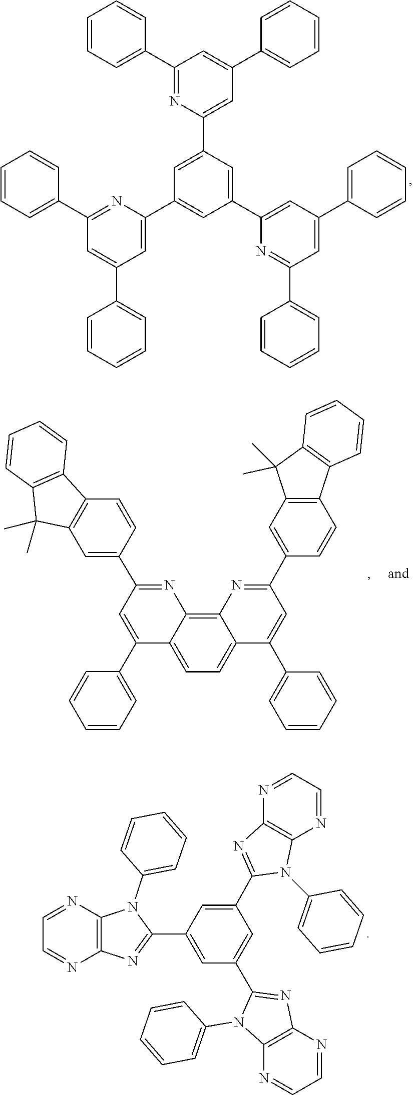

### Charge Generation Layer (CGL)

In tandem or stacked OLEDs, the CGL plays an essential role in the performance, which is composed of an n-doped layer and a p-doped layer for injection of electrons and holes, respectively. Electrons and holes are supplied from the CGL and electrodes. The consumed electrons and holes in the CGL are refilled by the electrons and holes injected from the cathode and anode, respectively; then, the bipolar currents reach a steady state gradually. Typical CGL materials include n and p conductivity dopants used in the transport layers.

In any above-mentioned compounds used in each layer of the OLED device, the hydrogen atoms can be partially or fully deuterated. The minimum amount of hydrogen of the compound being deuterated is selected from the group consisting of 30%, 40%, 50%, 60%, 70%, 80%, 90%, 95%, 99%, and 100%. Thus, any specifically listed substituent, such as, without limitation, methyl, phenyl, pyridyl, etc. may be undeuterated, partially deuterated, and fully deuterated versions thereof. Similarly, classes of substituents such as, without limitation, alkyl, aryl, cycloalkyl, heteroaryl, etc. also may be undeuterated, partially deuterated, and fully deuterated versions thereof.

It is understood that the various embodiments described herein are by way of example only and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

### EXPERIMENTAL

### Example 1: Efficient and Stable OLEDs With Inverted Device Structure Utilizing Solution Processed ZnO-Based Electron Injection Layer

To realize low-cost, efficient, and stable organic light-emitting diodes (OLEDs) in future large area displays and lighting, the development of suitable solution processed functional materials is highly desirable. Herein is described a series of efficient and stable OLEDs with an inverted device architecture employing both a vapor-deposited phosphorescent aggregate emitter, i.e. Pd(II) 7-(3-(pyridine-2-yl-κN)phenoxy-κC)(benzo -κC)([c]benzo[4,5]imidazo-κN)[1,2-a][1,5]naphthyridine (named Pd3O8-Py5), and a solution-processed ZnO layer as potential electron injection layer and electron transporting layer. One of optimized OLED devices exhibited its peak external quantum efficiency (EQE) of 23.9% and retained EQEs of 23.5% and 18.7% at 1,000 and 10,000 cd m⁻², with a low efficiency roll-off. Such an efficient device also demonstrated a measured LT₉₅ lifetime of 98.6 h with an initial brightness of 10,435 cd m⁻² corresponding to an estimated LT₉₅ of 5,313 hat 1,000 cd m⁻². By depositing a 2 nm Al on the ZnO surface, an estimated LT₉₅ lifetime at 1,000 cd m⁻² of such device can be further extended to 73,244 11, making it the longest-lived OLEDs reported in the literature domain This study laid the strong foundation for the future deployment of efficient and stable inverted OLEDs with solution-processed ZnO layers for a wide range of displays and lighting applications

Organic light-emitting diodes (OLEDs) have been widely considered as a key component for future display and lighting applications (M. A. Baldo, et al., Nature 1998, 395, 151; B. W. D'Andrade, et al., Adv. Mater. 2004, 16, 1585; A. Salehi, et al., Adv. Funct. Mater. 2019, 29, 1808803; S. Sudheendran Swayamprabha, et al., Adv. Sci. 2020, 8, 2002254; S. O. Jeon, et al., Nat. Photonics 2021, 15, 208; E. Pakhomenko, et al., Adv. Opt. Mater. 2022, 10, 2201348; G. Zhao, et al., Angew. Chem. Int. Ed Engl. 2022, 61, e0202212861, J. D. Bullock, et al., ACS Appl. Electron. Mater. 2020, 2, 1026). Due to their lower power consumption, long lifetime, and flexible form factors, OLEDs are widely adopted in electronic products like smart watches, phones, and tablets (J. S. Bangsund, et al., Sci. Adv. 2020. 6, eab132659; J. Park, et al., Adv. Mater. 2022, 34, e2108581; A. Salehi, et al., Nat. Commun. 2019, 10, 2305; V. V. Patil, et al., Adv. Sci. 2021, 8, e2101137). However, it has been challenging to produce full color OLED displays for large area TVs due to the technical limitation of existing metal-based shadow masks, which results in a low production yield and a high manufacture expense (C. Zhang, et al., Adv. Mater. 2022, 34, e2103102; H. L. Lee, et al., Adv. Mater. 2022, 34, e2202464; J. Wei, et al., Angew. Chem. Int. Ed Engl. 2021, 60, 12269: Y. Zhang, et al., Adv. Mater. 2022, 35, 2209396). While the current industry is making OLED TV based on individually controlled white OLED pixels with color filters or pixeled blue OLEDs integrated with external quantum-dot based color converters, such approaches will inevitably increase the complexity of manufacture process and demand higher power consumption for each OLED pixel. On the other hand, it has been suggested to fabricate large area full color displays with ink-jet printing techniques, which could circumvent the technical hurdle set by the shadow masks in the vapor-deposition process and produce more efficient OLED pixels in a potential low-cost fashion, making OLED TV more cost-competitive. However, the performance of solution processed OLEDs can't compete with vapor-deposited OLEDs more favorably, in terms of their efficiencies and device operational stabilities, due to the limited set of suitable solution processible functional materials and the lack of infrastructure support (L. Cao, et al., Nat. Photonics 2021, 15, 230; L. Cao, et al., Adv. Mater. 2021, 33, e2101423; M. Sessolo, et al., Adv. Mater. 2011, 23, 1829; Y.-J. Pu, et al., Adv. Mater. 2015, 27, 1327). Thus, more materials development efforts will be required to make the ink jet printing manufacture process ready for a wider market adoption.

In the past decade, there were significant efforts of applying solution-based metal oxides, like nickel oxide (NiO), molybdenum oxide (MoO₃), and zinc oxide (ZnO), into thin film LEDs that take advantage of their process compatibility, chemical stability, optical transparency, moisture resistance, heat resistance, and good electrical conductivity (T. Chiba, et al., Adv. Mater. 2015, 27, 4681; J. C. D. Faria, et al., Adv. Funct. Mater. 2015, 25, 4657; C. Song, et al., Adv. Electron. Mater. 2018, 4, 1700380; Y. Yu, et al., Adv. Funct. Mater. 2022, 32, 2106387; H. Liu, et al., Adv. Mater. 2022, 35, 2209417; S. Liu, et al., Chem. Mater. 2015, 27, 2532). For example, the performance of solution-based quantum-dot LED (QLED) was significantly improved when zinc oxide nanoparticle was explored as both electron-transporting layer (ETL) and electron injection layer (EIL) due to its high transparency, high electron mobility, and favorable energy level alignment for its conduction/valence bands. By adapting ZnO nanoparticles in device structure of ITO/PEDOT:PSS/TFB/QDs/ZnO/Al (J. Song, et al., Adv. Funct. Mater. 2019, 29, 1808377), recent studies showed that QLEDs consisting of Zn₁₋ₓCdₓSe/ZnSe/ZnS QDs demonstrated peak external quantum efficiency (EQEs) of 30.9% with a low efficiency roll-off, exhibiting an estimated LT 50 (decay to 50% of initial intensity) lifetime of 1,800,000 h at the brightness of 100 cd m⁻². While QLEDs have made significant progress in the past decades, the LT₉₅ lifetime of the best QLEDs, following the strict metric set by the display industry, is estimated be 4,691.5 hours at the brightness of 1000 cd/m², which remained to be inferior compared to previously reported phosphorescent OLEDs based on Pd(II) 7-(3-(pyridine-2-yl-κN)phenoxy-κC)(benzo-κC)([c]benzo[4,5]imidazo-κN)[1,2-a][1,5]naphthyridine (named Pd3O8-Py5) with an estimated LT₉₅ lifetime of 48,000 hours. Thus, it is be very important to study if the quality of solution-processed ZnO films can be further improved with a detailed investigation on their processing conditions and post-treatment methods

Compared with the conventional all solution processed QLEDs and OLEDs, the inverted device architecture presents a better opportunity to fabricate devices in a hybrid fashion by depositing solution processed EIL/ETL like zinc oxide , and following up with multiple layers of electron blocking materials, emissive materials, hole transporting materials, and hole injection materials through vapor-deposition process, which allow us to combine all available materials from the development of solution processed OLEDs and vapor deposited OLEDs, and enhance the chance of eventual success (H. Lee, et al., Appl. Phys. Lett. 2010, 96, 153306; H. Hosono, et al., Proc. Natl. Acad. Sci. U.S.A. 2017, 114, 233; H. Lee, et al., ACS Appl. Mater. Interfaces 2013, 5, 1977). Following such strategies, the performance of inverted OLEDs utilizing solution-processed ZnO based EIL employing a previously reported efficient and stable phosphorescent aggregate emitter, i.e. Pd3O8-Py5, was examined. The ultrathin layer of polyethylenimine ethoxylated (PETE) can significantly decrease the work function of ZnO, therefore, PEIE-modified ZnO is often used in the inverted OLEDs. But it may cost certain degree of aggregation on the film when both PEIE and ZnO were dissolved in same solvent (such as 2-ethoxyethanol). By modifying the surface of ZnO, orthogonal solvent for ZnO and PEIE can be selected, respectively. But this will decrease the mobility of ZnO and increase the fabrication complexity, especially for large scale devices. The uniformity of the ZnO nanoparticle layer is important for obtaining the best quality and production yield of the devices. The inventive devices are designed to adapt only one layer from solution process by using high stable ZnO as effective electron transporting/injection layer. By applying ZnO in various device architectures, the performance of these OLEDs was optimized. A Pd3O8-Py5-based OLED achieved a peak EQE of 23.9%, retained high EQEs of 23.5%, and 18.7% at 1,000 and 10,000 cd m⁻². Furthermore, the device demonstrated outstanding operational stability with a measured LT₉₅ of 98.6 h at 10,435 cd m⁻², which corresponds to an estimated LT₉₅ of 5,313 hat 1,000 cd m⁻². By depositing a 2 nm Al on the ZnO surface, an estimated LT₉₅ lifetime at 1,000 cd m⁻² of such device can be further extended to 73,244 h. It is expected that such hybrid inorganic-organic OLEDs will emerge as a potential competitor to conventional OLEDs, since they have intrinsically stable electrodes and can be partially solution-processed, which will expedite the manufacturing process of low-cost, large-area, and shadow mark-free OLED devices for future display and lighting applications

### 2. Results and Discussion

In a host-free device setting, a neat Pd3O8-Py5 film can be employed as an emissive layer in an efficient and stable device operation. A schematic representation, as well as an energy diagram for each functional material, is shown in FIG. 1, which illustrates the structure of various hybrid inorganic-organic OLEDs proposed in current study. Electrons are injected from the ITO into the lowest unoccupied molecular orbital (LUMO) of the organic material via the ZnO conduction band. ZnO nanoparticles were synthesized in polar aprotic media using alkylammonium hydroxides (TMAH) as oxygen precursors. ZnO particles with an average size of 3.0 nm can be synthesized reproducibly using this method, which is relatively simple and requires few reagents and solvents. The absorption and photoluminescent (PL) spectra of ZnO nanoparticles show broad and weak emission in the green spectral region indicated the existence of potential defect states, similar to previous literature reports. Due to intrinsic defects in the lattice, ZnO nanoparticles is normally n-type, and its electron mobility is known to be ˜10⁻³ cm²V⁻¹s⁻¹ (N. Kirkwood, et al., Adv. Mater. Interfaces 2016, 3, 1600868). The transparent patterned ITO substrate is first coated with an n-type ZnO thin film, used as the EIL. After the ZnO layer was dried, the substrates were loaded in the vacuum chamber and several organic layers were thermally deposited along with the Al electrode.

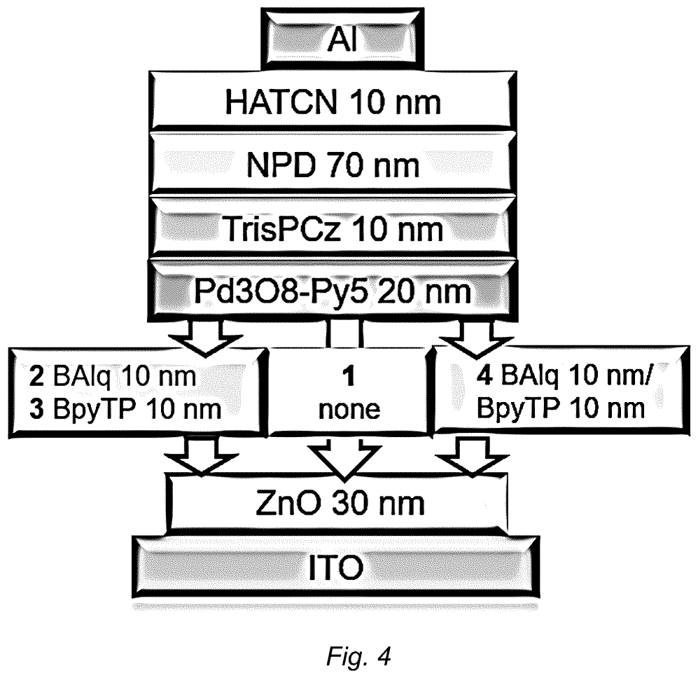

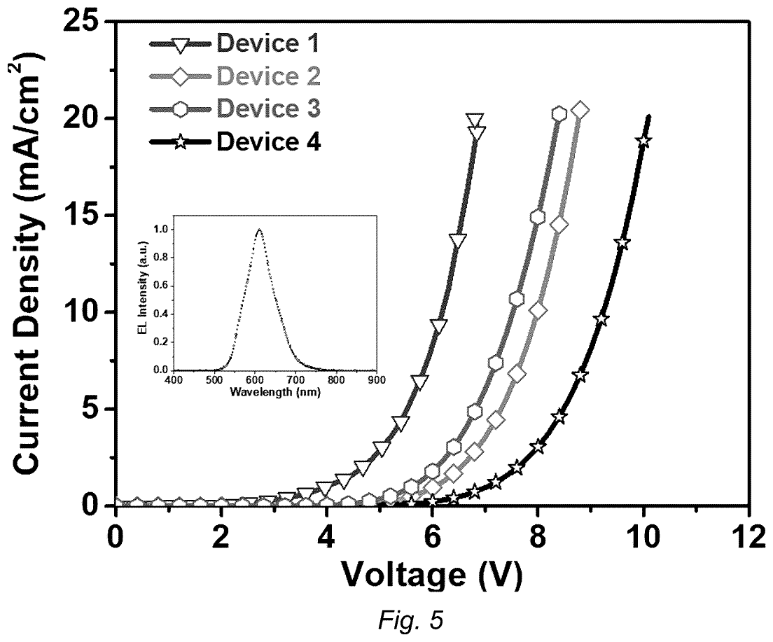

As illustrated in FIG. 4, in order to achieve efficient charge carrier recombination, a series of OLEDs with a general structure of ITO/ZnO (30 nm)/ETL/Pd3O8-Py5 (20 nm)/TrisPCz (10 nm)/NPD (70 nm)/HATCN (10 nm)/Al were fabricated and tested, where ETL could be none for Device 1, 10 nm bis(8-hydroxy-2-methylquinoline)-(4-phenylphenoxy)aluminum (BAlq) for Device 2, 10 nm 2,7-di(2,2′-bipyridine-5-yl)triphenylene (BPyTP) for Device 3 and 10 nm BPyTP/10 nm BAlq for Device 4, TrisPCz is 9,9′,9″-triphenyl-9H,9′ H,9″ H-3,3′ :6′,3″-tercarbazole, NPD is N,N′-diphenyl-N,N′-bis(1-naphthyl)-1,1′-biphenyl-4,4″-diamine, and HATCN is 1,4,5,8,9,11-hexaazatriphenylene-hexacarbonitrile. As illustrated in FIG. 5, the devices with various ETL exhibited different J-V characteristics. All 4 devices were required to have turn-on voltages (at the brightness of 1 cd/m²) within the range of 3.39-5.08 V and the operational voltages at 10 mA/cm² were 6.18, 7.54, 7.99, 9.24V respectively for device 1-4. Compared with previous reported Pd3O8-Py5 devices in a normal device architecture, the typical high turn-on and operational voltages can be associated with ether potential high energy barrier for electron injection from ZnO to individual BAlq, BPyTP, Pd3O8-Py5 layers or possibly low electron mobility of the prepared ZnO layers due to the existence of high defect concentration. As illustrated as an inset in FIG. 5, the EL spectrum of device 4 showed an exclusive emission of Pd3O8-Py5 aggregates without observation of any ZnO defect emission, indicating strong exciton confinement inside of Pd3O8-Py5 layer.

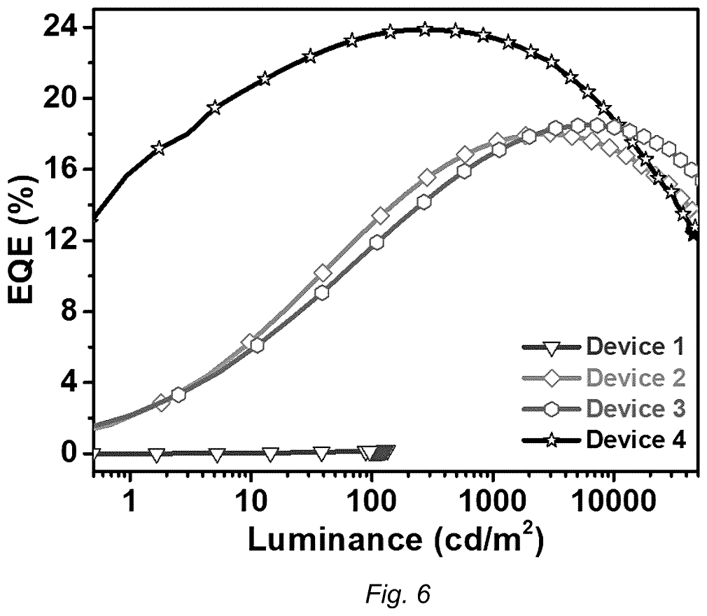

Plots of EQE versus luminance are shown in FIG. 6, which reveals that the peak EQEs of 18.1, 18.5, and 23.9% for devices 2-4, and retained EQEs of 17.3, 16.8, and 23.5% at 1000 cd/m 2 respectively while device 1 exhibits consistently low EQE of less than 0.1% regardless of the device brightness range. Such a drastic difference in device EQE values for device 1-4 indicated that it could be critical to separate the prepared ZnO layer from the emissive layer to prevent ether quenching of Pd3O8-Py5 excitons by ZnO defects or confining the excitons inside of the ZnO layer due to the direct hole injection to defect-induced trap states inside of the ZnO layer. Furthermore, the choice of electron-transporting layer/hole blocking layer also plays a key role of determining the device efficiency. As shown in FIG. 6, the device 4 with the layers of BPyTP/BAlq has the highest device efficiency, which can be attributed to a better charge confinement or a better optical cavity effect on the device outcoupling efficiencies.

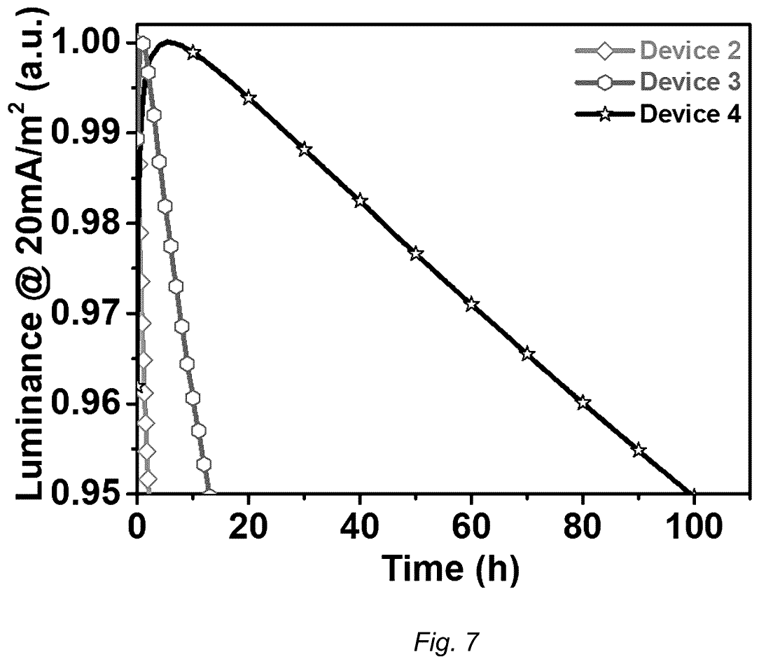

The device operational stabilities of devices 2-4 were also examined. FIG. 7 shows the normalized EL intensity versus operational time for the devices at constant driving current densities of 20 mA/cm². LT₉₅ was chosen as the metric due to the long operational lifetimes reported for devices employing a neat layer of Pd3O8-Py5 and to compare with the standards set by the display industry to minimize the image sticking effect. The measured LT₉₅ value of devices 2-4 was 2.1, 12.8, and 98.6 hours, respectively, which followed the same trend of peak device efficiency among device 2-4. Using the formula LT(L₁)=LT(L₀)(L₀/L₁)ⁿ, where L₁ is the desired luminance and the exponent n is assumed to be a moderate value of 1.7 following previous literature reports (K. Klimes, et al., Adv. Funct. Mater. 2019, 29, 1903068). The device 4 exhibited an estimated LT₉₅ of 5,313 hat 1,000 cd m⁻², which indicates that ZnO can be stable in the process of electron injection and electron transporting during normal OLED operation. This represents a significant step forward in the ongoing integration of ZnO into an efficient hybrid OLED structure and represents a progressive change of potential metal oxide based cathode materials for future OLED development.

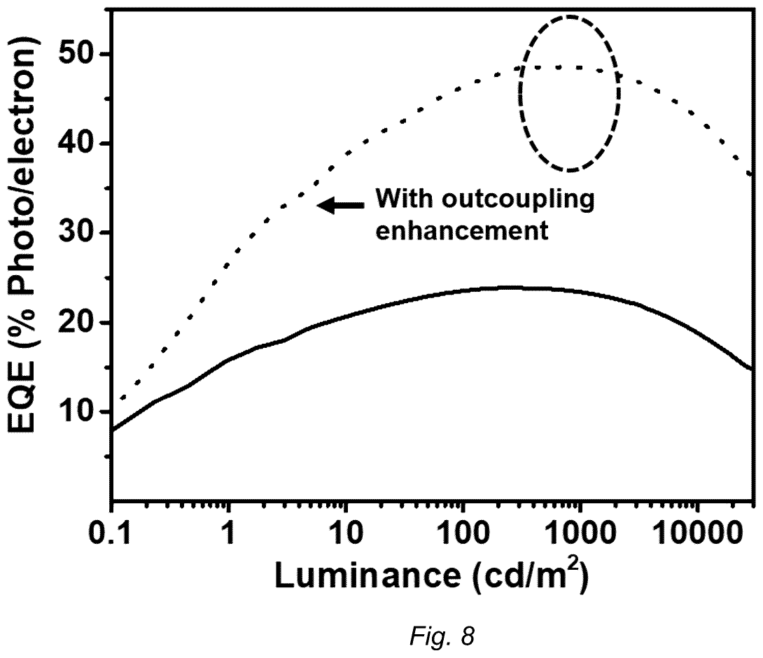

Additionally, the device efficiency, which includes both air mode and substrate mode, was remeasured using an index matching gel between the silicon photodiode and the OLED glass substrate without an air gap. Plots of EQE versus luminance for devices with or without outcoupling enhancement are shown in FIG. 8. The peak EQE_{air+sub} of the Pd3O8-Py5 device is enhanced by more than 2 times to reach 48.6%. The ratio of EQE_{sub}/EQEₐᵢᵣ (>1.0) is much higher than those of previously reported Pd3O8-Py5 based devices with average values of 0.7, which indicated that such inverted OLEDs with nanoparticle ZnO layer could have different photon distribution mechanisms, worthy of further investigation in the future. According to the observation of similar efficiency enhancements for all devices shown in Table 1, phosphorescent molecular aggregates with predominant horizontal emitting dipoles can not only produce more photons in the air mode but also create more photons trapped in the substrate mode.

TABLE 1
Device performance data summary for Pd3O8-Py5 based devices.

| | | EQE @ | EQE @ | | | | LT [symbol] @ |
|---|---|---|---|---|---|---|---|
| | Peak | 1,000 | 10,000 | Peak | | LT [symbol] @ | 1,000 |
| | EQE | cd m⁻² | cd m⁻² | EQE [symbol] | L [symbol] | L [symbol] | cd m⁻² |
| Device | [%] | [%] | [%] | [%] | [cd m⁻²] | [h] | [h] |
| 2 | 18.1 | 17.3 | 17.1 | 37.0 | 10 [symbol] 928 | 2.1 | 122 |
| 3 | 18.5 | 16.8 | 18.4 | 36.4 | 11 [symbol] 080 | 12.8 | 1 [symbol] 164 |
| 4 | 23.9 | 23.5 | 18.7 | 48.6 | 10 [symbol] 435 | 98.6 | 5 [symbol] 313 |
| 5 | 20.6 | 20.6 | 19.3 | 42.0 | 13 [symbol] 352 | 543.4 | 44 [symbol] 519 |
| 6 | 16.8 | 16.6 | 16.1 | 35.1 | 13 [symbol] 621 | 875.1 | 73 [symbol] 244 |
| 7 | 15.1 | 14.9 | 12.9 | 29.3 | 9 [symbol] 953 | 1017.7 | 50 [symbol] 599 |

Device 2: ITO/ZnO (30 nm)/BAlq (10 nm)/Pd3O8-Py5 (20 nm)/TrisPCz (10 nm)/NPD (70 nm)/HATCN (10 nm)/Al,
Device 3: ITO/ZnO (30 nm)/BPyTP (10 nm)/Pd3O8-Py5 (20 nm)/TrisPCz (10 nm)/NPD (70 nm)/HATCN (10 nm)/Al,
Device 4: ITO/ZnO (30 nm)/BPyTP (10 nm)/BAlq (10 nm)/Pd3O8-Py5 (20 nm)/TrisPCz (10 nm)/NPD (70 nm)/HATCN(10 nm)/Al,
Device 5: ITO/ZnO (30 nm)/Al (1 nm)/BPyTP (10 nm)/BAlq (10 nm)/Pd3O8-Py5 (20 nm)/TrisPCz (10 nm)/NPD (70 nm)/HATCN(10 nm)/Al,
Device 6: ITO/ZnO (30 nm)/Al (2 nm)/BPyTP (10 nm)/BAlq (10 nm)/Pd3O8-Py5 (20 nm)/TrisPCz (10 nm)/NPD (70 nm)/HATCN(10 nm)/Al,
Device 7: ITO/ZnO (30 nm)/Al (3 nm)/BPyTP (10 nm)/BAlq (10 nm)/Pd3O8-Py5 (20 nm)/TrisPCz (10 nm)/NPD (70 nm)/HATCN(10 nm)/Al,
Lifetime is estimated from the equation LT(L₁) = LT(L₀)(L₀/L₁)ⁿ, where n is 1.70 [symbol]
indicates data missing or illegible when filed

Compared to previously reported Pd3O8-Py5 based OLED with an estimated LT₉₅ lifetime of 48,000 hours at 1,000 cd/m², the LT₉₅ lifetime of device 4 remains unsatisfactory. In general, the ZnO layer always has structural defects (Zn/oxygen vacancies) that can play an important role in the degradation process of the devices (S. Ding, et al., Appl. Phys. Lett. 2020, 117, 093501; Q. Su, et al., Adv. Sci. 2018, 5, 1800549; W. Zhang, et al., J. Phys. Chem. Lett. 2020, 11, 5863). It is possible that these interface defects between ZnO and adjacent layer will create potential charge injection barriers and cause charge carrier nonradiative recombination, which will adversely affect the device efficiency and reduce the device operational lifetime. While the exploration of better ZnO nanoparticle synthesis method is actively pursued, passivating interfacial defects and filling surface trap states of ZnO can be a useful strategy for potential device performance improvement Similar approaches have proven successfully to reduce charge transport barrier and improve power conversion efficiency of organic solar cells through a universal and effective defect passivation method by fabricating a new ZnO/Al or ZnO/Al₂O₃ nanojunction (T. Cheng, et al., Adv. Opt. Mater. 2017, 5, 1700035; C. Liu, et al., ACS Appl. Mater. Interfaces 2017, 9, 22068). Thus, it will be highly desirable to eliminate nonradiative recombination of charges at the ZnO-organic interface and reduce defect-induced device degradation pathways by passivating ZnO surface with the deposition of nanometer-thin Al layers.

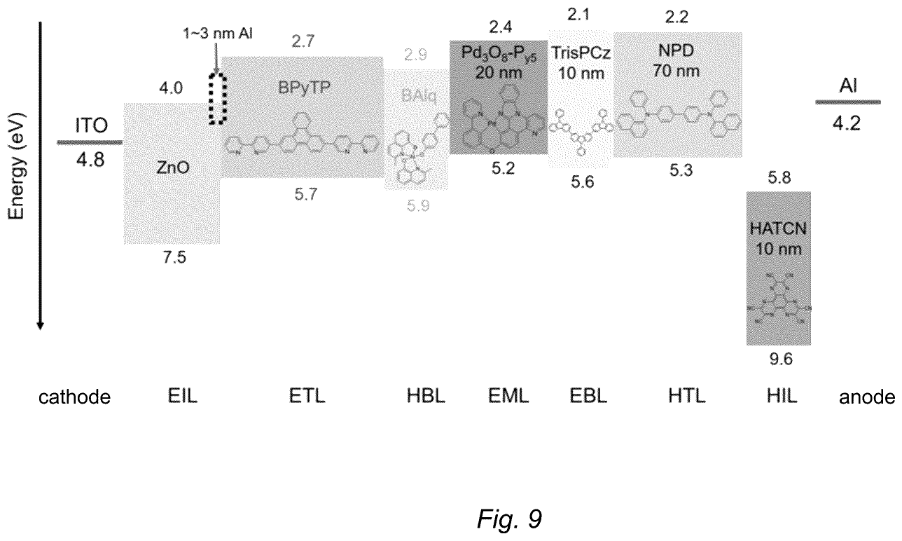

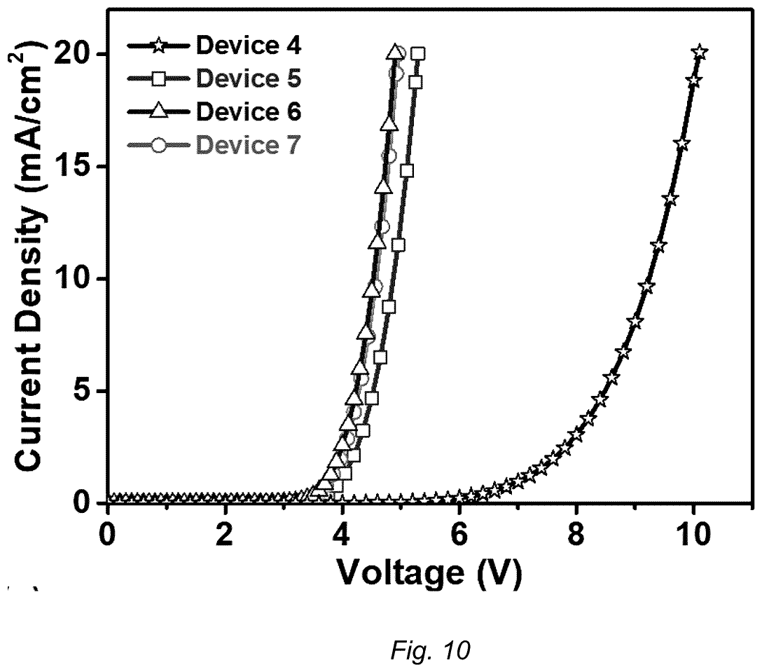

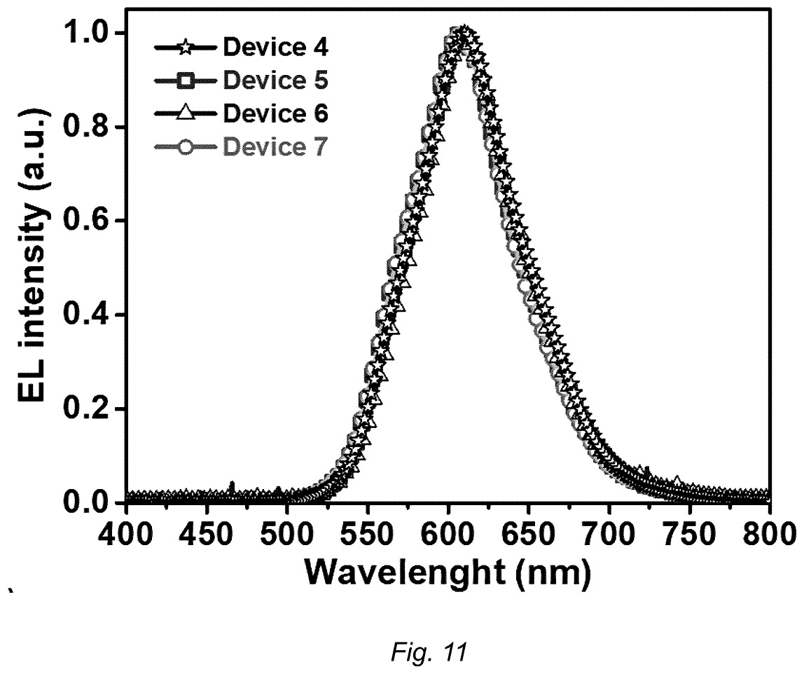

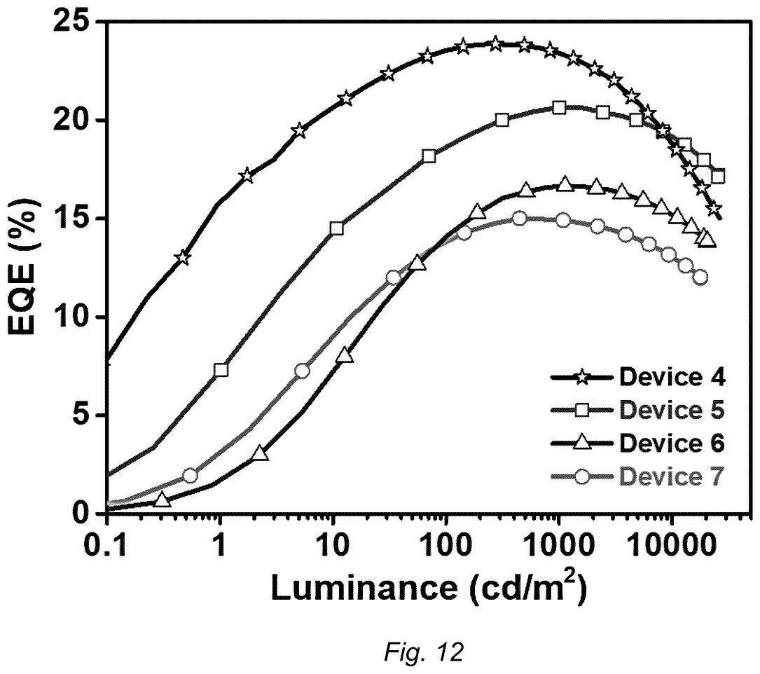

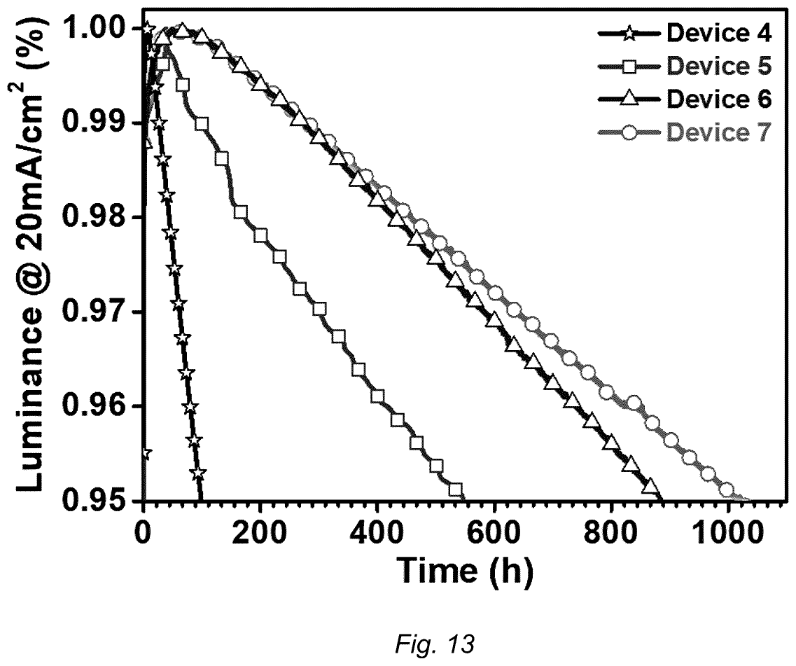

To optimize the effect of Al layer thickness on device performance, a series of OLEDs with a general structure of ITO/ZnO (30 nm)/Al (x nm)/BPyTP (10 nm)/BAlq (10 nm)/Pd3O8-Py5 (20 nm)/TrisPCz (10 nm)/NPD (70 nm)/HATCN (10 nm)/Al were fabricated and tested, where x is 0 nm for device 4, 1 nm for device 5, 2 nm for device 6, and 3 nm for device 7 (FIG. 9). As shown in FIGS. 10-13, different J-V characteristics were exhibited in the devices with various Al layer thickness. Devices 5-7 exhibited turn-on voltages within the range of 2.81-2.96 V and the operational voltages of 5.31, 4.53, and 4.58 V respectively at the current density of 10 mA/cm², which are much lower than those of device 4, i.e. 5.47 and 9.24 V. Thus, defect-induced charge injection barriers between ZnO and the BPyTP layer appeared to be reduced with a thin Al layer deposition. Moreover, the operational voltages of device 6-7 are still higher than that of our previously reported Pd3O8-Py5 device with normal device structure, i.e. 3.9 V, indicating the need of further device optimization with improved ZnO passivation method and different ETL with better LUMO energy level alignment. Additionally, all electroluminescent spectra exhibit similar emission peaks between 480 and 780 nm, centered at 610 nm (FIG. 11), indicating strong exciton confinement inside of the Pd3O8-Py5 layer for all 4 devices. However, as illustrated in FIG. 12, device 4-7 demonstrated peak device efficiencies of 23.9%, 20.6%, 16.8%, and 15.1% respectively, showing the trend of decreasing device efficiency with the increase of Al layer thickness. It is plausible to attribute the decrease of device efficiency to the existence of remaining Al nanoparticles during the passivating process, resulting in potential plasmon quenching of excitons and reduction of device efficiency. This result further validates the importance of optimizing ZnO passivation method. Accelerated operational lifetime testing was carried out on devices 4-7, exhibiting measured LT₉₅ lifetimes of 98.6, 543, 875, and 1,018 hours at the current density of 20 mA cm⁻² (FIG. 13). The 5-10 fold improvement in measured LT₉₅ lifetimes for device 5-7 suggested that the ZnO passivation process not only eliminated defect-induced charge injection barriers, but also suppressed some device degradation pathways. Based on the brightness of device at 20 mA cm⁻², device 4-7 demonstrated estimated LT₉₅ lifetime of 5,313, 44,519, 73,244, and 50,599 hours at the brightness of 1000 cd/m², respectively. It is worthy of mentioning that the measured LT₉₅ lifetime at 20 mA/cm² of device 6 is as almost twice long as the best reported Pd3O8-Py5 device in normal device structure, i.e. 504 hour, and the estimated LT₉₅ lifetime at 1,000 cd/m² of device 6 is 50% higher than the value obtained from the same reported device, i.e. 48,000 hours. To the best of the authors' knowledge, our data is the longest reported LT₉₅ lifetime for a single stack OLED in the literature domain Such a superior long device operational lifetime indicates that the inverted OLED employing a solution processed ZnO layer can compete effectively with conventional OLEDs, which will expedite the manufacturing process of low-cost, large-area, and shadow mark-free OLED devices for future display and automobile lighting applications

Several hybrid inorganic-organic OLEDs employing solution-processed ZnO layers were constructed. By passivating the surface of ZnO layer through a thin Al layer deposition, an inverted OLED device employing Pd3O8-Py5 aggregates demonstrated a long measured LT₉₅ lifetime of 875 hours with an initial brightness of 13,521 cd m⁻² corresponding to an estimated LT₉₅ of 73,244 hours at 1000 cd m⁻², which is the most stable reported single-stack OLED on the public domain. Such outstanding operational lifetime demonstrated the great potential of a solution-processed ZnO based inverted OLED as one OLED device class to be adopted in the low-cost and large scale manufacture process for future display and lighting applications. Moreover, such device efficiency and operational lifetime could be further improved by optimizing ZnO passivation method to eliminate potential plasmon quenching sites and suppress defect-induced degradation pathway.

### 4. Experimental Section

Materials and Reagents: All commercial reagents were purchased and used as received without further purification. Zinc acetate dihydrate (99.999%), tetramethylammonium hydroxide (TMAH, 99%), dimethyl sulfoxide (DMSO, 99.9%), hexanes, acetone, isopropyl alcohol, and ethanol were purchased from Aldrich, N,N′-diphenyl-N,N′-bis(1-naphthyl)-1,1′-biphenyl-4,4′-diamine (NPD), 1,4,5,8,9,11-hexaazatriphenylene-hexacarbonitrile (HATCN) and bis(8-hydroxy-2-methylquinoline)-(4-phenylphenoxy)aluminum (BAlq) were provided by Universal Display Corporation, 2,7-di(2,2′-bipyridine-5-yl)triphenylene (BPyTP), 9,9′,9″-triphenyl-9H,9′H,9″H-3,3′:6′,3″-tercarbazole (TrisPCz) and Pd(II) 7-(3-(pyridine-2-yl-κN)phenoxy-κC)(benzo -κC)([c]benzo[4,5]imidazo-κN)[1,2-a][1,5]naphthyridine (named Pd3O8-Py5) were prepared following the literature (L. Cao, et al., Nat. Photonics 2021, 15, 230).

Synthesis of ZnO nanoparticles: The synthesis of ZnO nanoparticles adopts the method reported in the literature (J. Song, et al., Adv. Funct. Mater. 2019, 29, 1808377). Specifically, 4 mL of 2 mmol of TMAH ethanol solution was added to 10 mL of a DMSO solution of 1 mmol of zinc acetate dihydrate and stirred in air for 1 h. After purification, ZnO nanoparticles were dissolved in ethanol at a concentration of 30 mg/mL and used as an electron transport layer

Materials characterization: The absorption spectrum was recorded on an Agilent 8453 UV—vis spectrometer. The PL spectra were obtained on a Horiba Jobin Yvon FluoroLog-3 spectrometer

Device Characterization and Fabrication: The materials used in the devices were purified via train sublimation in a four-zone thermal-gradient furnace under high vacuum. Prior to deposition, the prepatterned ITO-coated glass substrates were cleaned by subsequent sonication in deionized water, acetone, and isopropyl alcohol. Next, ZnO was spin-coated at 2,000 rpm for 90 seconds in nitrogen-filled glovebox, and then these samples were annealed at 110° C. for 30 min. Organic layers were deposited by vacuum thermal evaporation in a custom-made vacuum thermal evaporation chamber built by Trovato Man. Inc. Base pressure was kept between 10⁻⁸ and 10⁻⁷ Torr, and deposition rates were monitored by quartz-crystal microbalances. The Al cathode was deposited at 1-2 Å s⁻¹ through a shadow mask without breaking vacuum, defining a device area of 0.04 cm². The current—voltage—luminance characteristics were measured using a Keithley 2400 Source-Meter in conjunction with a calibrated Thor Labs FDS10X10 Si photodiode. The photodiode area was considerably larger than that of the OLED, and the OLED was placed in close contact to the center of the photodiode. Accelerated lifetime testing was performed in a nitrogen-filled glove box without encapsulation. Electroluminescent spectra were measured with a Horiba Jobin Yvon FluoroLog-3 spectrometer

### Example 2: Metal Oxides, Doped Metal Oxides, and Mixed Metal Oxides as Single-Layer EIL, EBL, and HBL

The n-type metal oxide is selected from the group consisting of zinc oxide (ZnO), tin oxide (SnOx), titanium oxide (TiOx) can be used as electron injection layer (EIL), electron transporting layer (En) and hole blocking layer (HBL) in OLED stack. However, such neat film materials can function properly due to its potential high defect level. Thus, it will be innovative that Al-, Ga-, Mg-, or Li-doped zinc oxide (ZnO) or mixed zinc oxide layer with MX and M2Y salts will improve the functionality of such materials, where M⁺ is like Cs⁺, Li⁺, Na⁺, Al³⁺ and other cations, X⁻ is like Br⁻, Cl⁻, F⁻ and other anions, and Y is like CO₃²⁻, SO₄²⁻, PO₄³⁻ and other anions.

For instance, pre-synthesized ZnO nanoparticles and Cs₂CO₃ were mixed together 2-methoxyethanol and stirred until complete clear solution was obtained. Its weight ratio between ZnO and Cs₂CO₃ is generally ranged from 1:1 to 10:1 and in the range of 5 to 100 mg/mL.

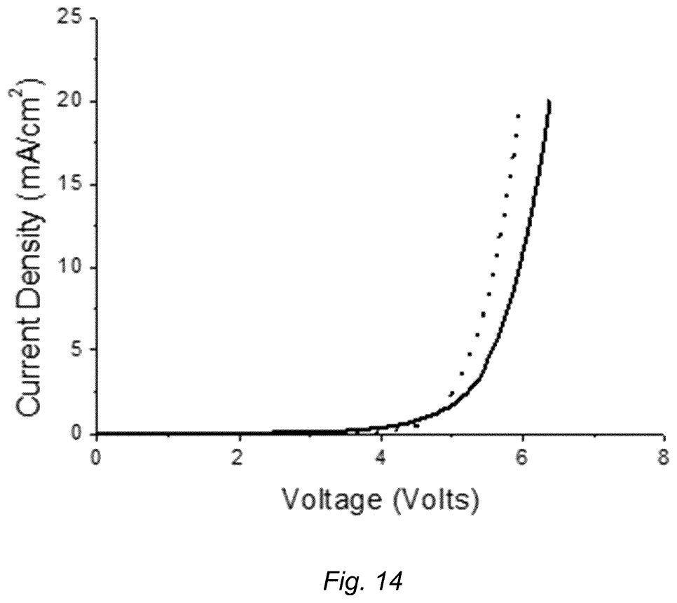

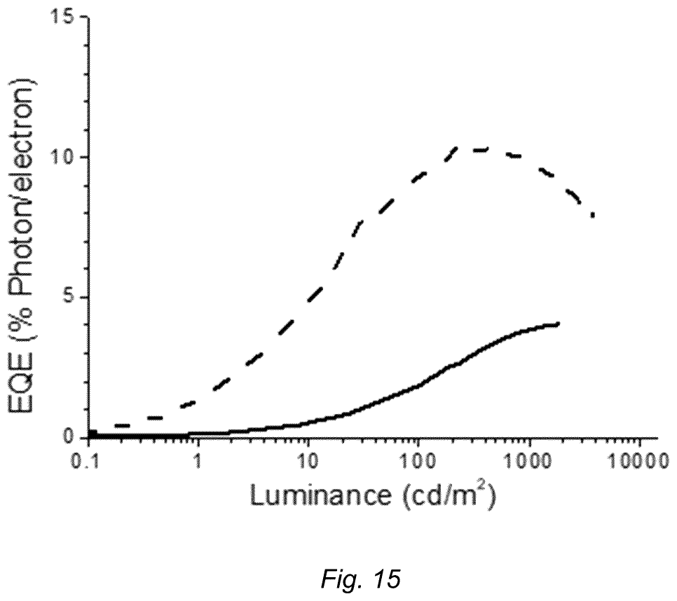

For blue OLED, a general structure of ITO 60 nm/ ZnO mixed layer 30 nm/10% PtON5N: 90% SiTrzCz2 25 nm/cohost 10 nm SiTrzCz2(n):SiBCz (p) 2:1 /SiBCz 5 nm/NPD 60 nm/HATCN 10 nm/ Al 100 nm was fabricated and tested . Here, CsBr or Cs₂CO₃ mixed with zinc oxide on 1:1 weight ratio was spin-coated at 2000 rpm for 90 s in nitrogen-filled glove box, and then these samples were annealed at 200° C. for 30 min (FIGS. 14 and 15). No additional ETL and/or HBL is needed in this structure and the peak EQE is over 10% when the mixed Cs₂CO₃:ZnO layer has been adapted (FIG. 15).

It is understood that the various embodiments described herein are by way of example only, and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

We claim:

1. A hybrid inorganic-organic light emitting device, comprising:
a cathode
an anode;
at least one organic layer disposed between the cathode and the anode, wherein the at least one organic layer comprises an emissive material;
at least one additional layer selected from the group consisting of an electron injection layer, an electron transport layer, and a hole blocking layer;
wherein the at least one additional layer is disposed between the cathode and the at least one organic layer; and
wherein the at least one additional layer comprises at least one metal oxide.

2. The device of claim 1, wherein the at least one additional layer comprises metal oxide nanoparticles.

3. The device of claim 4, wherein the metal oxide nanoparticles have an average diameter between 1 nm and 10 mm

4. The device of claim 1, wherein the at least one metal oxide comprises a compound selected from the group consisting of zinc oxide (ZnO), tin oxide (SnOx), and titanium oxide (TiOx).

5. The device of claim 1, wherein the at least one metal oxide comprises zinc oxide (ZnO).

6. The device of claim 1, wherein the at least one additional layer comprises at least one metal oxide selected from the group consisting of zinc oxide (ZnO), tin oxide (SnOx), and titanium oxide (TiOx); and
at least one additional salt having the formula MXₙ or MYₘ;
wherein M is selected from the group consisting of Cs⁺, Li⁺, Na⁺, and Al³⁺;
X is selected from the group consisting of Br, Cl, and F;
Y is selected from the group consisting of CO₃²⁻, and SO₄²⁻;
n is an integer equal to the charge on the metal M; and
m is equal to the charge on the metal M, divided by 2.

7. The device of claim 6, wherein the at least one additional salt is dispersed in the at least one additional layer.

8. The device of claim 6, wherein the at least one additional salt is disposed between the at least one additional layer and the at least one organic layer.

9. The device of claim 1, further comprising an interlayer thin film, disposed between the at least one additional layer and the at least one organic layer, wherein the interlayer thin film has a thickness between 1 and 5 nm.

10. The device of claim 9, wherein the interlayer thin film comprises a metal selected from the group consisting of aluminum, lithium, magnesium, and gallium.

11. The device of claim 9, wherein the interlayer thin film comprises a metal salt selected form the group consisting of cesium bromide, cesium chloride, cesium carbonate, lithium chloride, lithium bromide, lithium carbonate, lead chloride, lead bromide, and lead carbonate.

12. The device of claim 9, wherein the interlayer thin film comprises aluminum metal.

13. The device of claim 9, wherein the interlayer thin film has a thickness between 1 and 3 nm.

14. The device of claim 9, wherein the interlayer thin film has a thickness of about 1 nm.

15. The device of claim 9, wherein the interlayer thin film has a thickness of about 2 nm.

16. The device of claim 9, wherein the interlayer thin film has a thickness of about 3 nm.

17. The device of claim 1, wherein the emissive material comprises a tetracoordinate metal complex comprising a metal selected from the group consisting of Au(I), Ir(I), Rh (I), Pt(II), and Pd(II).

18. The device of claim 1, wherein the emissive material has a structure represented by General Formula I or General Formula II: 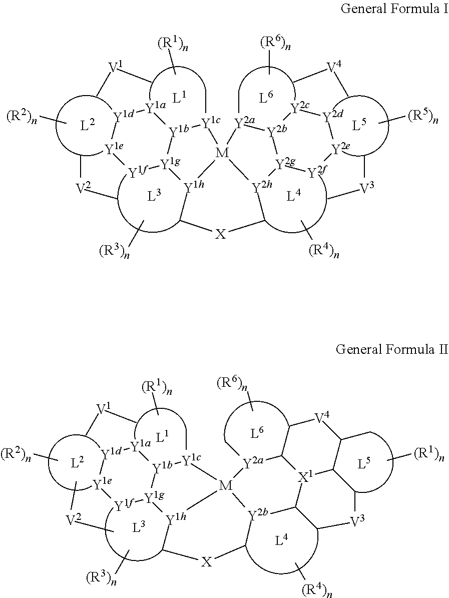
wherein, in General Formula I and General Formula II:
M represents Pt(II), Pd(II), Ir(I), Rh(I), Au(III);
Y^{1a}, Y^{1b}, Y^{1c}, Y^{1f}, Y^{1g}, Y^{1h}, Y^{2a}, Y^{2b}, Y^{2c}, Y^{2f}, Y^{2g}, Y^{2h} each independently represents C or N;
Y^{1d}, Y^{1e}, Y^{2d}, Y^{2e} , each is independently absent or present, and if present, Y^{1d}, Y^{1e}, Y^{2d}, Y^{2e} each independently represents C or N;
X and X¹ each is independently present or absent, and, if present, each of X and X¹ independently represents C, N, Si, O, S, Ge, P, As, Se, B, Al, or Bi, or if valency permits, each independently represents CR⁷, SiR⁷, GeR⁷, NR⁷, P═O, As═O, B, BR⁷, AlR⁷, Bi═O, CR⁷R⁸, C═O, SiR⁷R⁸, GeR⁷R ⁸, PR⁷, PR⁷R⁸, R⁷P═O, AsR⁷, R⁷As═O, S═O, SO₂, Se═O, SeO₂, BR⁷R⁸, AlR⁷R⁸, R⁷Bi═O, or BiR⁷;
R¹, R², R³, R⁴, R⁵, R⁶, R⁷, and R⁸ each is independently absent or present as a single substituent or multiple substituents, valency permitting, and, if present, each of R¹, R², R³, R⁴, R⁵, R⁶, R⁷, and R⁸ independently represents hydrogen, deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof; wherein any two adjacent groups R¹, R², R³, R⁴, R⁵, R⁶, R⁷, or R⁸ may together join to form a ring
L¹, L³, L⁴, and L⁶ each independently represents a 5- to 10-membered aryl, heteroaryl, fused aryl, or fused heteroaryl;
L² and L⁵ each is independently present or absent, and, if present, L² and L⁵ each independently represents a 5- to 10-membered aryl, heteroaryl, fused aryl, or fused heteroaryl;
V¹, V², V³, V⁴ each is independently present, absent, or a covalent bond, and if present, each of V¹, V², V³, V⁴ independently represents C, N, Si, O, S, Ge, P, As, Se, B, Al, or Bi, or if valency permits, each independently represents CR⁷, SiR⁷, GeR⁷, NR⁷, P═O, As═O, B, BR⁷, AlR⁷, Bi═O, CR⁷R⁸, C═O, SiR⁷R⁸, GeR⁷R ⁸, PR⁷, PR⁷R⁸, R⁷P═O, AsR⁷, R⁷As═O, S═O, SO₂, Se═O, SeO₂, BR⁷R⁸, AlR⁷R⁸, R⁷Bi═O, or BiR⁷; and
each n is independently an integer, valency permitting.

19. A consumer product comprising a hybrid inorganic-organic light emitting device, wherein the hybrid inorganic-organic light emitting device comprises:
a cathode
an anode;
at least one organic layer disposed between the cathode and the anode, wherein the at least one organic layer comprises an emissive material;
at least one additional layer selected from the group consisting of an electron injection layer, an electron transport layer, and a hole blocking layer;
wherein the at least one additional layer is disposed between the cathode and the at least one organic layer; and
wherein the at least one additional layer comprises at least one metal oxide.

20. The consumer product of claim 19, wherein the consumer product is selected from the group consisting of a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video walls comprising multiple displays tiled together, a theater or stadium screen, and a sign.
